(19) United States
(12) Patent Application Publication
(10) Pub. No.: US 2026/0279091 A1
(43) Pub. Date: Sep. 17, 2026

(54) METHODS AND SYSTEMS FOR CONSTRUCTION TASK ASSIGNMENT BASED ON RECOGNITION OF CONSTRUCTION DRAWING INFORMATION

(71) Applicant: YIZHI TECHNOLOGY (CHENGDU) CO., LTD., Chengdu (CN)

(72) Inventors: Junjie LIU, Chengdu (CN); Xiaoping LUO, Chengdu (CN); Xian NIE, Chengdu (CN)

(73) Assignee: YIZHI TECHNOLOGY (CHENGDU) CO., LTD., Chengdu (CN)

(21) Appl. No.: 19/672,604

(22) Filed: May 9, 2026

Related U.S. Application Data
(63) Continuation of application No. PCT/CN2025/134781, filed on Nov. 13, 2025.

(30) Foreign Application Priority Data
Dec. 31, 2024 (CN) 202411978286.0
Feb. 7, 2025 (CN) 202510136538.3
Apr. 22, 2025 (CN) 202510507527.1
Nov. 3, 2025 (CN) 202511586952.0

(51) Int. Cl. G06V 30/422; G06F 30/13; G06F 40/279; G06Q 10/0631; G06Q 50/08; G06V 10/26; G06V 10/28; G06V 30/148; G06V 30/412; G06V 30/414

(52) U.S. Cl. CPC G06V 30/422; G06F 30/13; G06F 40/279; G06Q 10/06316; G06V 10/26; G06V 10/28; G06V 30/148; G06V 30/412; G06V 30/414; G06Q 50/08; G06T 2210/04

(57) ABSTRACT

Embodiments of the present disclosure provide a method and a system for construction task assignment based on recognition of construction drawing information. The method includes: obtaining a construction drawing. The method further includes: recognizing a plurality of closed paths in the construction drawing. The method further includes: determining a drawing border of the construction drawing based on a positional relationship between the plurality of closed paths. The method further includes: determining title block information based on the drawing border of the construction drawing and a title block scope of the construction drawing. The method further includes: determining a recognition result of a target object in the construction drawing based on the title block information. The method further includes: performing a construction task assignment based on the recognition result of the target object.

### CROSS-REFERENCE TO RELATED APPLICATIONS

This application is a continuation of International Application No. PCT/CN2025/134781, filed on Nov. 13, 2025, which claims priority of Chinese Patent Application No. 202411978286.0, filed on Dec. 31, 2024, Chinese Patent Application No. 202510136538.3, filed on Feb. 7, 2025, Chinese Patent Application No. 202510507527.1, filed on Apr. 22, 2025 and Chinese Patent Application No. 202511586952.0, filed on Nov. 3, 2025, entire contents of the applications are incorporated herein by reference.

### TECHNICAL FIELD

The present disclosure relates to a field of construction, and in particular, to a method and a system for construction task assignment based on recognition of construction drawing information.

### BACKGROUND

In engineering construction and management, construction drawing management of is a key link to ensure smooth progress of a project. With development of digital technology, electronic CAD construction drawings have become an important tool for engineering design and management. The construction drawing management and the construction task assignment based on the construction drawings directly affect the promotion efficiency of the project. However, a plurality of problems exist in current relevant links. On one hand, extraction efficiency and precision of construction drawing information are insufficient, such that spatial information included in sub-item names of the construction drawings, drawing names of the construction drawings, or the like need to be manually inputted by a user. The degree of intelligence is low, and processing a plurality of pieces of data is difficult. A plurality of rectangular boxes with diverse positional relationships (e.g., non-intersection, inclusion, tangency, or the like) exist in complex electronic construction drawings, resulting in high difficulty and low accuracy in recognizing a drawing border of the complex electronic construction drawings. The title block information has differences in naming and positions due to different drawing standards of different design institutes, and existing extraction processes of the title block information depending on manual annotation or simple geometric matching are difficult to adapt to diverse layouts and rules, and need to consider both geometric characteristics of primitives (e.g., a position, a size, or the like) and text content, further reducing recognition efficiency. On the other hand, the construction task assignment lacks precision. Taking the construction task assignment of a wall surface as an example, an inner wall surface and an outer wall surface have different facing spaces, and differences exist in corresponding process practices, such as waterproofing, plastering, or the like. A traditional construction task assignment depends on manual designation by the experience of a manager, has strong subjectivity and low efficiency, only roughly divides regions, fails to perform the construction task assignment with the wall surface as a unit, and does not distinguish the inner wall surface and the outer wall surface to be processed as independent units.

Therefore, providing a method and a system for construction task assignment based on recognition of construction drawing information is necessary to improve the effectiveness of the construction drawing management, and efficiency and accuracy of the construction task assignment based on the construction drawings.

### SUMMARY

One or more embodiments of the present disclosure provide a method for construction task assignment based on recognition of construction drawing information. The method includes obtaining a construction drawing. The method further includes recognizing a plurality of closed paths in the construction drawing. The method further includes determining a drawing border of the construction drawing based on a positional relationship between the plurality of closed paths. The method further includes determining title block information based on the drawing border of the construction drawing and a title block scope of the construction drawing. The method further includes determining a recognition result of a target object in the construction drawing based on the title block information. The method further includes performing a construction task assignment based on the recognition result of the target object.

One or more embodiments of the present disclosure provide a system for construction task assignment based on recognition of construction drawing information. The system includes a first recognition module, a second recognition module, a first determination module, a second determination module, a third determination module, and a task assignment module. The first recognition module is configured to obtain a construction drawing. The second recognition module is configured to recognize a plurality of closed paths in the construction drawing. The first determination module is configured to determine a drawing border of the construction drawing based on a positional relationship between the plurality of closed paths. The second determination module is configured to determine title block information based on the drawing border of the construction drawing and a title block scope of the construction drawing. The third determination module is configured to determine a recognition result of a target object in the construction drawing based on the title block information. The task assignment module is configured to perform a construction task assignment based on the recognition result of the target object.

One or more embodiments of the present disclosure provide a method for drawing border recognition. The method includes recognizing a plurality of closed paths in a construction drawing. The method further includes generating one or more closed path sets based on a positional relationship between the plurality of closed paths. Each of the one or more closed path sets includes one or more closed paths at one or more levels. A first area enclosed by each of closed paths at a lower level being included within a second area enclosed by closed paths at an upper level of the lower level, or intersecting with the second area. The method further includes determining whether each of the one or more closed path sets includes a target closed path corresponding to a drawing border.

One or more embodiments of the present disclosure provide a method for title block information recognition. The method includes obtaining a title block scope of a construction drawing. The method further includes determining a first closed path list based on a drawing border of the construction drawing and the title block scope, the first closed path list including all first closed paths that do not contain any other closed paths. The method further includes determining a closed path of a title block field based on a primitive scope of a text primitive in a text primitive list and the first closed paths in the first closed path list. The method further includes determining a content value range of the title block field based on a first Intersection over Union (IoU) between the closed path of the title block field and the primitive scope, and an offset distance between a scope center point of the text primitive and a center point of the closed path of the title block field. The method further includes obtaining a text content value within the content value range according to the content value range.

One or more embodiments of the present disclosure provide a method for extracting spatial information of a construction drawing. The method includes obtaining a drawing border of a construction drawing, the drawing border including title block information. The method further includes performing title block recognition based on the drawing border to determine initial spatial information. The method further includes comparing the initial spatial information based on a preset spatial information database to obtain a comparison result. The method further includes splitting the initial spatial information according to the comparison result to obtain spatial description information. The method further includes obtaining target spatial information of a target construction drawing based on the spatial description information.

One or more embodiments of the present disclosure provide a method for wall surface task assignment. The method includes recognizing wall surfaces in a target construction area from a construction drawing. The method further includes obtaining a construction task sheet corresponding to the wall surfaces. The construction task sheet includes construction task information and construction worker information corresponding to a target construction period. The method further includes determining target wall surfaces to be constructed in the target construction period and a construction task item corresponding to each target wall surface from the wall surfaces in the target construction area based on the construction task information and historical construction data of the wall surface. The method further includes determining target construction workers, and the target wall surfaces and the construction task item assigned to each of the target construction workers in the target construction period, based on the construction worker information and the construction task item corresponding to each of the target wall surfaces.

### BRIEF DESCRIPTION OF THE DRAWINGS

The present disclosure will be further described by way of exemplary embodiments. These exemplary embodiments will be described in detail with reference to the accompanying drawings. These embodiments are not limiting. In these embodiments, the same reference numerals refer to the same structures, where:

FIG. 1 is a schematic diagram illustrating an application scenario of a system for construction task assignment based on recognition of construction drawing information according to some embodiments of the present disclosure;

FIG. 2 is a flowchart of an exemplary process for construction task assignment based on recognition of construction drawing information according to some embodiments of the present disclosure;

FIG. 3A is a flowchart of an exemplary process for determining a drawing border of a construction drawing according to some embodiments of the present disclosure;

FIG. 3B is a flowchart of an exemplary process for determining a drawing border of a construction drawing according to some other embodiments of the present disclosure;

FIG. 4 is a flowchart of an exemplary process for determining a plurality of closed paths according to some embodiments of the present disclosure;

FIG. 5 is a schematic diagram illustrating exemplary determination of a plurality of closed paths according to some embodiments of the present disclosure;

FIG. 6 is a flowchart of an exemplary process for generating one or more closed path sets according to some embodiments of the present disclosure;

FIG. 7 is a schematic diagram illustrating an exemplary relationship tree configured to represent a closed path set according to some embodiments of the present disclosure;

FIG. 8 is a flowchart of an exemplary process for processing one or more closed paths at a current level according to some embodiments of the present disclosure;

FIG. 9A and FIG. 9B are schematic diagrams illustrating exemplary closed path sets according to some embodiments of the present disclosure;

FIG. 10 is a flowchart of an exemplary process for determining title block information according to some embodiments of the present disclosure;

FIG. 11 is a schematic diagram illustrating determining a content value range according to some embodiments of the present disclosure;

FIG. 12 is a flowchart of an exemplary process for determining a title block scope according to some embodiments of the present disclosure;

FIG. 13 is a schematic diagram illustrating an exemplary title block according to some embodiments of the present disclosure;

FIG. 14 is a flowchart of an exemplary process for determining a recognition result of a target object in a construction drawing according to some embodiments of the present disclosure;

FIG. 15 is a flowchart of an exemplary process for determining target spatial information according to some embodiments of the present disclosure;

FIG. 16 is a flowchart of an exemplary process for verifying target spatial information based on a target construction drawing according to some embodiments of the present disclosure;

FIG. 17 is a partial schematic diagram illustrating a drawing border region of the target construction drawing according to some embodiments of the present disclosure;

FIG. 18 is a flowchart of an exemplary process for performing construction task assignment according to some embodiments of the present disclosure;

FIG. 19 is a schematic diagram illustrating a construction floor plan of a target construction area according to some embodiments of the present disclosure;

FIG. 20 is a flowchart of an exemplary process for determining target construction workers, and a target wall surface and a construction task item assigned to each of the target construction workers in a target construction period according to some embodiments of the present disclosure;

FIG. 21 is a schematic diagram illustrating determining a distance between wall surfaces according to some embodiments of the present disclosure;

FIG. 22 is a flowchart of an exemplary process for determining target construction workers, and a target wall surface and a construction task item assigned to each of the target construction workers in a target construction period according to some other embodiments of the present disclosure;

FIG. 23 is a flowchart of an exemplary process for determining target construction workers, and a target wall surface and a construction task item assigned to each of the target construction workers in a target construction period according to some other embodiments of the present disclosure;

FIG. 24 is an exemplary module diagram illustrating a system for construction task assignment based on recognition of construction drawing information according to some embodiments of the present disclosure;

FIG. 25 is a flowchart of an exemplary process for drawing border recognition according to some embodiments of the present disclosure;

FIG. 26 is a flowchart of an exemplary process for title block information recognition according to some embodiments of the present disclosure;

FIG. 27 is a flowchart of an exemplary process for extracting spatial information of a construction drawing according to some embodiments of the present disclosure;

FIG. 28 is a flowchart of an exemplary process for wall surface task assignment according to some embodiments of the present disclosure.

### DETAILED DESCRIPTION

To more clearly illustrate the technical solutions in the embodiments of the present disclosure, the accompanying drawings required for describing the embodiments are briefly described below. Obviously, the accompanying drawings in the following description are merely some examples or embodiments of the present disclosure. For a person of ordinary skill in the art, the present disclosure may be applied to other similar scenarios based on these accompanying drawings without making creative efforts. Unless obvious from the context or otherwise indicated by the context, the same reference numerals in the drawings refer to the same structures or operations.

It should be understood that the terms “system”, “device”, “unit”, and/or “module” used herein are a method for distinguishing components, elements, parts, portions, or assemblies of different levels. However, if other terms can achieve the same purpose, the aforementioned terms may be replaced by other expressions.

As used in the present disclosure and the claims, unless the context clearly indicates an exception, the terms “a”, “an”, “one”, and/or “the” are not limited to the singular form and may include the plural form. Generally, the terms “include” and “comprise” merely indicate that the identified steps and elements are included. These steps and elements do not constitute an exclusive list, and a method or device may also include other steps or elements.

Flowcharts are used in the present disclosure to illustrate operations performed by systems according to the embodiments of the present disclosure. It should be understood that the preceding or following operations are not necessarily performed in exact sequence. On the contrary, the steps may be processed in reverse order or simultaneously. Meanwhile, other operations may be added to these processes, or one or more steps may be removed from these processes.

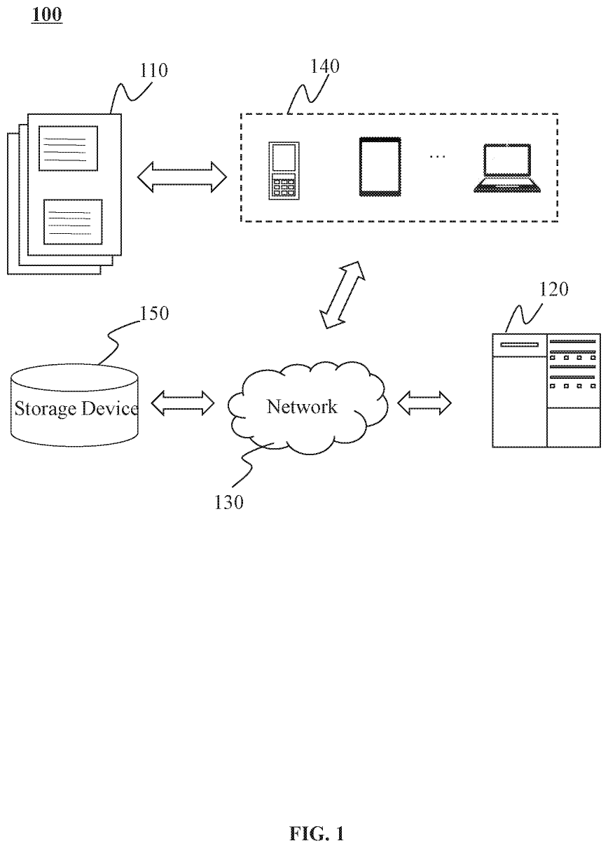

FIG. 1 is a schematic diagram illustrating an application scenario of a system for construction task assignment based on recognition of construction drawing information according to some embodiments of the present disclosure.

In some embodiments, as shown in FIG. 1, an application scenario 100 of the system for construction task assignment based on recognition of construction drawing information includes a construction drawing 110, a processor 120, a terminal device 140, a network 130, and a storage device 150, or the like.

The construction drawing 110 refers to a schematic diagram requiring recognition of construction drawing information. For example, the construction drawing 110 may be an architectural design drawing, a construction design drawing, or the like, requiring extraction of spatial information. Types of the construction drawing 110 listed above are merely by way of example, and do not constitute a limitation. The construction drawing 110 may also be any drawing requiring the extraction of the spatial information.

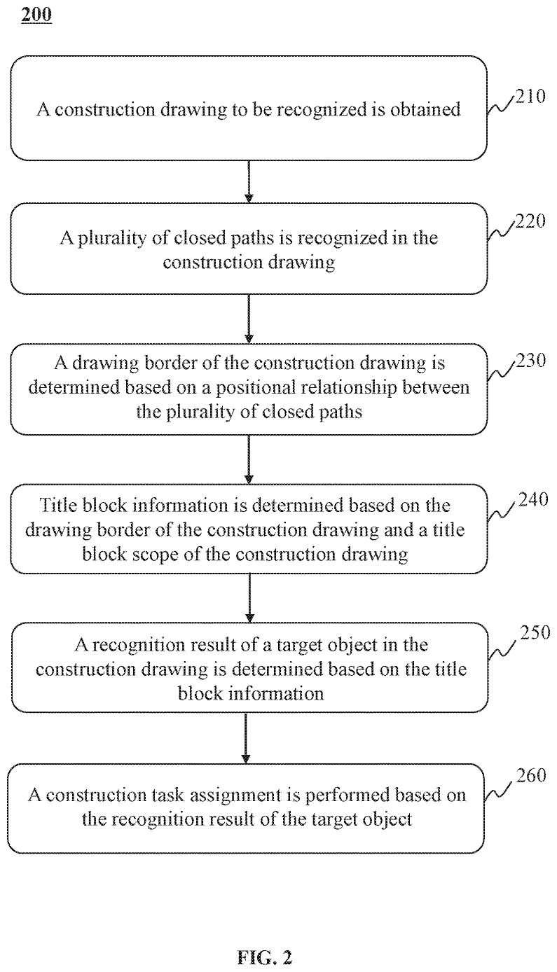

In some embodiments, the construction drawing 110 may be a physical drawing (e.g., a paper drawing). In some embodiments, the construction drawing 110 may be an electronic drawing. More descriptions regarding the construction drawing may be found elsewhere in the present disclosure (e.g., FIG. 2 and related descriptions thereof).

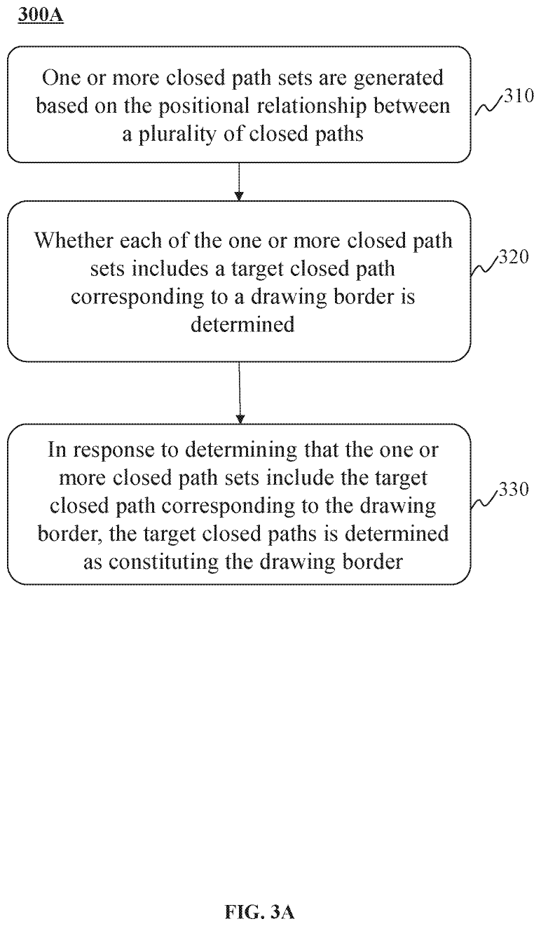

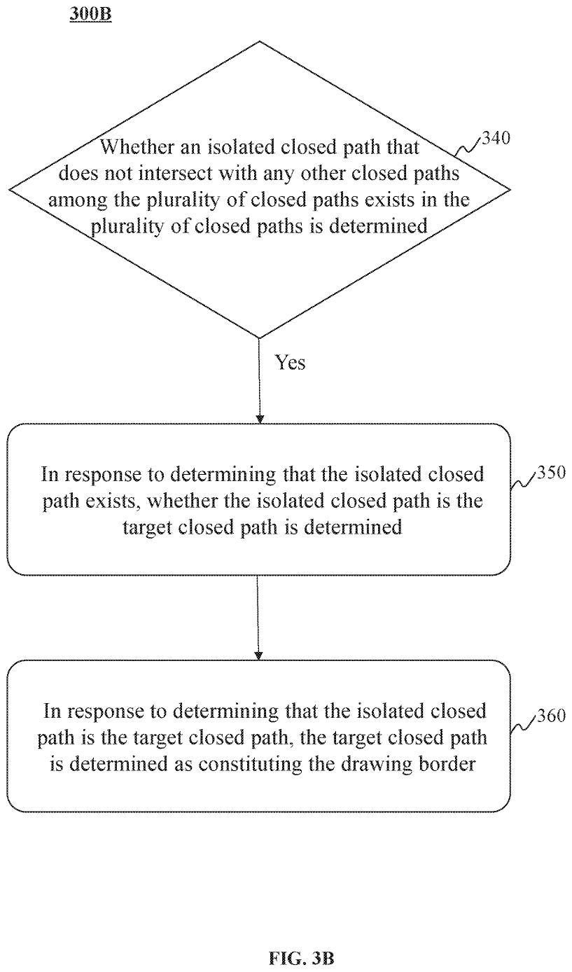

The processor 120 is configured to process information and/or data related to the system for construction task assignment based on recognition of construction drawing information, to perform one or more functions described in the present disclosure. In some embodiments, the processor 120 may obtain a construction drawing, recognize a plurality of closed paths in the construction drawing, determine a drawing border of the construction drawing based on a positional relationship between the plurality of closed paths, determine title block information based on the drawing border of the construction drawing and a title block scope of the construction drawing, determine a recognition result of a target object in the construction drawing based on the title block information, and perform a construction task assignment based on the recognition result of the target object. More descriptions regarding related contents may be found elsewhere in the present disclosure (e.g., FIG. 2, FIG. 3, and related descriptions thereof).

In some embodiments, the processor 120 may include a central processing unit (CPU), a digital signal processor (DSP), a microcontroller unit (MCU), a computer, a user console, or the like, or any combination thereof. In some embodiments, the processor 120 may include a single server or a server group. The server group may be centralized or distributed. In some embodiments, the processor 120 may be local or remote. In some embodiments, the processor 120 may be implemented on a cloud platform. Merely by way of example, the cloud platform may include a private cloud, a public cloud, a hybrid cloud, a community cloud, a distributed cloud, an internal cloud, a multi-tier cloud, or the like, or any combination thereof.

The network 130 may connect components in the application scenario 100 of the system for construction task assignment based on recognition of construction drawing information and/or connect other components outside the application scenario 100. In some embodiments, one or more components of the application scenario 100 of the system for construction task assignment based on recognition of construction drawing information (e.g., the processor 120, a terminal 140, and the storage device 150, or the like) may be connected and/or communicate with each other through the network 130. For example, the terminal 140 may send the construction drawing 110 to the processor 120 through the network 130, or the like.

The terminal 140 is configured to provide functional components for user interaction and to implement user interaction functions (e.g., to provide or display information and data to a user). The user may refer to a manager of the construction drawing 110, a finder, a user of the construction drawing 110, or the like. Merely by way of example, the terminal 140 may be one or more of a mobile device, a tablet computer, a laptop computer, a desktop computer, or the like, or other devices with an input function and/or an output function.

The storage device 150 is configured to store data, instructions, and/or any other information. In some embodiments, the storage device 150 may store data obtained from the processor 120, the terminal 140, or the like, such as the construction drawing 110, the title block information, or the like. In some embodiments, the storage device 150 may include mass storage, removable storage, volatile read-write memory, read-only memory (ROM), or the like, or any combination thereof. In some embodiments, the storage device 150 may be implemented on the cloud platform. In some embodiments, the storage device 150 may be connected to the network 130 to communicate with one or more other components (e.g., the processor 120, the terminal 140, or the like) of the application scenario 100 of the system for construction task assignment based on recognition of construction drawing information. In some embodiments, the storage device 150 may be a portion of the processor 120.

It is worth noting that the application scenario 100 of the system for construction task assignment based on recognition of construction drawing information is provided merely for illustration purposes, and is not intended to limit the scope of the present disclosure. For persons of ordinary skill in the art, various changes and modifications may be made according to the descriptions of the present disclosure. For example, the application scenario 100 of the system for construction task assignment based on recognition of construction drawing information may further include a database, an information source, or the like. As another example, the application scenario 100 of the system for construction task assignment based on recognition of construction drawing information may be implemented on other devices to implement similar or different functions. However, the changes and the modifications do not depart from the scope of the present disclosure.

FIG. 2 is a flowchart of an exemplary process for construction task assignment based on recognition of construction drawing information according to some embodiments of the present disclosure. In some embodiments, a process 200 may be performed by the processor 120. As shown in FIG. 2, the process 200 includes the following steps.

In 210, a construction drawing to be recognized is obtained.

The construction drawing to be recognized is a drawing that requires recognition of construction drawing information to perform a construction task assignment. In some embodiments, the construction drawing to be recognized may also be referred to as a target construction drawing.

The construction drawing refers to a drawing configured to guide the construction of a construction project. The construction drawing may include a graphical representation of details required for construction such as marked dimensions, orientations, and technical parameters, and a graphical representation of a target physical work to be constructed.

In some embodiments, the construction drawing may include an architectural construction drawing, a structural construction drawing, an equipment construction drawing, or the like. The architectural construction drawing represents a planned position, an external shape, an internal arrangement of each room, internal and external decoration structures, and construction requirements, etc., of a building. The structural construction drawing represents a structure type, a structural arrangement, component types, counts, sizes, and practices, etc., of a load-bearing structure of a building. The equipment construction represents an arrangement and construction requirements of equipment such as water supply and drainage, heating and ventilation, power supply and lighting, or the like of the building.

In some embodiments, the construction drawing may be a drawing drawn for an entire construction project. In some embodiments, the construction drawing may be a drawing drawn for a construction object in the construction project. The construction project is a specific project prepared for building or engineering construction. Taking a construction project to build a school as an example, the construction drawing may cover the entire school. The construction drawing may also be a drawing for a specific teaching building. The construction drawing may also be a drawing for a specific floor of the teaching building.

In some embodiments, the construction drawing may be an electronic drawing generated by CAD software, or may be a drawing converted into an electronic format through scanning or other means from a paper drawing.

The construction drawing information refers to information included on the construction drawing related to the construction project. For example, the construction drawing information may include content information such as a name, a serial number, a designer name, a design date, a unit name, or the like, or a combination thereof, of the construction drawing. As another example, the construction drawing information may include content information such as project information, building information, floor information, construction requirements of the construction project and drawing dimensions (e.g., a length, a width, an area, or the like of the construction drawing).

In some embodiments, the construction drawing to be recognized may be obtained through user upload and input. In some embodiments, the construction drawing to be recognized may further be stored in the storage device 150, and the processor 120 may obtain the construction drawing to be recognized from the storage device 150 through an interface.

In 220, a plurality of closed paths is recognized in the construction drawing.

The closed path is a continuous trajectory starting from a starting point, passing through a plurality of continuous straight-line segments, and finally returning to the starting point. The closed path is composed of a plurality of interconnected straight-line segments capable of enclosing a closed region.

In some embodiments, the processor 120 may extract a plurality of straight-line segments (hereinafter referred to as straight-lines) from the construction drawing. For example, the construction drawing is parsed through a parsing technology of CAD software to extract the plurality of straight-lines in the construction drawing. As another example, the plurality of straight-lines in the construction drawing are extracted through an image recognition algorithm (e.g., a Hough transform algorithm, an edge detection algorithm, or the like). Furthermore, the processor 120 may obtain intersection information of the plurality of straight-lines, and determine whether the plurality of straight-lines may form a closed path based on the intersection information of the plurality of straight-lines. For example, the processor 120 may determine whether endpoints of the plurality of straight-lines intersect through positions of the plurality of straight-lines, and determine whether the plurality of straight-lines form a closed path based on whether the plurality of straight-lines with continuously intersecting endpoints return to the starting point that is an endpoint of the plurality of straight-lines.

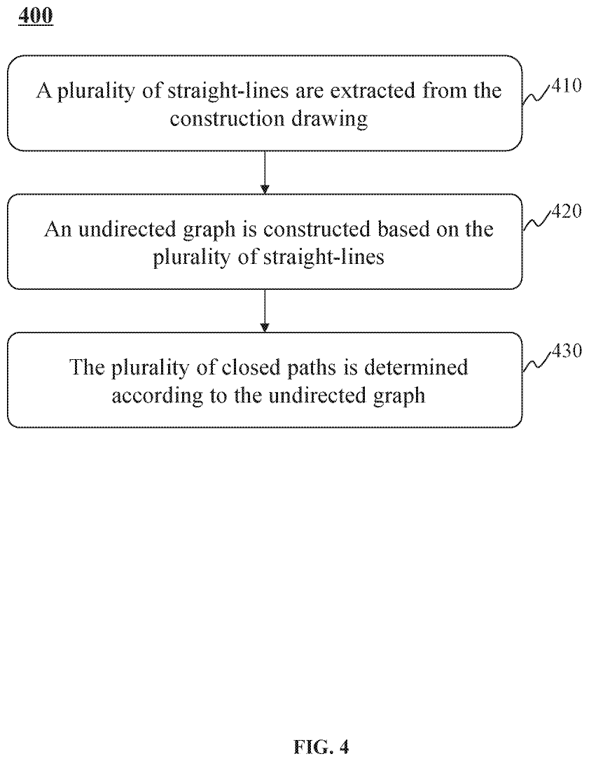

In some embodiments, the processor 120 may construct an undirected graph based on the construction drawing, and determine the plurality of closed paths according to the undirected graph. More descriptions regarding constructing an undirected graph based on a construction drawing and determining a plurality of closed paths according to the undirected graph may be found in FIG. 4 and related descriptions thereof.

In 230, a drawing border of the construction drawing is determined based on a positional relationship between the plurality of closed paths.

The drawing border is a boundary line identifying the boundary of the construction drawing.

In some embodiments, the processor 120 may recognize the drawing border in the target construction drawing. For example, the processor 120 may annotate the drawing border on the target construction drawing through an annotation tool to obtain the drawing border of the target construction drawing. An exemplary annotation tool may include various CAD annotation software, or the like.

In some embodiments, the processor 120 may generate one or more closed path sets based on the positional relationship between the plurality of closed paths. For each of the one or more closed path sets, the processor 120 may determine whether the closed path set includes a target closed path corresponding to the drawing border. In response to determining that the closed path set includes the target closed path corresponding to the drawing border, determine that the target closed path constitutes the drawing border. More descriptions regarding related contents may be found in related portions below, such as FIGS. 3A to 9B.

In 240, title block information is determined based on the drawing border of the construction drawing and a title block scope of the construction drawing.

The title block scope refers to a region occupied by a title block on the construction drawing. The title block is an element used to identify the construction drawing information.

The construction drawing includes a drawing scope and the title block scope. The drawing scope is configured to draw a specific design drawing, and the title block scope is configured to present the title block information.

The title block is a label in the construction drawing that identifies the construction drawing information. For example, the title block may include elements such as a drawing name, a drawing type, a drawing number, a designer name, a design date, a unit name, or the like on the construction drawing. Information included in the title block is referred to as the title block information.

Generally, specific construction drawing content (i.e., a drawing region) is placed at a middle position of the drawing border, and the title block is placed at an inner corner position of the drawing border.

The title block scope may be a rectangular region. The scope of the rectangular region may be defined by a maximum abscissa, a minimum abscissa, a maximum ordinate, and a minimum ordinate of each vertex of a shape enclosed by the rectangular region.

In some embodiments, the processor may obtain the title block scope based on a plurality of manners. For example, the processor may determine a regional scope of a minimum bounding rectangular region, completely including the title block (e.g., the drawing name, the drawing type, the drawing number, the designer name, the design date, the unit name, or the like) as the title block scope.

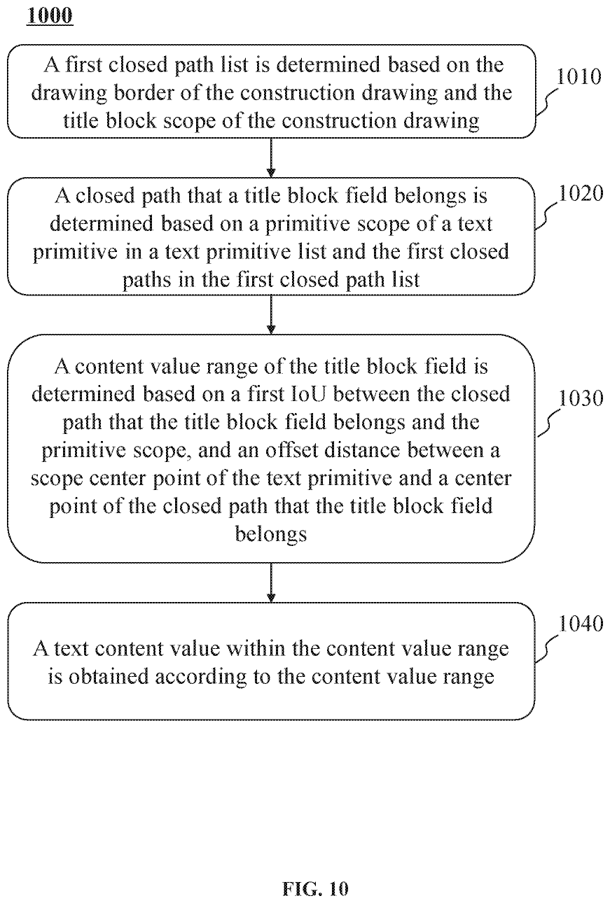

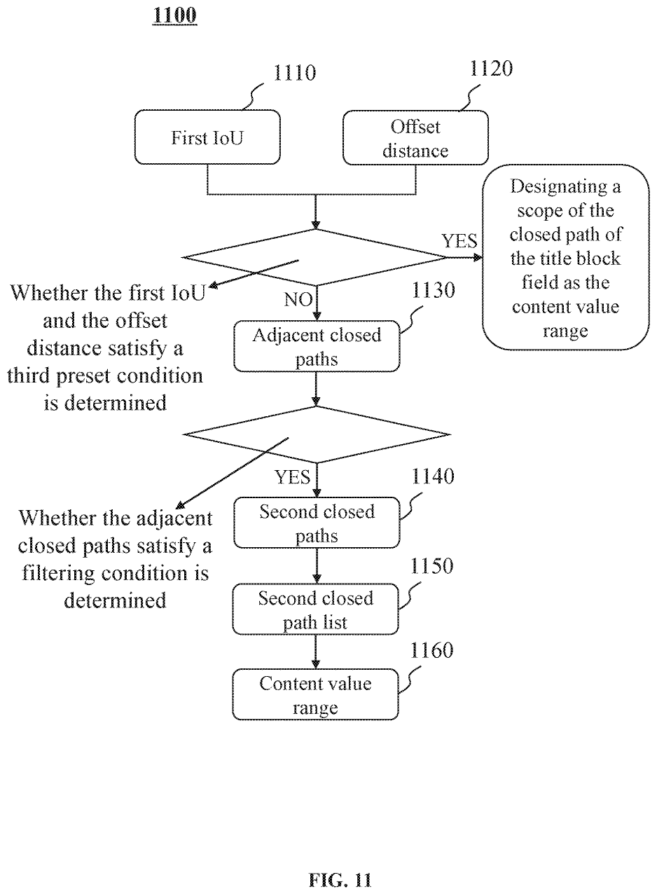

In some embodiments, the processor may further generate a primitive information list based on text primitives in the construction drawing; determine an aggregation scope list based on an aggregation relationships among text primitives in the primitive information list; and determine the title block scope based on the aggregation scope list. More descriptions regarding this embodiment for determining the title block scope may be found in FIG. 10 and related contents thereof.

In some embodiments, the processor 120 may recognize the title block scope through a technology such as image recognition (e.g., optical character recognition, OCR) to determine the title block information. As another example, the processor 120 may recognize the drawing border and the title block scope using a manner such as a machine vision technique, an image recognition technique, or the like, and extract the title block information.

In some embodiments, the processor 120 may further determine a first closed path list based on the drawing border of the construction drawing and the title block scope of the construction drawing. The processor 120 may further determine the title block information based on the first closed path list and a primitive scope of a text primitive in text primitive list. More descriptions of related content may be found in the FIGS. 10-13.

In 250, a recognition result of a target object in the construction drawing is determined based on the title block information.

The target object is an element in the construction drawing that requires recognition. In some embodiments, the target object includes spatial information in the title block and wall surfaces in the construction drawing. The recognition result of the target object includes target spatial information and the wall surfaces.

The spatial information refers to information/data that describes the spatial attribution of a building recorded in the construction drawing. For example, the spatial information may indicate a specific floor and/or a building of the building recorded in the construction drawing. The target spatial information refers to spatial information corresponding to a building and a floor extracted from the target construction drawing. For example, for initial spatial information “floor plan of buildings 1~3, floors 1~3, equipment floor and building 5, building 7, floors 2~5”, corresponding target spatial information includes: “Building 1: Floor 1, Floor 2, Floor 3, Equipment Floor”, “Building 2: Floor 1, Floor 2, Floor 3, Equipment Floor”, “Building 3: Floor 1, Floor 2, Floor 3, Equipment Floor”, “Building 5: Floor 2, Floor 3, Floor 4, Floor 5”, “Building 7: Floor 2, Floor 3, Floor 4, Floor 5”, or the like.

A wall refers to a component in a target construction region playing a structural role such as space separation, load-bearing, enclosure, thermal insulation, sound insulation, or the like. A wall surface refers to the outer surface of a wall. It should be noted that each wall has two sides, that is, each wall includes two wall surfaces, and the two wall surfaces need to be considered separately.

In some embodiments, the wall surfaces may include an inner wall surface facing an indoor area and an outer wall surface facing an outdoor area.

The inner wall surface refers to a wall surface facing the indoor area.

The outer wall surface refers to a wall surface facing the outdoor area. The outdoor area may include other spaces such as an open platform, a corridor, a terrace, an overhead, a roof, or the like.

It should be noted that when a wall is an outer wall, one side of the outer wall faces the outdoor area (i.e., the outer wall surface), and another side of the outer wall faces the indoor area (i.e., the inner wall surface). Process practices for the inner wall surface and the outer wall surface are different, which also need to be distinguished and considered during task assignment. Therefore, by recognizing the inner wall surface and the outer wall surface, the inner wall surface and the outer wall surface may be used as different basic units for task assignment.

In some embodiments, the processor 120 may directly extract the spatial information from the title block information. For example, the processor 120 may extract the spatial information through a technique such as semantic analysis on the title block information.

In some embodiments, the processor 120 may further determine initial spatial information based on the title block information; compare the initial spatial information with a preset spatial information database to obtain a comparison result; split the initial spatial information according to the comparison result to obtain spatial description information; and obtain the target spatial information of the construction drawing based on the spatial description information.

In some embodiments, the processor 120 may recognize the wall surfaces based on the title block information. For example, the processor 120 may recognize the wall surfaces based on a drawing name in the title block information. For example, in response to determining that the drawing name includes a keyword such as “indoor”, “inner wall surface”, “room XX wall surface”, or the like, the wall surfaces are the inner wall surfaces. In response to determining that the drawing name includes a keyword such as “outer wall”, “facade”, “outer wall surface”, or the like, the wall surfaces are the outer wall surfaces.

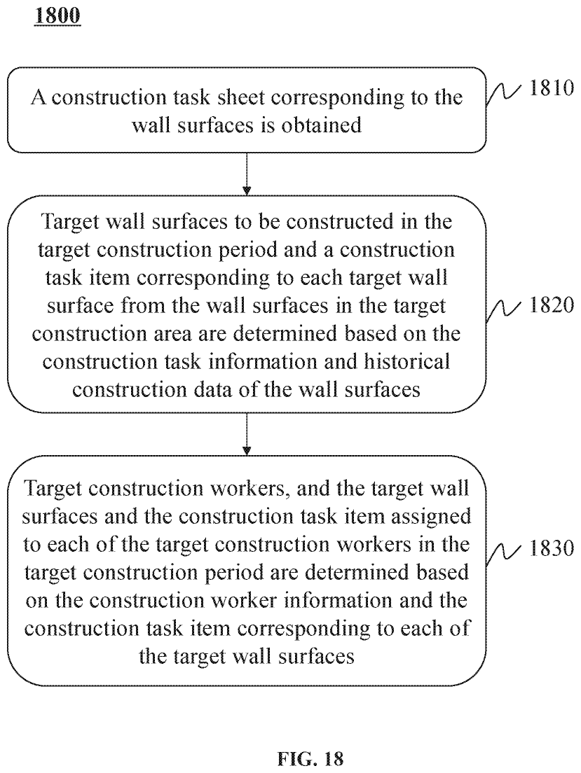

In some embodiments, the processor 120 may further determine whether the construction drawing is related to the wall surfaces based on the title block information. In response to determining that the construction drawing is related to the wall surfaces, the processor 120 may recognize a wall primitive, a door primitive, and a window primitive in the construction drawing, recognize a room region in the construction drawing based on the wall primitive, the door primitive, and the window primitive in the construction drawing, and determine the wall based on a boundary of the room region, and determine a wall surface facing an internal space of the room region as the inner wall surface, and a wall surface facing an external space of the room region as the outer wall surface. More descriptions regarding related contents may be found in FIGS. 18-23, or the like.

In 260, a construction task assignment is performed based on the recognition result of the target object.

The construction task refers to one or more construction task items related to wall surface task assignment within a target construction time period. It should be noted that the construction task item here is a relatively rough task item, which will not be detailed to a specific wall surface. A construction task item refers to the type of construction task. A construction task item may include a waterproofing task, a painting task, a plastering task, a tile sticking task, or the like. For example, construction task information may include a waterproofing task and a painting task of an inner wall, a painting task of an outer wall, or the like, in the target construction region.

In some embodiments, the processor 120 may determine a specific construction region requiring the construction task assignment based on the target spatial information, such as Community A, Building B, Floor C, or the like.

In some embodiments, the processor 120 may determine that a construction task requiring assignment is related to the inner wall surface facing the indoor area or the outer wall surface facing the outdoor area based on the recognition result of the wall surfaces.

In some embodiments, the processor 120 may further obtain a construction task sheet corresponding to the wall surfaces. The construction task sheet may include the construction task information and construction worker information corresponding to a target construction period. The processor 120 may determine target wall surfaces to be constructed in the target construction period from the wall surfaces in the target construction area and a construction task item corresponding to each of the target wall surfaces based on the construction task information and historical construction data of the wall surfaces. The processor 120 may also determine target construction workers, and the target wall surface assigned to each of the target construction workers in the target construction period, and the construction task item of each target wall surface based on the construction worker information and the construction task item corresponding to each of the target wall surfaces. More descriptions regarding related contents may be found elsewhere in the present disclosure (e.g., FIGS. 18-23, etc.).

In the method for construction task assignment based on recognition of construction drawing information described in some embodiments of the present disclosure, through efficient and accurate recognition of the construction drawing information, not only can management efficiency of the construction drawing be improved, but also accuracy of the spatial information of the construction drawing can be improved, facilitating subsequent assignment of the construction task. In addition, by determining the target construction workers, the target wall surface assigned to each target construction worker within the target construction time period, and the construction task items of the target wall surfaces, automatic assignment of the construction task item corresponding to the target wall surface is realized, the assignment efficiency is improved, an assignment unit is detailed to the specific wall surface, and the inner wall surface and the outer wall surface are distinguished, making the construction task assignment more accurate.

FIG. 3A is a flowchart of an exemplary process for determining a drawing border of a construction drawing according to some embodiments of the present disclosure. In some embodiments, the process 300A may be performed by the processor 120. As shown in FIG. 3A, the process 300A includes the following steps.

In 310, one or more closed path sets are generated based on the positional relationship between a plurality of closed paths.

The positional relationship between the plurality of closed paths refers to the intersection relationship among the regions enclosed by the plurality of closed paths. For example, the intersection relationship may include non-intersection, intersection, inclusion, vertex intersection, straight-line intersection (or tangency), or the like. The inclusion may also be regarded as a special intersection.

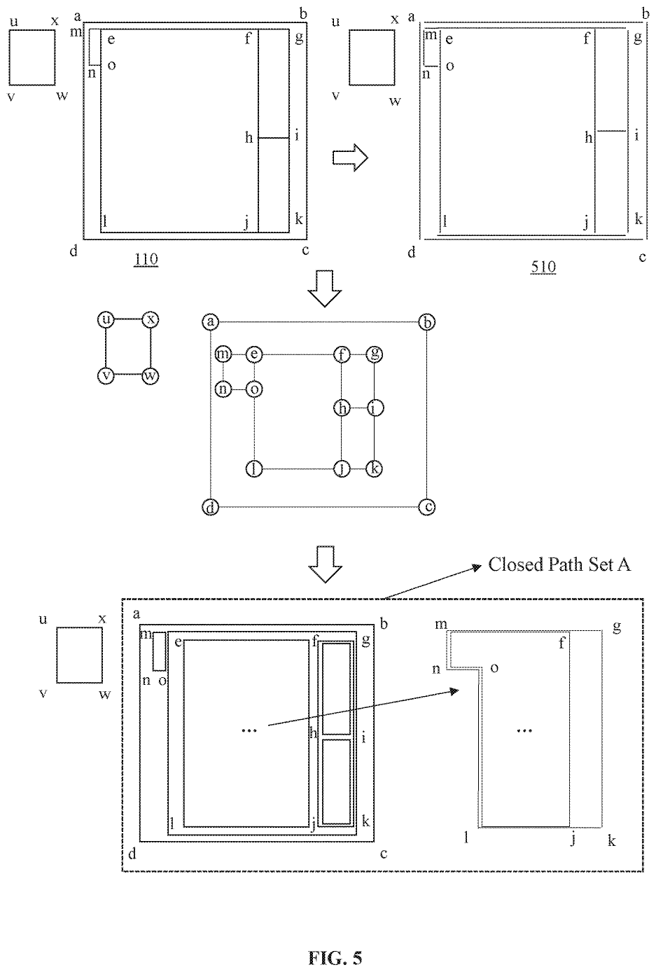

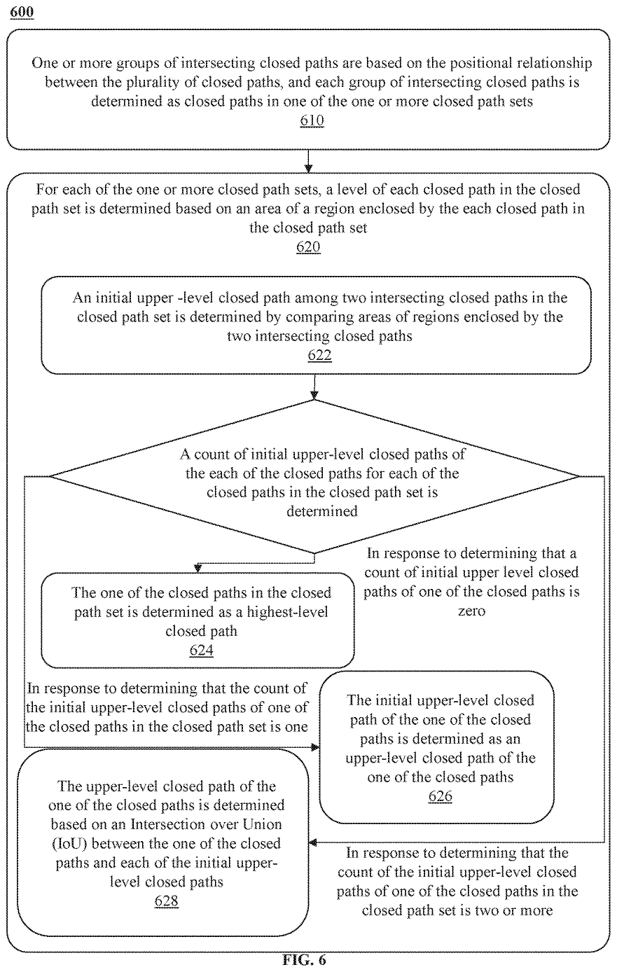

A closed path set refers to a set generated after classifying a plurality of intersecting closed paths into levels. Each of the one or more closed path sets includes one or more closed paths at one or more levels. A first area enclosed by each of closed paths at a lower level in a closed path set is included within a second area enclosed by closed paths at an upper level of the lower level in the closed path set, or intersects with the second area. For example, referring to FIG. 5, a first region enclosed by a closed path meon is included in a closed path abcd, then the closed path meon is a lower-level closed path of the closed path abcd, that is, the closed path abcd is an upper-level closed path of the closed path meon. More descriptions regarding generating the one or more closed path sets may be found elsewhere in the present disclosure (e.g., FIG. 6 and related descriptions thereof).

In 320, whether each of the one or more closed path sets includes a target closed path corresponding to a drawing border is determined.

The drawing border refers to a rectangular border configured to define a view boundary in a construction drawing. The target closed path is configured to indicate the drawing border.

In some embodiments, the processor 120 may process closed paths in each of the one or more closed path sets starting from a closed path at a highest level, until the target closed path is found or all closed paths in the each closed path set of the one or more closed path sets are processed. Generally, the drawing border refers to a larger area border in the construction drawing, which includes other rectangular borders, so that a higher-level closed path in the closed path set is more likely to be the target closed path.

For example, in response to determining that a root node of a relationship tree corresponding to the closed path set has a child node, the relationship tree may be traversed from the root node to obtain one or more second rectangular closed paths satisfying a first preset condition.

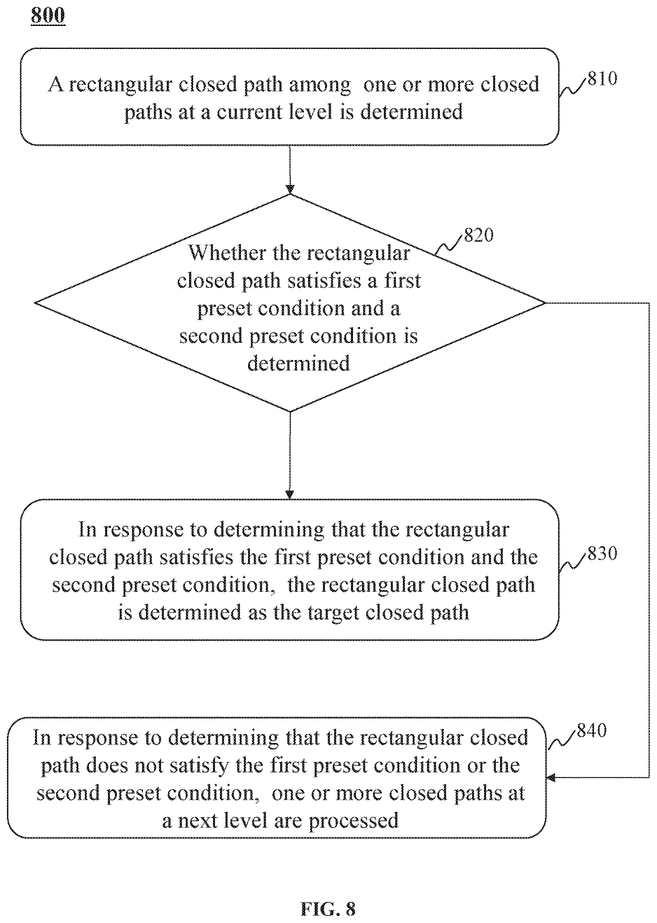

In some embodiments of the present disclosure, by preferentially processing high-level closed paths, a target closed path with a higher probability can be located more quickly, thereby improving calculation efficiency. More descriptions regarding processing the closed paths at a current level may be found elsewhere in the present disclosure (e.g., FIG. 8 and related descriptions thereof).

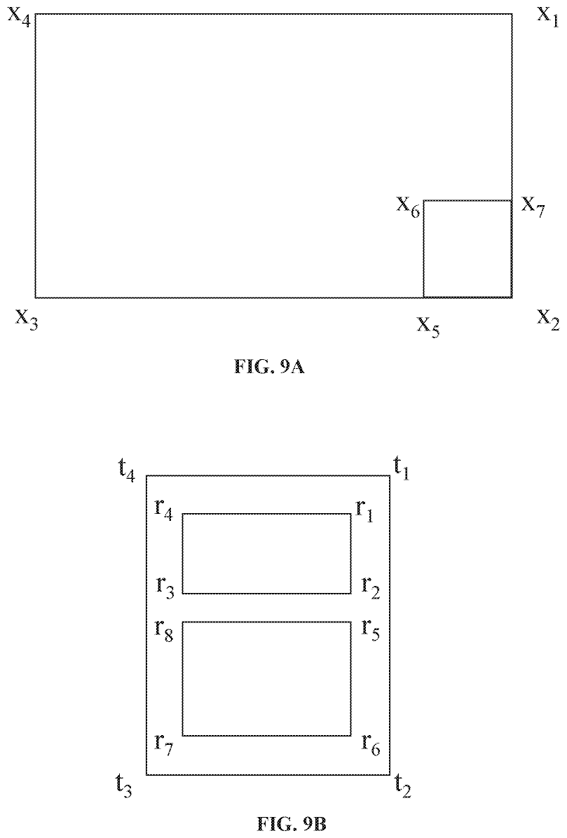

There may be a plurality of closed paths at the current level. For example, as shown in FIG. 9B, if the current level is a second level, the closed paths at the current level include two closed paths r1r2r3r4 and r5r6r7r8. The processor 120 may determine path characteristics of the closed paths at the current level. The path characteristics of a closed path may include whether the closed path at the current level is a rectangle, an Intersection over Union (IoU) between the closed path at the current level and a lower-level closed path of the closed path at the current level, whether the closed path at the current level includes a lower-level closed path passing through a vertex of the closed path at the current level, an area of a region enclosed by the closed path at the current level, or the like. More descriptions regarding the IoU between the closed path at the current level and the lower-level closed path of the closed path at the current level, and whether the closed path at the current level includes the lower-level closed path passing through the vertex of the closed path at the current level may be found in related descriptions of whether the rectangular closed path satisfies the first preset condition in 820.

In some embodiments, the processor 120 may sort the closed paths at the current level based on the path characteristics of the closed paths at the current level. For example, a closed path at the current level having a lower-level closed path is prioritized in sorting. As another example, among a plurality of closed paths at the current level having lower-level closed paths, a closed path including a lower-level closed path passing through a vertex of the closed path is prioritized; among a plurality of closed paths at the current level including lower-level closed paths passing through vertices of the plurality of closed paths at the current level, a closed path having a larger IoU with a lower-level closed path of the closed path is prioritized in sorting. As a further example, among a plurality of closed paths at the current level having no lower-level closed paths, a closed path enclosing a region with a larger area is prioritized. For example, neither the closed path r₁r₂r₃r₄ nor the closed path r₅r₆r₇r₈ has a lower-level closed path, so the closed path r₁r₂r₃r₄ enclosing a region with a larger area is prioritized in sorting.

In some embodiments, the processor 120 may sequentially process the sorted closed paths until the target closed path is found or all the closed paths at the current level are processed. More descriptions regarding the processing of the closed paths at the current level may be found elsewhere in the present disclosure (e.g., FIG. 8 and related descriptions thereof).

In some embodiments of the present disclosure, by sorting the closed paths at the same level, it ensures that a target closed path with a higher probability may be quickly located, thereby improving processing efficiency.

In some embodiments, the processor 120 may filter one of the one or more closed path sets, and then process the filtered closed path set.

In some embodiments, closed paths in the one of the one or more closed path sets may be filtered to obtain the filtered closed path set. The filtered closed path set includes rectangular closed paths that satisfy a first preset condition and a second preset condition. The first preset condition is related to a positional relationship between a closed path and a lower-level closed path of the closed path, and the second preset condition is related to one or more characteristics of the drawing border. For example, more descriptions regarding the first preset condition and the second preset condition may be found elsewhere in the present disclosure (e.g., FIG. 8 and related descriptions thereof). In some embodiments, the highest-level closed path in the filtered closed path set is designated as the target closed path.

In 330, in response to determining that the one or more closed path sets include the target closed path corresponding to the drawing border, the target closed paths is determined as constituting the drawing border.

In some embodiments, in response to determining that a closed path set includes the target closed path corresponding to the drawing border, the processor 120 may determine that the target closed path constitutes the drawing border. For example, the processor 120 may determine the target closed path as the drawing border.

In some embodiments of the present disclosure, by filtering the rectangular closed paths satisfying the first preset condition and the second preset condition to directly locate the target closed path, the efficiency of determining the target closed path is improved.

In some embodiments of the present disclosure, by recognizing a plurality of closed paths in the construction drawing, grouping and classifying the plurality of closed paths into levels based on the positional relationship among the plurality of closed paths to obtain the one or more closed path sets, and determining the target closed path corresponding to the drawing border according to the one or more closed path sets, the target closed path may be determined based on the plurality of hierarchical closed paths to achieve automated processing of a complex construction drawing, thereby greatly improving speed and accuracy of drawing border recognition.

FIG. 3B is a flowchart of an exemplary process for determining a drawing border of a construction drawing according to some other embodiments of the present disclosure. In some embodiments, the process 300B may be performed by the processor 120. As shown in FIG. 3B, the process 300B includes the following steps.

In 340, whether an isolated closed path that does not intersect with any other closed paths among the plurality of closed paths exists in the plurality of closed paths is determined.

The processor 120 may designate a closed path that does not intersect with any other closed path among the plurality of closed paths as the isolated closed path based on the positional relationship among the plurality of closed paths. For example, as shown in FIG. 5, a closed path uvwx does not intersect with any other closed path, and thus may be determined as the isolated closed path.

In 350, in response to determining that the isolated closed path exists, whether the isolated closed path is the target closed path is determined.

In some embodiments, the processor 120 may determine whether the isolated closed path is a rectangular closed path that satisfies a second preset condition. The second preset condition is related to one or more characteristics of the drawing border. More descriptions regarding the second preset condition may be found elsewhere in the present disclosure (e.g., FIG. 8 and related descriptions thereof). In some embodiments, in response to determining that the isolated closed path is the rectangular closed path that satisfies the second preset condition, the processor 120 may designate the isolated closed path as the target closed path.

In 360, in response to determining that the isolated closed path is the target closed path, the target closed path is determined as constituting the drawing border.

In some embodiments, in response to determining that the isolated closed path is the target closed path, the processor 120 may determine that the isolated closed path constitutes the drawing border. For example, the processor 120 may determine the isolated closed path as the drawing border.

In some embodiments of the present disclosure, identifying and determining the isolated closed path can ensure that a potential target closed path is not missed on the one hand. On the other hand, separately determining the isolated closed path may eliminate the need to consider the positional relationship among the plurality of closed paths, thereby improving determination efficiency. At the same time, processing a relationship between other intersecting closed paths and the isolated closed path reduces the complexity of subsequent processing of closed paths at a plurality of levels, and optimizes the overall processing process.

FIG. 4 is a flowchart of an exemplary process for determining a plurality of closed paths according to some embodiments of the present disclosure. In some embodiments, step 220 may be performed according to process 400.

In 410, a plurality of straight-lines are extracted from the construction drawing.

More descriptions regarding extracting the plurality of straight-lines from the construction drawing may be found elsewhere in the present disclosure (e.g., related descriptions of 220). FIG. 5 is a schematic diagram illustrating exemplary determination of a plurality of closed paths according to some embodiments of the present disclosure. As shown in FIG. 5, the processor 120 extracts a plurality of straight-lines 510 from the construction drawing 110, including a straight-line ab, a straight-line me, a straight-line mf, a straight-line mg, a straight-line ef, a straight-line eg, a straight-line fg, etc.

In 420, an undirected graph is constructed based on the plurality of straight-lines.

The undirected graph refers to a data structure configured to represent a relationship (e.g., whether to constitute a straight-line) between objects (e.g., endpoints of the straight-lines). Vertices of the undirected graph correspond to endpoints of the plurality of straight-lines, and edges of the undirected graph correspond to the plurality of straight-lines. The undirected graph may include a vertex list configured to represent the endpoints of the plurality of straight-lines and an edge list configured to represent the plurality of straight-lines.

In some embodiments, the processor 120 may determine whether an intersection point between a straight-line and another straight-line is an endpoint of the straight-line, and in response to determining that the intersection point between the straight-line and the another straight-line is not the endpoint of the straight-line, split the straight-line into a plurality of straight-lines based on the intersection point. For example, as shown in FIG. 5, an intersection point e between the straight-line mg and the straight-line el is not an endpoint of the straight-line mg, then the straight-line mg is split into the straight-line me and the straight-line eg based on the intersection point e; an intersection point f between the straight-line eg and a straight-line fj is not an endpoint of the straight-line eg, then the straight-line eg is further split into the straight-line ef and the straight-line fg based on the intersection point f.

In some embodiments, the processor 120 may extract endpoints of all straight-lines to constitute the vertex list. For example, as shown in FIG. 5, endpoints a, b, m, e, f, g, etc., of the straight-line ab, the straight-line me, the straight-line ef, the straight-line fg, etc., may be extracted to constitute the vertex list.

In some embodiments, the processor 120 may traverse the vertex list, and find straight-lines passing through a current vertex based on intersection information of the plurality of straight-lines, to constitute the edge list. For example, as shown in FIG. 5, a traversal starts from the vertex a. Taking the vertex m as an example, the straight-line me, the straight-line mf, and the straight-line mg passing through the vertex m may be found based on the intersection information of the plurality of straight-lines to constitute a portion of the edge list.

In 430, the plurality of closed paths is determined according to the undirected graph.

In some embodiments, the processor 120 may traverse the undirected graph based on a depth-first search algorithm to obtain a plurality of initial closed paths. For any traversal, a path starting from a vertex corresponding to a current traversal, passing through a series of unrepeatedly visited vertices along the edges of the undirected graph, and finally returning to the starting vertex is an initial closed path. For example, starting from the vertex m, an initial closed path meon, an initial closed path mefhjlon, and an initial closed path mefgikjlon may be obtained; starting from a vertex n, an initial closed path nmeo, an initial closed path nmefhjlo, and an initial closed path nmefgikjlo may be obtained.

In some embodiments, the processor 120 may remove repeated closed paths from the plurality of initial closed paths to obtain the plurality of closed paths. It may be understood that traversals starting from different vertices may result in repeated initial closed paths. For example, the aforementioned initial closed path meon and the initial closed path nmeo essentially are repeated initial closed paths.

First, the processor 120 may adjust a plurality of initial closed paths passing through the same vertex to make the plurality of adjusted initial closed paths passing through the same vertex start with the same vertex, and remove repeated closed paths from the plurality of adjusted initial closed paths to obtain a plurality of intermediate closed paths. For example, the plurality of initial closed paths meon, mefhjlon, mefgikjlon, nmeo, nmefhjlo, and nmefgikjlo passing through the vertex m are adjusted to start with the vertex m to obtain a plurality of adjusted initial closed paths meon, mefhjlon, mefgikjlon, meon, mefhjlon, and mefgikjlon, and after removing the repeated closed paths therein, a plurality of intermediate closed paths meon, mefhjlon, and mefgikjlon are obtained.

Then, the processor 120 may determine whether a plurality of consecutive vertices in the plurality of intermediate closed paths are collinear, and in response to determining that the plurality of consecutive vertices are collinear, delete an intermediate vertex among the plurality of consecutive vertices. For example, taking the aforementioned intermediate closed path mefhjlon as an example, there is a collinearity of a plurality of vertices m, e, and f, and a collinearity of a plurality of vertices f, h, and j, then an intermediate vertex e and an intermediate vertex h may be deleted to obtain an intermediate closed path mfjlon.

Finally, the plurality of intermediate closed paths may be adjusted again to make the plurality of intermediate closed paths start with the same vertex, and repeated intermediate closed paths from a plurality of adjusted intermediate closed paths may be removed to obtain the plurality of closed paths. To avoid overlapping, FIG. 5 merely illustrates a portion of closed paths, and a portion of the closed paths therein is placed in the right position of the original position for description.

In some embodiments of the present disclosure, by extracting the plurality of straight-lines from the construction drawing and constructing the undirected graph, the plurality of closed paths may be efficiently and accurately determined, thereby improving the accuracy and efficiency of drawing border recognition.

FIG. 6 is a flowchart of an exemplary process for generating one or more closed path sets according to some embodiments of the present disclosure. In some embodiments, step 310 may be performed according to process 600.

In 610, one or more groups of intersecting closed paths are based on the positional relationship between the plurality of closed paths, and each group of intersecting closed paths is determined as closed paths in one of the one or more closed path sets.

Any one closed path in each group of intersecting closed paths intersects with at least one other closed path in the group of intersecting closed paths. In some embodiments, the processor 120 may determine whether regions enclosed by any two intersecting closed paths intersect; and in response to determining that the regions enclosed by the any two intersecting closed paths intersect, classify the any two intersecting closed paths into the same group of closed paths.

For example, as shown in FIG. 5, a plurality of closed paths in a dashed box may be a group of intersecting closed paths, and the plurality of closed paths in the dashed box are closed paths included in a closed path set A.

In 620, for each of the one or more closed path sets, a level of each closed path in the closed path set is determined based on an area of a region enclosed by the each closed path in the closed path set. In some embodiments, step 620 may include the following sub-steps:

In sub-step 622, an initial upper-level closed path among two intersecting closed paths in the closed path set is determined by comparing areas of regions enclosed by the two intersecting closed paths. For example, taking the aforementioned closed path set A as an example, an area of a region enclosed by a closed path abcd is greater than an area of a region enclosed by an intersecting closed path mfjlon of the closed path abcd, then the closed path abcd is an initial upper-level closed path of the closed path mfjlon.

For each of the closed paths in the closed path set, the processor 120 may determine a count of initial upper-level closed paths of the each of the closed paths.

In sub-step 624, in response to determining that a count of initial upper level closed paths of one of the closed paths is zero, the one of the closed paths in the closed path set is determined as a highest-level closed path.

For example, the count of initial upper-level closed paths of the closed path abcd in the aforementioned closed path set A is zero, then the closed path abcd is determined as the highest-level closed path.

In sub-step 626, in response to determining that the count of the initial upper-level closed paths of one of the closed paths in the closed path set is one, the initial upper-level closed path of the one of the closed paths is determined as an upper-level closed path of the one of the closed paths.

For example, a count of initial upper-level closed paths of a closed path mgklon in the aforementioned closed path set A is one, that is, an initial upper-level closed path abcd, then the initial upper-level closed path abcd is determined as an upper-level closed path of the closed path mgklon.

In sub-step 628, in response to determining that the count of the initial upper-level closed paths of one of the closed paths in the closed path set is two or more, the upper-level closed path of the one of the closed paths is determined based on an Intersection over Union (IoU) between the one of the closed paths and each of the initial upper-level closed paths.

For example, a count of initial upper-level closed paths of a closed path efjl in the aforementioned closed path set A is 8, including initial upper-level closed paths abcd, mgklon, mgihjlon, . . . , mfjlon, then an upper-level closed path of the closed path efjl is determined based on an IoU between the closed path efjl and each of the initial upper-level closed paths.

The IoU between a closed path and an initial upper-level closed path refers to a ratio of an intersection area to a union area between the closed path and the initial upper-level closed path of the closed path. In some embodiments, the processor 120 may determine an initial upper-level closed path corresponding to a maximum value among a plurality of IoUs between the closed path and the initial upper-level closed paths as an upper-level closed path of the closed path.

For example, IoUs between the closed path efjl and the initial upper-level closed paths abcd, mgklon, mgihjlon, . . . , mfjlon are respectively S_{efjl}/S_{abcd}, S_{efjl}/S_{mgklon}, S_{efjl}/S_{mgihjlon}, . . . , S_{efjl}/S_{egkl}, and an initial upper-level closed path mfjlon corresponding to a maximum value S_{efjl}/S_{mfjlon} may be determined as the upper-level closed path of the closed path efjl.

In some embodiments of the present disclosure, by using different determination manners for the upper-level closed path of the closed path according to the count of the initial upper-level closed paths of the closed path, corresponding upper-level closed paths may be effectively determined for different types of closed paths, thereby improving the accuracy of classifying the plurality of closed paths into levels.

In some embodiments of the present disclosure, by analyzing the positional relationship between the plurality of closed paths to determine the closed paths included in the closed path set, and comparing areas of regions enclosed by intersecting closed paths to determine levels of the plurality of closed paths in the closed path set, a hierarchical relationship between the plurality of closed paths may be analyzed more accurately, thereby facilitating subsequent hierarchical analysis of the plurality of closed paths.

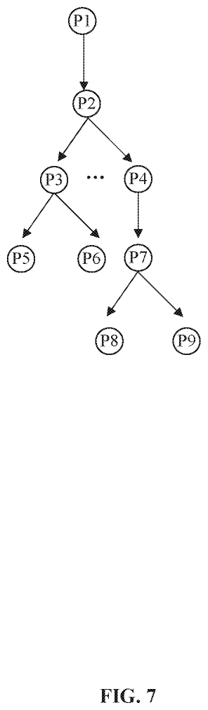

In some embodiments, the processor 120 may represent each of the one or more closed path sets with a relationship tree. The highest-level closed path in each of the one or more closed path sets may be determined as a root node of the relationship tree, and a lower-level closed path in each of the one or more closed path sets may be determined as a child node of an upper-level closed path of the lower-level closed path. FIG. 7 is a schematic diagram illustrating an exemplary relationship tree configured to represent a closed path set according to some embodiments of the present disclosure. In combination with FIG. 5 and FIG. 7, the highest-level closed path abcd in the closed path set A may be determined as a root node P1 of the relationship tree, and a lower-level closed path mgklon may be determined as a child node P2 of an upper-level closed path abcd, etc.

In some embodiments of the present disclosure, representing levels among the plurality of closed paths in the closed path set with the relationship tree can intuitively reflect a hierarchical structure among the plurality of closed paths.

FIG. 8 is a flowchart of an exemplary process for processing one or more closed paths at a current level according to some embodiments of the present disclosure.

In 810, a rectangular closed path among one or more closed paths at a current level is determined.

In some embodiments, if one of the one or more closed paths at the current level conforms to a rectangular characteristic, the one of the or more closed paths at the current level may be determined as the rectangular closed path. The rectangular characteristic refers to a characteristic configured to distinguish the rectangular closed path. For example, the rectangular characteristic may be that there are only two edges passing through any vertex in a closed path, and the included angle between the two edgesstraight-line is a right angle. As another example, the rectangular characteristic may be that the closed path is sequentially connected by four straight-lines, and the included angle between two adjacent straight-lines is a right angle.

Merely by way of example, taking the closed path set A shown in FIG. 5 as an example. For example, a closed path abcd at the current level conforms to the rectangular characteristic, and the closed path abcd is the rectangular closed path.

In 820, whether the rectangular closed path satisfies a first preset condition and a second preset condition is determined.

The first preset condition is related to a positional relationship between the rectangular closed path at the current level and one or more lower-level closed paths of the rectangular closed path at the current level. In some embodiments, the first preset condition includes that the rectangular closed path has a lower-level closed path with an IoU greater than a preset threshold, or the rectangular closed path includes a lower-level closed path passing through a vertex of the rectangular closed path.

That the rectangular closed path has the lower-level closed path with the IoU greater than the preset threshold may avoid the rectangular closed path being a meaningless closed path including the drawing border. More descriptions of the IoU may be found elsewhere in the present disclosure (e.g., related descriptions in sub-step 628). The preset threshold may be set manually, such as 0.8. For example, as shown in FIG. 5, an IoU between the rectangular closed path abcd and a lower-level closed path mgklon is greater than 0.8, then the rectangular closed path abcd satisfies the first preset condition.

That the rectangular closed path includes the lower-level closed path passing through the vertex of the rectangular closed path may correspond to a scenario where the lower-level closed path is a title block information box. The vertex may be determined according to a drawing habit of the title block information of a construction drawing draftsman. For example, if the construction drawing draftsman is accustomed to drawing the title block information at a lower right of the drawing border, the vertex may be determined as a lower right point. For example, FIGS. 9A and 9B are schematic diagrams illustrating exemplary closed path sets according to some embodiments of the present disclosure. As shown in FIG. 9A, a lower-level closed path x₂x₅x₆x₇ of a rectangular closed path x₁x₂x₃x₄ passes through a lower right point x₂ of the rectangular closed path x₁x₂x₃x₄, then the rectangular closed path x₁x₂x₃x₄ satisfies the first preset condition.

As another example, as shown in FIG. 9B, IoUs between a rectangular closed path t₁t₂t₃t₄ and lower-level closed paths r₁r₂r₃r₄ and r₅r₆r₇r₈ are all less than the preset threshold 0.8, and the lower-level closed paths r₁r₂r₃r₄ and r₅r₆r₇r₈ do not pass through a vertex of the rectangular closed path t₁t₂t₃t₄, then the rectangular closed path t₁t₂t₃t₄ does not satisfy the first preset condition.

In some embodiments, for each rectangular closed path, the processor 120 may first determine whether the rectangular closed path has a lower-level closed path with an IoU greater than the preset threshold. In response to determining that the rectangular closed path has the lower-level closed path with the IoU greater than the preset threshold, the processor 120 may determine that the rectangular closed path satisfies the first preset condition and in response to determining that the rectangular closed path does not have the lower-level closed path with the IoU greater than the preset threshold, the processor 120 may continue to determine whether the rectangular closed path includes a lower-level closed path passing through the vertex of the rectangular closed path. The processor 120 may, in response to determining that the rectangular closed path includes the lower-level closed path passing through the vertex of the rectangular closed path, determine that the rectangular closed path satisfies the first preset condition. In some embodiments, for each rectangular closed path, the processor 120 may respectively determine whether the rectangular closed path has a lower-level closed path with an IoU greater than the preset threshold and whether the rectangular closed path includes a lower-level closed path passing through a vertex of the rectangular closed path, to obtain two determination results, and then determine whether the rectangular closed path satisfies the first preset condition based on the two determination results.

In some embodiments of the present disclosure, the first preset condition considers positional relationships between upper-level closed paths and lower-level closed paths in two special scenarios, thereby improving the accuracy of recognizing the target closed path.

The second preset condition is related to one or more characteristics of the drawing border. In some embodiments, the second preset condition may be that a region enclosed by the rectangular closed path includes title block information. In some embodiments, text information in the region enclosed by the rectangular closed path may be recognized through a text recognition technique, such as an optical character recognition (OCR) technique, and then whether the text information includes title block keywords (e.g., drawing name, drawing number, scale, design unit, designer, date, etc.) may be retrieved, and in response to determining that the text information includes the title block keywords, it indicates that the title block information is included.

In 830, in response to determining that the rectangular closed path satisfies the first preset condition and the second preset condition, the rectangular closed path is determined as the target closed path.

For example, the rectangular closed path abcd shown in FIG. 5 satisfies the first preset condition and the second preset condition, then the rectangular closed path abcd may be determined as the target closed path.

In 840, in response to determining that the rectangular closed path does not satisfy the first preset condition or the second preset condition, one or more closed paths at a next level are processed.

For example, the rectangular closed path t₁t₂t₃t₄ shown in FIG. 9B does not satisfy the first preset condition, then lower-level closed paths r₁r₂r₃r₄ and r₅r₆r₇r₈ of the next level may be processed respectively.

In some embodiments of the present disclosure, by first verifying whether a closed path is a rectangular closed path, and then verifying whether the rectangular closed path satisfies the first preset condition related to the positional relationship with a lower-level closed path of the closed path, and the second preset condition related to one or more characteristics of the drawing border, on one hand, it ensures that an ultimately determined target closed path corresponds to the drawing border through a plurality of verifications; on the other hand, a step-by-step verification manner may quickly exclude a closed path that does not satisfy conditions and avoid unnecessary calculations, thereby improving the accuracy and the efficiency of recognizing the target closed path.

It should be noted that the above descriptions are provided for an illustrative purpose only, and are not intended to limit the scope of the present disclosure. For those skilled in the art, a plurality of variations and modifications may be made under the guidance of the present disclosure. Characteristics, structures, processes, and other characteristics of the exemplary embodiments described in the present disclosure may be combined in various ways to obtain additional and/or alternative exemplary embodiments. However, these variations and modifications do not depart from the scope of the present disclosure.

Beneficial effects that can be brought about by the process for determining the drawing border described in the embodiments of the present disclosure include, but are not limited to: (1) recognizing a plurality of closed paths in the construction drawing, grouping and classifying the plurality of closed paths into levels based on the positional relationship between the plurality of closed paths to obtain the one or more closed path sets, and determining the target closed path corresponding to the drawing border according to the one or more closed path sets, can determine the target closed path based on the plurality of hierarchical closed paths to achieve automated processing of a complex construction drawing, thereby greatly improving speed and accuracy of drawing border recognition; (2) by analyzing the positional relationship between the plurality of closed paths to determine the closed paths included in the closed path set, and comparing areas of regions enclosed by arbitrary two intersecting closed paths to determine levels of a plurality of closed paths in the closed path set, a hierarchical relationship between the plurality of closed paths can be analyzed more accurately, thereby facilitating subsequent hierarchical analysis of the plurality of closed paths; (3) by using different determination manners for an upper-level closed path of a closed path according to a count of initial upper-level closed paths of the closed path, corresponding upper-level closed paths can be effectively determined for different types of closed paths, thereby improving accuracy of classifying the plurality of closed paths into levels; (4) by preferentially processing high-level closed paths, a target closed path with a higher probability can be located more quickly, thereby improving calculation efficiency. In addition, by first verifying whether a closed path is a rectangular closed path, and then verifying whether the rectangular closed path satisfies the first preset condition related to the positional relationship with a lower-level closed path of the closed path, and the second preset condition related to one or more characteristics of the drawing border, on one hand, it can ensure that an ultimately determined target closed path corresponds to the drawing border through a plurality of verifications; on the other hand, a step-by-step verification manner can quickly exclude a closed path that does not satisfy conditions and avoid unnecessary calculations, thereby improving accuracy and efficiency of recognizing the target closed path; (5) filtering rectangular closed paths satisfying the first preset condition and the second preset condition, thereby directly locating the target closed path, can improve the efficiency of determining the target closed path; (6) identifying and determining the isolated closed path can ensure that a potential target closed path is not missed on one hand; on the other hand, separately determining the isolated closed path can eliminate a need to consider the positional relationship between the plurality of closed paths, thereby improving the determination efficiency. At the same time, processing a relationship between other intersecting closed paths and the isolated closed path can reduce the complexity of subsequent processing of closed paths at a plurality of levels, and optimize the overall processing process.

FIG. 10 is a flowchart of an exemplary process for determining title block information according to some embodiments of the present disclosure. In some embodiments, the process 1000 may be performed by the processor 120.

In 1010, a first closed path list is determined based on the drawing border of the construction drawing and the title block scope of the construction drawing.

The drawing border refers to a wireframe configured to define a drawing region on the construction drawing in engineering drawing, usually drawn with thick solid lines. The drawing border may be configured to indicate a drawing scope of the construction drawing.

The first closed path list is composed of a plurality of first closed paths. In some embodiments, the first closed path list includes all first closed paths that do not contain any other closed paths.

A first closed path refers to a closed path that does not contain other closed paths in the title block scope. The first closed path is a minimum rectangular border in the title block scope.

The closed path refers to a path connecting a starting point and an ending point. The path may be a line segment in the construction drawing. The closed path may constitute a closed figure. For example, for a title block in a table form, the title block includes a plurality of closed rectangular grids, and a minimum rectangular grid that does not contain other rectangular grids is a first closed path.

In some embodiments, the processor may determine the first closed paths based on a plurality of manners, and further determine the first closed path list. For example, the processor may determine the one or more first closed paths in a plurality of title block scopes in the drawing border through image recognition (e.g., connected domain analysis, Hough transform, etc.), and generate the first closed path list based on one or more first closed paths.

In some embodiments, the processor may determine straight-line segments where the drawing border intersects with the title block scope, construct an undirected graph based on the straight-line segments and an intersection condition between the drawing border and the title block scope, traverse the undirected graph to determine a plurality of closed paths, and determine the first closed path list based on inclusion relationships between the plurality of closed paths.

In some embodiments, line segments in the construction drawing may include graphic outline line segments, annotation line segments, dimension line segments, etc.

In some embodiments, the processor may determine straight-line segments where the construction drawing intersects the title block scope using a computer recognition algorithm (e.g., a line intersection analysis).

The undirected graph refers to a mathematical structure figure composed of vertices and edges. The vertices of the undirected graph are intersection points of straight-line segments straight-line, and the edges of the undirected graph are straight-line segments straight-line. When straight-line segment endpoints corresponding to two intersection points belong to two endpoints of one straight-line segment, the straight-line segment constitutes an edge. The edges of the undirected graph have no direction.

In some embodiments, the processor may construct the undirected graph through a plurality of manners. For example, the processor may determine straight-line segments where the construction drawing intersects with the title block scope through a computer recognition algorithm, taking intersection points formed by intersecting the straight-line segments as vertices of the undirected graph, determine whether any two vertices of the vertices are two endpoints of a same straight-line segment based on the plurality of vertices, and in response to determining that the any two vertices are the two endpoints of the same straight-line segment, connect the two vertices to form an edge of the undirected graph, so as to construct the undirected graph.

The closed path refers to a path connecting a starting point and an ending point, forming a closed figure. In some embodiments, there may be an inclusion or being included relationship among a plurality of closed paths.

In some embodiments, the processor may determine a closed path that does not contain other closed paths (i.e., a minimum closed path) as a first closed path, and construct the first closed path list based on the first closed path.

In some embodiments of the present disclosure, determining the first closed path list based on the undirected graph helps accurately identify closed paths that do not contain other closed paths, thereby making the first closed path list more accurate and complete.

In 1020, a closed path that a title block field belongs is determined based on a primitive scope of a text primitive in a text primitive list and the first closed paths in the first closed path list.

The text primitive list refers to a list composed of text primitives in the construction drawing.

A text primitive refers to an entity of text in the construction drawing. The text primitive may include text information (e.g., drawing name, drawing number). In some embodiments, the text primitive may also include other information of the text information, such as a position point (e.g., a coordinate point (50,120)), scope information (e.g., [xₘᵢₙ=50, yₘᵢₙ=100, xₘₐₓ=150, yₘₐₓ=120], xₘᵢₙ and xₘₐₓ are respectively a minimum abscissa and a maximum abscissa of each vertex of a rectangular border where the text primitive is located (i.e., a scope of the text primitive), and yₘᵢₙ and yₘₐₓ are respectively a minimum ordinate and a maximum ordinate of each vertex of the rectangular border where the text primitive is located), etc.

In some embodiments, the processor may obtain the text primitives in the construction drawing through a computer recognition algorithm. The computer recognition algorithm may include image recognition, OCR recognition, etc.

In some embodiments, the processor may obtain the text primitive list from user input.

In some embodiments, the processor may determine text primitives included in the construction drawing, and further determine the text primitive list. For example, the processor may cluster the text primitives determined from the construction drawing, and determine text primitives belonging to the same clustering category as the same text primitive in the text primitive list. For example, texts “drawing name”, “drawing title”, “drawing name”, “drawing title”, etc., are clustered into the same clustering category, and determined as the same text primitive in the text primitive list.

The processor may determine the text primitives from the construction drawing through a plurality of ways. In some embodiments, the processor may obtain primitives within a drawing border scope based on a parsing technology. A plurality of types of primitives may be included in the drawing border scope. The processor may further determine the text primitives from the plurality of types of primitives.

The parsing technique refers to a technique for parsing the construction drawing. The parsing technique may include a geometric parsing technique, a text parsing technique, a layer parsing technique, an attribute parsing technique, etc.

A primitive refers to a basic element in the construction drawing. Primitives include a plurality of types such as text primitives, straight-line segments, polylines, etc. A polyline may be split into a plurality of straight-line segments. For example, a polyline may be a closed rectangle formed by combining a plurality of straight-line segments, or a broken line formed by connecting a plurality of straight-line segments, etc.

In some embodiments, the processor may determine the text primitives from the plurality of types of primitives based on a computer recognition technique, etc.

In some embodiments, the processor may further generate a primitive information list based on the text primitives in the construction drawing, and generate the text primitive list based on the primitive information list and a common text information table.

The primitive information list includes one or more text primitives.

In some embodiments, the processor may fill all text primitives recognized from the construction drawing into the primitive information list one by one.

In some embodiments, the common text information list includes a plurality of pieces of common text information.

A piece of common text information refers to a common text expression of texts corresponding to a title block field or a title block field value in different construction drawings. For example, a title block field “drawing name” is generally “drawing title” in a construction drawing of design institute A, and is generally “drawing name” in a construction drawing of design institute B, then both “drawing title” and “drawing name” are common text information of the title block field “drawing name”. The title block field value refers to the content value of the title block field. The title block field refers to a field configured to indicate an attribute of the title block. For example, the title block field may include a field such as drawing name, drawing number, draftsman of the title block, etc. The title block field value may include a content value corresponding to the drawing name, a content value corresponding to the drawing number, a content value corresponding to the draftsman, etc.

In some embodiments, the common text information list may be constructed by a technician based on experience. In some embodiments, the processor may construct the common text information list based on historical data. For example, the processor may count construction drawings of different design institutes, determine text content with a higher occurrence count (e.g., exceeding a certain threshold) therein as the common text information, and fill the common text information into the common text information list.

In some embodiments, the common text information list includes a plurality of pieces of common text information (i.e., texts of text primitives).

In some embodiments, the processor may obtain title block information and common text information, and determine a common text information table based on the title block information and the common text information.

In some embodiments, the title block information includes a title block field and a title block field value.

In some embodiments, the processor may determine the common text information table based on the title block information, the common text information, and a corresponding relationship between the title block information and the common text information. For example, the processor determines common text information of each title block information in historical construction drawings based on the historical data. For each title block information, the processor may determine one or more historical construction drawings corresponding to the title block information. Each of the historical construction drawings may include common text information corresponding to the title block information. The title block information and common text information in one or more corresponding historical construction drawings are constructed as a record, and the common text information table is constructed based on a plurality of records.

In some embodiments, the processor may generate the text primitive list through a plurality of ways. For example, the processor may traverse the primitive information list, and determine whether a text primitive in the primitive information list is included in the common text information table (i.e., the text primitive has at least one field in the common text information table). If the text primitive in the primitive information list is included in the common text information table, the processor records a title block field corresponding to the text primitive, and adds the title block field into the text primitive list; if the text primitive in the primitive information list is not included in the common text information table, the processor continues to traverse a next text primitive in the primitive information list.

In some embodiments of the present disclosure, generating the text primitive list based on the primitive information list and the common text information table helps generate the text primitive list more accurately and reduces errors caused by manual generation.

The primitive scope refers to a circumscribed rectangle including a primitive. For example, a primitive scope of a text primitive may be a rectangular region composed of a maximum ordinate, a minimum ordinate, a maximum abscissa, and a minimum abscissa of a circumscribed rectangle of the text primitive. As another example, for a straight-line segment, a primitive scope of the straight-line segment may be the coordinates of endpoints of the straight-line segment and a connection line between the two endpoints.

The closed path that the title block field belongs refers to a closed path that completely includes a primitive scope of a text primitive of the title block field and does not contain any other closed paths.

In some embodiments, for a primitive scope of any text primitive in the text primitive list, the processor may determine an inclusion relationship between the primitive scope and each closed path that does not contain any other closed paths, and determine a closed path that does not contain any other closed paths and completely includes the primitive scope as a closed path of a title block field corresponding to the text primitive.

In 1030, a content value range of the title block field is determined based on a first IoU between the closed path that the title block field belongs and the primitive scope, and an offset distance between a scope center point of the text primitive and a center point of the closed path that the title block field belongs. The closed path that the title block field belongs may also be referred to as the closed path of title block field.

The first IoU is an index configured to measure the degree of overlap between the closed path of the title block field and the primitive scope of a text primitive corresponding to the title block field. The first IoU may be represented by a numerical value. A larger value of the first IoU indicates a larger degree of overlap between the closed path of the title block field and the primitive scope of the text primitive corresponding to the title block field.

In some embodiments, the processor may determine an overlapping region between the closed path of the title block field and the primitive scope of the text primitive corresponding to the title block field, and determine the first IoU based on the overlapping region and the closed path of the title block field. For example, the processor may determine an area of an overlapping region between the primitive scope of the text primitive and the closed path of the title block field, and determine a ratio of the area of the overlapping region to an enclosed area corresponding to the closed path of the title block field as the first IoU.

The scope center point of the text primitive refers to the center point of the primitive scope of the text primitive.

In some embodiments, the processor may determine the scope center point based on a geometric center point of the primitive scope of the text primitive. For example, if the primitive scope of the text primitive is a rectangular region, the processor may determine a geometric center point of the rectangular region as the scope center point.

The offset distance refers to a distance between the scope center point of the text primitive and the center point of a region enclosed by the closed path of the title block field in a target direction. The target direction may be a horizontal axis direction or a vertical axis direction of the construction drawing, which may be set according to actual needs.

In some embodiments, the processor may determine a relative distance between the scope center point of the text primitive and the center point of the region enclosed by the closed path of the title block field in the target direction, and further determine the offset distance.

The content value range refers to a primitive scope of a text primitive of a title block field value corresponding to the title block field.

In some embodiments, the processor may determine the content value range of the title block field based on the first IoU between the closed path of the title block field and the primitive scope, and the offset distance between the scope center point of the text primitive and the center point of the closed path of the title block field.

More descriptions regarding how to determine the content value range may be found elsewhere in the present disclosure (e.g., FIG. 11 and related descriptions thereof).

In 1040, a text content value within the content value range is obtained according to the content value range.

The text content value refers to texts within the content value range. For example, for a cell B of a content value range A, if “strong current design instruction” is filled in the cell B, then “strong current design instruction” is a text content value of the content value range A.

In some embodiments, the processor may obtain the text content value within the content value range based on a computer recognition algorithm. The computer recognition algorithm may include image recognition, OCR recognition, etc.

In some embodiments of the present disclosure, determining the first closed path based on the title block scope, determining the closed path of the title block field, and determining the content value range based on an IoU between the closed path of the title block field and a primitive scope of a text primitive and an offset distance between a scope center point of the text primitive and a center point of the closed path of the title block field, so as to extract the text content value, is beneficial to accurately determine scopes of title block fields in construction drawings with different standards of different design institutes, thereby improving accuracy of recognizing the text content value.

FIG. 11 is a schematic diagram illustrating determining a content value range according to some embodiments of the present disclosure. In some embodiments, a process 1100 may be performed by the processor 120.

As shown in FIG. 11, in some embodiments, the processor may determine the content value range based on a first Intersection over Union (IoU) 1110 between a closed path of a title block field and a primitive scope of a text primitive corresponding to the title block field, and an offset distance 1120 between a scope center point of the text primitive corresponding to the title block field and a center point of the closed path of the title block field, and the closed path of the title block field.

As shown in FIG. 11, in some embodiments, the processor may determine whether the first IoU 1110 and the offset distance 1120 satisfy a third preset condition, and in response to determining that the first IoU 1110 and the offset distance 1120 satisfy the third preset condition, designate a scope of the closed path of the title block field as the content value range.

In some embodiments, the third preset condition may include that a weighted sum of the first IoU and the offset distance is greater than a preset threshold. Weights corresponding to the first IoU and the offset distance and the preset threshold may be set by the processor based on a default setting or by a technician based on experience.

In some embodiments, the third preset condition may further include that the first IoU is less than or equal to a first threshold, and a ratio of the offset distance to a length of the closed path of the title block field in a target direction is greater than a second threshold. The length in the target direction refers to a projection length of the closed path of the title block field in the target direction.

The first threshold refers to a threshold related to the first IoU. For example, the first threshold may be any value between 0.1 and 0.6. As another example, the first threshold may be any value between 0.2 and 0.5. As a further example, the first threshold may be any value between 0.25 and 0.45. When the first IoU is less than or equal to the first threshold, a degree of overlap between the closed path of the title block field and the primitive scope is relatively small.

In some embodiments, the first threshold may be a system default value, an empirical value, an artificially preset value, or the like, or any combination thereof, which may be set according to actual needs.

The second threshold refers to a threshold related to the offset distance. For example, the second threshold may be any value between 0.1 and 0.7. As another example, the second threshold may be any value between 0.2 and 0.6. As a further example, the second threshold may be any value between 0.25 and 0.55. When the ratio of the offset distance to the length of the closed path of the title block field in the target direction is greater than the second threshold, the text primitive corresponding to the title block field and the closed path of the title block field are in the same closed path.

In some embodiments, the second threshold may be a system default value, an empirical value, an artificially preset value, or the like, or any combination thereof, which may be set according to actual needs.

In some embodiments of the present disclosure, determining the third preset condition through the first threshold and the second threshold is beneficial to reduce erroneous recognition of the content value range, improve the recognition efficiency of the content value range, and reduce redundant calculations.

The scope of the closed path of the title block field refers to a region enclosed by straight-line segments constituting the closed path of the title block field.

In some embodiments of the present disclosure, designating the scope of the closed path of the title block field as the content value range based on determining whether the first IoU and the offset distance satisfy the third preset condition is beneficial to accurately determine a content value range of a title block field in construction drawings with different standards of different design institutes, thereby improving accuracy of recognizing a text content value.

Referring to FIG. 11, in some embodiments, the processor may, further in response to the first IoU 1110 and the offset distance 1120 not satisfying the third preset condition, determine adjacent closed paths 1130 each of which shares the same vertex with the closed path of the title block field, determine adjacent closed paths satisfying a filtering condition as second closed paths 1140 defining a second closed path list 1150, and determine a content value range 1160 based on the second closed path list 1150.

In some embodiments, the first IoU and the offset distance not satisfy the third preset condition includes that the first IoU is not less than or equal to the first threshold, and/or the ratio of the offset distance to the length of the closed path of the title block field in the target direction is not greater than the second threshold.

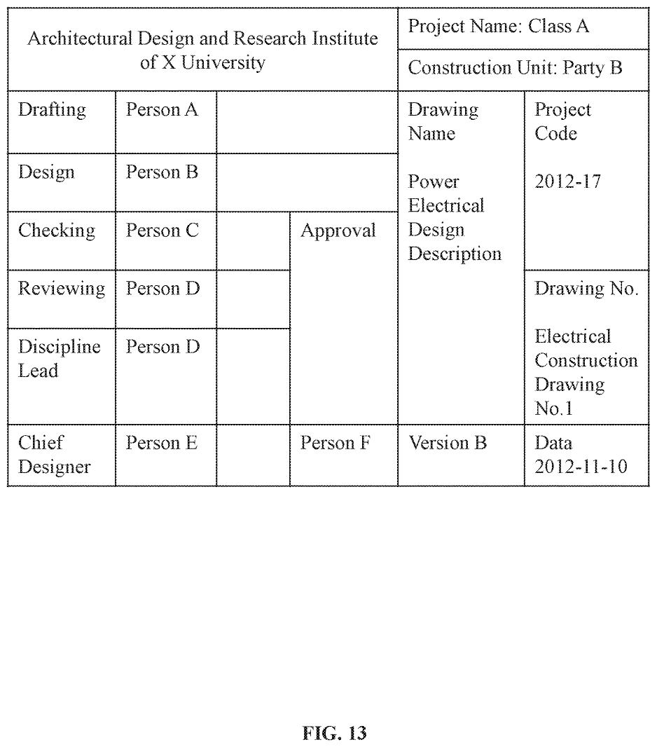

An adjacent closed path refer to a closed path that shares the same vertex with the closed path of the title block field. For example, FIG. 13 is a schematic diagram illustrating an exemplary title block according to some embodiments of the present disclosure. As shown in FIG. 13, a cell where “Drafting” is located is a closed path of a title block field “Drafting”, and adjacent closed paths of the closed path of the title block field may include closed paths where text primitives “Architectural Design and Research Institute of X University”, “Person A”, “Design”, and “Person B” are located.

In some embodiments, the first IoU is less than or equal to the first threshold, and the ratio of the offset distance to the length of the closed path of the title block field in the target direction is greater than the second threshold, then the first IoU and the offset distance satisfy the third preset condition. For example, as shown in FIG. 13, taking a title block field “Project Name” as an example, a first IoU between a scope of “Project Name” (i.e., a primitive scope of a text primitive corresponding to a text “Project Name”) and a closed path of a title block field of “Project Name” is between 0.1 and 0.5, and a projected distance between a center point of the primitive scope of the title block field “Project Name” and a center point of the closed path of the title block field in a target direction (i.e., a horizontal direction in the figure) is greater than 0.1 to 0.7 times a projection length of the closed path of the title block field in the horizontal direction, then it is considered that the first IoU and the offset distance between the title block field “Project Name” and the closed path of the title block field satisfy the third preset condition. Then it is considered that a content value “Class A” of the field and the text primitive “Project Name” are in a same closed path, then the scope of the closed path of the title block field is a range of a title block field content value, the text content value may be determined, that is, “Class A”.

In some embodiments, the first IoU is not less than or equal to the first threshold, and/or the ratio of the offset distance to the length of the closed path of the title block field in the target direction is not greater than the second threshold, then the first IoU and/or the offset distance do not satisfy the third preset condition. For example, as shown in FIG. 13, taking a title block field “Drafting” as an example, a projected distance between a center point of a primitive scope of “Drafting” (i.e., a primitive scope of a text primitive corresponding to a text “Drafting”) and a center point of a corresponding closed path of the title block field in a target direction (i.e., a horizontal direction in the figure) is greater than 0.7 times a projection length of the closed path of the title block field in the horizontal direction, it is considered that the title block field “Drafting” does not satisfy the third preset condition, and adjacent closed paths each of which shares the same vertex with the closed path of the title block field of “Drafting” are further determined.

In some embodiments, the processor may determine the adjacent closed paths through a plurality of methods. For example, the processor may traverse an undirected graph to determine the adjacent closed paths, each of which shares the same vertex with the closed path of the title block field.

The second closed path list refers to a list including the second closed paths. A second closed path refers to an adjacent closed path that is not occupied by any title block field in the construction drawing or not occupied by a text primitive corresponding to a title block field value. In some embodiments, the second closed path list may be empty.

In some embodiments, the filtering condition includes that the second closed path is not occupied by any title block field in the construction drawing or not occupied by a text primitive corresponding to a title block field value. For example, if among adjacent closed paths of the closed path of the title block field, there is an adjacent closed path that is neither determined as a closed path of a title block field nor determined as a closed path of a text primitive corresponding to a title block field value, then the adjacent closed path may be designated as the second closed path. As shown in FIG. 13, among adjacent closed paths “Person A”, “Design”, “Architectural Design and Research Institute of X University”, and “Person B” each of which shares the same vertex with the closed path of the title block field “Drafting”, closed paths already occupied by the title block field, such as “Architectural Design and Research Institute of X University” and “Design”, are excluded; then closed paths already occupied by content values of other fields, such as a closed path occupied by a content value “Person B” of a title block “Design”, are excluded, and a closed path to which “Person A” belongs is designated as the second closed path.

In some embodiments, the processor may determine the content value range based on a count of second closed paths in the second closed path list.

In some embodiments, the processor may determine a path count in the second closed path list. In response to the path count in the second closed path list being 0, the processor may determine the closed path of the title block field as the content value range. In response to the path count in the second closed path list being greater than 0, the processor may determine an aggregation scope of each of the second closed paths in the second closed path list and the scope of the closed path corresponding to the title block field, and determine a second IoU between each aggregation scope and the title block scope. In response to a count of the second closed paths whose second IoUs satisfy a fourth preset condition being less than a preset count, the processor may designate the second closed paths whose second IoUs satisfy the fourth preset condition as the content value range. In response to the count of the second closed paths whose second IoUs satisfy the fourth preset condition being not less than the preset count, the processor may determine a target distance between a center point of each of the second closed paths and the center point of the closed path corresponding to the title block field in a preset direction, and designate the second closed path whose center point has the target distance in the preset direction from the center point of the closed path of the title block field satisfy a fifth preset condition as the content value range.

The path count refers to a count of the second closed paths in the second closed path list.

The aggregation scope may be a union scope of the second closed path and the scope of the closed path of the title block field.

The second IoU refers to an intersection ratio between the aggregation scope and the title block scope. The second IoU may be represented by a numerical value. A larger second IoU indicates a larger intersection between the second closed path and the title block scope. In some embodiments, the processor may determine a ratio between an area of the aggregation scope and an area of the title block scope as the second IoU.

In some embodiments, the fourth preset condition includes that the second IoU is less than a fifth threshold. The fifth threshold may be represented by a numerical value. For example, the fifth threshold may be any value between 0.2 and 0.5.

In some embodiments, the fourth preset condition includes that the second IoU is minimum.

In some embodiments, the fourth preset condition may be a system default value, an empirical value, an artificially preset value, or the like, or any combination thereof, which may be set according to actual needs.

The preset count may be expressed by a numerical value. In some embodiments, the preset count may be a system default value, an empirical value, an artificially preset value, or the like, or any combination thereof, which may be set according to actual needs. For example, the preset count may be 1.

The target distance refers to a distance between the center point of the second closed path and the center point of the closed path of the title block field in the preset direction. In some embodiments, the preset direction may be a vertical axis direction of the construction drawing.

In some embodiments, the fifth preset condition includes that the target distance is a minimum.

In some embodiments, the processor may designate a second closed path satisfying the fifth preset condition for the target distance as the content value range. For example, the processor may determine a value between the center point of the second closed path and the center point of the closed path of the title block field in the vertical axis direction, and designate a second closed path corresponding to the center point of the second closed path with a minimum value in the vertical axis direction as the content value range.

Merely by way of example, the processor may obtain the path count of second closed paths included in the second closed path list. When determining that the path count is 0, the closed path of the title block field is determined as the content value range. That is, when there is no adjacent closed path, the content value range is determined in the closed path of the title block field. When determining that the path count of the second closed paths included in the second closed path list is not 0, that is, a plurality of adjacent closed paths are included, a second IoU between each of the second closed paths in the second closed path list and the title block scope is further determined, and a second closed path whose second IoU is less than the fifth threshold (hereinafter referred to as a target second closed path) is determined.

When a count of target second closed paths is less than the preset count, the target second closed path is determined as the content value range; when the count of the target second closed paths is not less than the preset count, a target distance between a center point of each of the target second closed paths and the center point of the closed path of the title block field in the vertical axis direction of the construction drawing is further determined, and a target second closed path with a minimum target distance is determined as the content value range.

In some embodiments of the present disclosure, determining the content value range based on the path count in the second closed path list, the fourth preset condition, and the preset count is beneficial to dynamically adjust a strategy for recognizing the content value range and adapt to drawing structures of different construction drawings of different design institutes, thereby determining the content value range more accurately and improving recognition accuracy of the content value range.

In some embodiments of the present disclosure, determining the adjacent closed paths based on the first IoU, the offset distance, and the third preset condition, so as to generate the second closed path list and determine the content value range, may automatically adjust a recognition step from analyzing the closed path of the title block field to analyzing the adjacent closed paths, which is beneficial to improve fault tolerance capability of recognizing the content value range.

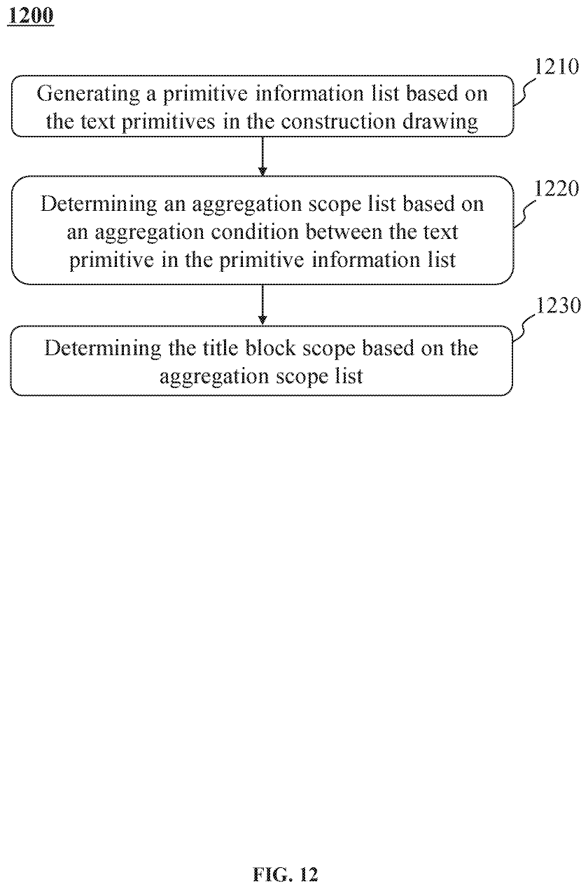

FIG. 12 is a flowchart of an exemplary process for determining a title block scope according to some embodiments of the present disclosure.

In some embodiments, the process 1200 may be performed by the processor 120. As shown in FIG. 12, the process 1200 includes the following steps.

In 1210, a primitive information list is generated based on the text primitives in the construction drawing.

More descriptions regarding generating the primitive information list based on the text primitives may be found elsewhere in the present disclosure (e.g., related descriptions of FIG. 10).

In 1220, an aggregation scope list is determined based on an aggregation condition between the text primitives in the primitive information list.

The aggregation condition refers to an overall overlapping condition between the text primitives. For example, the aggregation condition between two text primitives may include overlapping, partial overlapping, inclusion, partial inclusion, non-overlapping, etc.

In some embodiments, the processor may determine the aggregation condition of the text primitives based on an Intersection over Union (IoU) between the text primitives. The IoU refers to the ratio of an intersection to a union between primitive scopes of a plurality of text primitives. For example, the processor may determine an IoU between primitive scopes of any two text primitives among the plurality of text primitives, and determine the aggregation condition by determining whether the IoU is within a threshold range. The threshold range may include a plurality of sub-threshold ranges, and different sub-threshold ranges correspond to different aggregation conditions. When an IoU of two text primitives is within a certain sub-threshold range, an aggregation condition corresponding to the sub-threshold range is an aggregation condition of primitive scopes of the two text primitives. In some embodiments, a corresponding relationship between different sub-threshold ranges and different aggregation conditions may be manually preset and determined.

The aggregation scope list refers to a list including one or more aggregation scopes. In some embodiments, an aggregation scope may include a primitive scope of a single text primitive, a union between primitive scopes of a plurality of text primitives, etc. In some embodiments, the aggregation scope list may be empty, and the aggregation scope list does not contain a primitive scope of any text primitive.

In some embodiments, the processor may determine the aggregation scope list based on the primitive scopes of the text primitives and a drawing border scope. More descriptions regarding how to determine the aggregation scope list may be found in related descriptions below.

In 1230, the title block scope is determined based on the aggregation scope list.

In some embodiments, the processor may determine the title block scope based on an occurrence count of different title block fields in the aggregation scope list. For example, the processor may determine an aggregation scope corresponding to a title block field with the highest occurrence count as the title block scope.

For example, the processor may determine an intersection between another primitive scope and an initial primitive scope based on an initial primitive scope at four corner positions of the construction drawing (e.g., a primitive scope at a lower left corner or a primitive scope at a lower right corner, etc.), and in response to determining that there is an intersection between the another primitive scope and the initial primitive scope, obtain a union between the another primitive scope and the initial primitive scope to obtain a first aggregation scope, determine an intersection between the first aggregation scope and a next another primitive scope, in response to determining that there is an intersection, obtain a union between the first aggregation scope and the next another primitive scope to obtain a second primitive scope, and so on, until a last primitive scope is merged into an n-th aggregation scope. The processor may construct the aggregation scope list based on the above first aggregation scope to the n-th aggregation scope, and determine an aggregation scope including a largest count of title block fields in the aggregation scope list as the title block scope.

In some embodiments, for each of the text primitives in the primitive information list, the processor may further determine a first IoU between the primitive scope of the text primitive and a drawing border scope of a drawing border. In response to the first IoU being greater than a third threshold, the processor may delete the text primitive from the primitive information list. In response to the first IoU being less than or equal to the third threshold: in response to the aggregation scope list being empty, the processor may fill the primitive scope of the text primitive into the aggregation scope list, or in response to the aggregation scope list being non-empty, the processor may determine a union of each aggregation scope in the aggregation scope list and the primitive scope of the text primitive, and determine a second IoU between the union of each aggregation scope in the aggregation scope list and the primitive scope of the text primitive and the drawing border. In response to the second IoU between the union of an aggregation scope in the aggregation scope list and the primitive scope of the text primitive and the drawing border being greater than a fourth threshold, the processor may fill the primitive scope of the text primitive into the aggregation scope list; in response to the second IoU between the union of an aggregation scope in the aggregation scope list and the primitive scope of the text primitive and the drawing border being less than or equal to the fourth threshold, replace the aggregation scope with the union of each aggregation scope in the aggregation scope list and the primitive scope of the text primitive. The processor may determine the title block scope based on an occurrence count of a title block field in at least one aggregation scope in the aggregation scope list.

The first IoU refers to an IoU between the primitive scope of the text primitive and the drawing border scope. The first IoU may be represented by a numerical value. A larger numerical value indicates a larger degree of overlap between the primitive scope and the drawing border scope.

In some embodiments, the processor may determine the first IoU based on the sizes of an intersection and a union between the primitive scope of the text primitive and the drawing border scope.

The third threshold refers to a threshold related to the first IoU. For example, the third threshold may be any value between 0.1 and 0.2.

In some embodiments, the third threshold may be a system default value, an empirical value, an artificially preset value, or the like, or any combination thereof, which may be set according to actual needs.

The second IoU refers to an IoU between the union of the primitive scope of the text primitive and an aggregation scope and the drawing border scope. The second IoU may be represented by a numerical value. A larger numerical value indicates a larger degree of overlap between the union and the drawing border scope.

In some embodiments, the processor may determine the second IoU based on the sizes of an intersection and a union between the union of the primitive scope of the text primitive and the aggregation scope, and the drawing border scope.

The fourth threshold refers to a threshold related to the second IoU. For example, the fourth threshold may be any value between 0.1 and 0.4.

In some embodiments, the fourth threshold may be a system default value, an empirical value, an artificially preset value, or the like, or any combination thereof, which may be set according to actual needs.

In some embodiments, the processor may determine an aggregation scope with a highest occurrence count of the title block field as the title block scope based on the occurrence count of the title block field in the at least one aggregation scope in the aggregation scope list.

Merely by way of example, for each text primitive of the text primitives in the primitive information list, the processor may determine a first IoU between the primitive scope of the text primitive and the drawing border scope of the drawing border. When the first IoU is greater than a third threshold, the processor may delete the text primitive from the primitive information list, and when the first IoU is less than or equal to the third threshold, the processor may further determine whether the aggregation scope list is empty. When the aggregation scope list is empty (that is, no aggregation scope exists in the aggregation scope list), the processor may fill the primitive scope of the text primitive into the aggregation scope list, and when the aggregation scope list is non-empty (that is, at least one aggregation scope exists in the aggregation scope list), the processor may determine a union of each aggregation scope in the aggregation scope list and the primitive scope of the text primitive, determine a second IoU between the union and the drawing border, and determine a magnitude relationship between the second IoU and a fourth threshold. When the second IoU is greater than the fourth threshold, the processor may fill the primitive scope of the text primitive into the aggregation scope list, and when the second IoU is less than or equal to the fourth threshold, the processor may replace the aggregation scope with the union. Finally, the processor may determine an occurrence count of the title block field in each aggregation scope in the aggregation scope list, and determine an aggregation scope corresponding to the title block field with a highest occurrence count of the title block field as the title block scope.

In some embodiments of the present disclosure, determining at least one aggregation scope based on the first IoU and the second IoU, and then determining the aggregation scope list based on the aggregation scope, so as to determine the title block scope, is beneficial to quickly exclude a primitive scope of a text primitive with an excessively high degree of overlap, thereby improving recognition efficiency and reducing misjudgments.

In some embodiments of the present disclosure, determining the aggregation scope list based on the aggregation condition between the text primitive in the primitive information list, and further determining the title block scope, is beneficial to more comprehensively recognize the title block field, more accurately determine the title block scope, and simplify subsequent processes of title block information extraction and parsing.

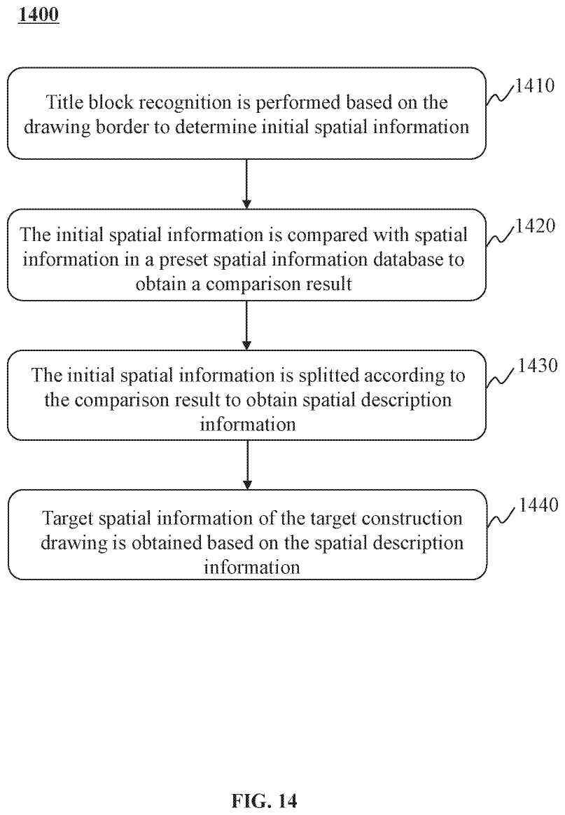

FIG. 14 is a flowchart of an exemplary process for determining a recognition result of a target object in a construction drawing according to some embodiments of the present disclosure. In some embodiments, the recognition result includes target spatial information. In some embodiments, the process 1400 may be performed by the processor 120.

In 1410, title block recognition is performed based on the drawing border to determine initial spatial information.

The initial spatial information refers to spatial information that is extracted from a target construction drawing and is unverified. In some embodiments, the processor 120 may further process the initial spatial information to obtain more accurate and complete target spatial information. Spatial information refers to information/data describing a spatial attribution of a building recorded in the construction drawing. For example, the spatial information may indicate specific floors and/or buildings of the building recorded in the construction drawing.

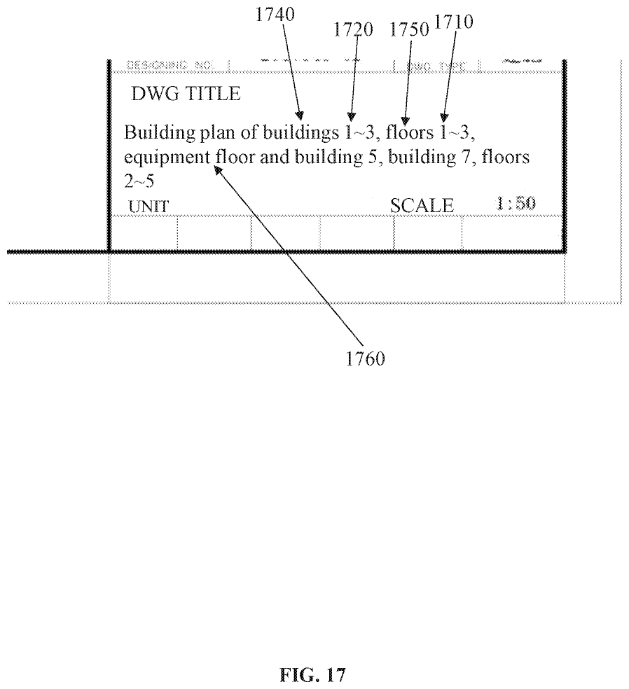

FIG. 17 is a schematic diagram illustrating a portion of a drawing border region of the target construction drawing according to some embodiments of the present disclosure.

In some embodiments, the spatial information may include information related to a building keyword, a floor keyword, a building number, a floor count, etc. The building keyword and the building number may be referred to as building information related to a building in the construction drawing; the floor keyword and the floor count may be referred to as floor information related to a floor in the construction drawing. For example, a drawing name of the target construction drawing may include the information related to the building keyword, the floor keyword, the building number, the floor count, etc.

The building keyword refers to identification information related to indicating the buildings in the target construction drawing. For example, referring to FIG. 17, a building keyword 1740 may include “Unit”, etc. In some embodiments, the building keyword may also include other identification information configured to indicate the building, such as “Building”, “Building No.” (e.g., “Building No. 1”, “Building No. 2”), etc. In some embodiments, the processor 120 may determine whether title block information is related to the building based on the building keyword. For example, when a certain piece of title block information includes a building keyword such as “Block”, “Building”, “Building No.”, etc., the processor 120 may determine that the title block information is related to the building.

The floor keyword refers to identification information related to indicating a floor in the target construction drawing. For example, referring to FIG. 17, a floor keyword 1750 may include “Layer”, etc. In some embodiments, the floor keyword may also include other identification information configured to indicate the floor, such as “Floor”, “F”, etc. In some embodiments, the processor 120 may determine whether the title block information is related to the floor based on the floor keyword. For example, when a certain piece of title block information includes a floor keyword such as “Layer”, “Floor”, “F”, etc., the processor 120 may determine that the title block information is related to a floor.

The building number refers to data/information configured to distinguish different buildings. In some embodiments, the building number includes a number, a connecting symbol, a custom buildin, etc.

The floor number refers to data/information configured to distinguish different floors. In some embodiments, the floor number includes a number, a connecting symbol, a custom floor, a prefix, a supplementary word, etc.

A number is configured to indicate a specific building and/or floor, including an Arabic numeral (e.g., 1, 2, 3, etc.), a Chinese character numeral (e.g., one, two, three, etc.), a Roman numeral, etc. As shown in FIG. 17, the numbers include a first number 1710 indicating a specific floor, a second number 1720 indicating a specific building, etc. More descriptions regarding the first number and the second number may be found elsewhere in the present disclosure (e.g., 1440 and related descriptions thereof).

The connecting symbol is configured to connect a plurality of different pieces of information. As shown in FIG. 17, a connecting symbol 1730 may connect different building numbers and/or floor counts, different numbers, etc. The connecting symbol includes a separation word (e.g., “,”, “,”, “and”, “with”, etc.) and a continuous word (e.g., “-”, “~”, “to”, “up to”, etc.). The continuous word refer to a word or symbol connecting a plurality of continuous buildings (or floors).

The custom building refer to a word indicating a non-standardized description of a building. For example, the custom building may include “basement, garage, guardhouse”, etc.

The custom floor refer to a word indicating a non-standardized description of a floor. As shown in FIG. 17, a custom floor 1760 may be an “equipment floor”. In some embodiments, the custom floor may also include a type such as “roof, machine room floor, roofing, top floor”, etc.

The prefix and the supplementary word are configured to explain and supplement some special floors. For example, prefixes such as “negative, −, B” may represent underground floors; supplementary words such as “mezzanine, half floor, M” may represent a mezzanine, etc.

In some embodiments, the processor 120 may determine the initial spatial information through a plurality of ways. For example, the processor 120 may recognize the drawing border through a technique such as image recognition (e.g., OCR) to obtain the title block information such as a drawing name of the drawing border, and extract the building keyword, the floor keyword, the building number, the floor count, etc., in the title block information as the initial spatial information. As another example, the processor 120 may perform title block recognition on the drawing border through a process such as a machine vision technique, an image recognition technique, etc., and extract the initial spatial information.

In 1420, the initial spatial information is compared with spatial information in a preset spatial information database to obtain a comparison result.

The spatial information database refers to a database system configured to store, manage, and retrieve spatial information of construction drawings.

In some embodiments, the spatial information in the spatial information database may be obtained by collecting spatial information of a plurality of existing construction drawings and performing a standardized processing.

The standardized processing refers to processing spatial information related to buildings, floors, etc., of a construction drawing based on a preset rule. An exemplary preset rule may include arranging different buildings and floors corresponding to the different buildings alternately. For example, extracted spatial information related to buildings, floors, etc., of the construction drawing is arranged according to a manner shown in formula (1):

(a×n₁+β×n₂)×n₃ (1),

where a represents a standardized expression form of building information, β represents a standardized expression form of floor information, and n₁, n₂, and n₃ respectively represent a building count, a floor count, and an occurrence count of the building information and/or the floor information. Merely by way of example, “building plan of buildings 1~3, floors 1~3, equipment floor and building 5, building 7, floors 2~5” may represent spatial information after the standardized processing.

In some embodiments, the standardized expression form of the building information may include: (number|building keyword+connecting symbol)+(number|building keyword+connecting symbol)+ . . . +(number|building keyword+connecting symbol). For example, the standardized expression form of the building information may be: Building No. 1~3, Building No. 5 and Building No. 7, Building No. 9~10. The building keyword includes custom buildings such as “basement, garage, guardhouse”, etc.

In some embodiments, the standardized expression form of the floor information may include: (number|floor keyword+connecting symbol)+(number|floor keyword+connecting symbol)+ . . . +(number|floor keyword+connecting symbol). For example, the standardized expression form of the floor information may be: floors 1~3, 5, 7, 9, and equipment floor. The floor keyword includes custom floors such as “roof, equipment floor, machine room floor, roofing, top floor”, etc.

The above descriptions of the standardized processing are merely examples, and those skilled in the art may also set other standardized processing manners according to different extraction needs for construction drawing spatial information. For example, the spatial information database may include a plurality of pieces of spatial information obtained through processing by different standardized processing manners.

In some embodiments, the processor 120 may match the initial spatial information of the target construction drawing with the spatial information in the spatial information database, and designate a matching result as the comparison result. A matching manner includes text matching, etc. For example, the processor 120 may match a building keyword, a floor keyword, a building number, and a floor count in key information of the drawing border of the target construction drawing with the spatial information in the spatial information database for comparison.

In some embodiments, a plurality of types of comparison results are obtained by comparing the initial spatial information with the spatial information in the preset spatial information database obtains. For example, when a floor keyword (including a custom floor) and a building keyword (including a custom building) in the initial spatial information successfully match a floor keyword (including a custom floor) and a building keyword (including a custom building) in the spatial database respectively, the processor 120 may determine that the initial spatial information includes spatial information related to both a floor and a building at the same time, and this result is referred to as a first comparison result; when a floor keyword (including a custom floor) in the initial spatial information successfully matches a floor keyword (including a custom floor) in the spatial database, the processor 120 may determine that the initial spatial information includes spatial information related to a floor, and this result is referred to as a second comparison result; when a floor keyword (including a custom floor) in the initial spatial information fails to match a floor keyword (including a custom floor) in the spatial database, the processor 120 may determine that the initial spatial information does not include spatial information related to floors, and further determine that the target construction drawing does not include spatial information, and this result is referred to as a third comparison result.

In some embodiments, when the comparison result satisfies the first comparison result, the processor 120 may determine the target spatial information of the target construction drawing through methods described in 1430 to 1440.

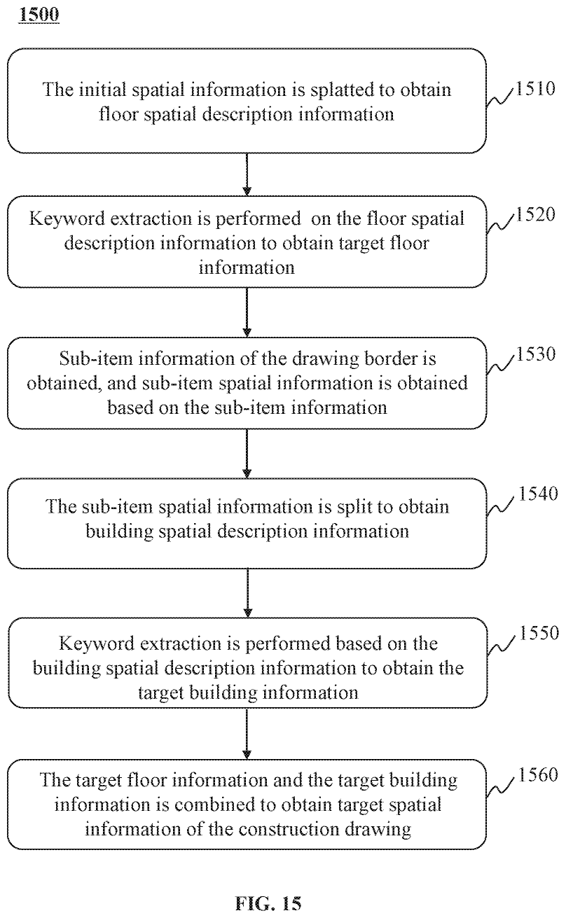

In some embodiments, when the comparison result satisfies the second comparison result, the processor 120 may determine that a drawing name of the target construction drawing includes only floor information and no building information. Target floor information in the target spatial information may be obtained from the drawing name, and target building information may be obtained from sub-item information, and the processor 120 may determine the target spatial information of the target construction drawing through methods described in process 1500. More descriptions regarding related contents may be found in related descriptions of FIG. 15.

In some embodiments, when the comparison result satisfies the third comparison result, the processor 120 may determine that the target construction drawing does not include spatial information, and end the process.

In 1430, the initial spatial information is splitted according to the comparison result to obtain spatial description information.

The spatial description information refers to data/information describing buildings, floors, etc., in the target construction drawing. In some embodiments, the spatial description information includes building spatial description information describing the buildings and floor spatial description information describing the floors.

In some embodiments, when the comparison result satisfies a fifth preset condition, the processor 120 may split the initial spatial information to obtain a plurality of spatial information combinations. Foreach of the spatial information combinations, the processor 120 may obtain the floor spatial description information and the building spatial description information based on a preset manner.

The fifth preset condition may include that the comparison result is the first comparison result. More descriptions regarding the first comparison result may be found in 1420.

A spatial information combination refers to a combination of the building spatial description information and the floor spatial description information obtained after splitting the initial spatial information. For example, the processor 120 may split initial spatial information “building plan of buildings 1~3, floors 1~3, equipment floor and building 5, building 7, floors 25” into a spatial information combination 1: “buildings 1~3, floors 1~3, equipment floor” and a spatial information combination 2: “building 5, building 7, floors 25”.

In some embodiments, if there is a floor keyword or a custom floor in front of a certain building keyword or a certain custom building, the processor 120 may take a connecting symbol connecting the building keyword or the custom building and the floor keyword or the custom floor in front of the building keyword or the custom building as a dividing point, to split the initial spatial information. Continuing to use the aforementioned initial spatial information “building plan of buildings 1~3, floors 1~3, equipment floor and building 5, building 7, floors 2~5”, wherein before a building keyword of “building 5”, a floor keyword “floor” of “floors 1~3” and a custom floor “equipment floor” are included. The processor 120 may take a connecting symbol “and” as a dividing point, to split the initial spatial information into the spatial information combination 1: “buildings 1~3, floors 1~3, equipment floor” and the spatial information combination 2: “building 5, building 7, floors 25”.

In some embodiments, the preset manner includes: extracting floor-related information from the spatial information combination to obtain the floor spatial description information; and extracting building-related information from the spatial information combination to obtain the building spatial description information.

In some embodiments, for each of the plurality of spatial information combinations, extracting the floor-related information includes deleting the building keyword and characters preceding the building keyword, and extracting the floor keyword and a floor number from remaining characters. For example, for the spatial information combination 1: “buildings 1~3, floors 1~3, equipment floor”, the processor 120 may delete the building keyword “building” and characters “1~3” preceding the building keyword, and extract the floor-related information “floors 1~3, equipment floor” as the floor spatial description information.

In some embodiments, for each of the plurality of spatial information combinations, extracting the building-related information includes deleting characters after a rightmost one of the building keyword and the custom building, and extracting the building keyword and a building number from remaining characters. For example, for the spatial information combination 1: “buildings 1~3, floors 1~3, equipment floor”, the processor 120 may delete characters “floors 1~3, equipment floor” after the rightmost of the building keyword “buildings”, and extract the building-related information “buildings 1~3” as the building spatial description information.

In 1440, target spatial information of the target construction drawing is obtained based on the spatial description information.

The target spatial information refers to spatial information corresponding to the buildings and the floors extracted from the target construction drawing. For example, for the initial spatial information “building plan of buildings 1~3, floors 1~3, equipment floor and building 5, building 7, floors 2~5”, target spatial information corresponding to the initial spatial information includes: “building 1: floor 1, floor 2, floor 3, equipment floor”, “building 2: floor 1, floor 2, floor 3, equipment floor”, “building 3: floor 1, floor 2, floor 3, equipment floor”, “building 5: floor 2, floor 3, floor 4, floor 5”, “building 7: floor 2, floor 3, floor 4, floor 5”, etc.

In some embodiments, for each of the plurality of spatial information combinations, the processor 120 may perform keyword extraction based on the floor spatial description information and the building spatial description information to obtain target floor information and target building information; and combine the target floor information and the target building information to obtain the target spatial information of the target construction drawing.

In some embodiments, the processor 120 may extract first numbers and a custom floor in the floor spatial description information, determine first floor information based on an adjacent connecting word of the first numbers, determine second floor information based on a continuity word between the first numbers, determine the target floor information based on the first floor information and the second floor information, and take the custom floor as supplementary floor information.

A first number refers to a number describing a specific floor number. The first number may include a number in one of a plurality of forms, such as an Arabic numeral (e.g., 1, 2, 3, etc.), a Chinese character numeral (e.g., one, two, three, etc.), a Roman numeral, etc.

The adjacent connecting word refers to a word immediately adjacent to a number (including the first number and second number). In some embodiments, the adjacent connecting words of the first number includes a prefix, a supplementary word, the floor keyword, etc. Taking floor spatial description information “negative floor 2”, “underground floor 1” as an example, the adjacent connecting words include “negative”, “floor”, “underground”, “layer”, etc. More descriptions regarding the prefix, the supplementary word, and the floor keyword may be found in step 1410.

The first floor information refers to floor information determined based on the first number and the adjacent connecting word of the first number.

In some embodiments, the processor 120 may process the adjacent connecting word of the first number, and substitute the first number to obtain the first floor information. An exemplary processing method includes converting the adjacent connecting word into a standardized prefix and/or a standardized supplementary word and/or a standardized floor keyword, and combining the standardized prefix and/or the standardized supplementary word and/or the standardized floor keyword with the first number to obtain the first floor information. For example, taking “negative floor 1”, “−2F”, “underground floor 1”, “basement floor 1”, etc., as examples, the processor 120 may convert adjacent connecting words such as “negative”, “−”, “underground”, “basement”, etc., representing underground into a standardized prefix “−” (or converting into prefixes in other forms according to needs), convert floor keywords such as “layer”, “floor”, “F”, etc., into a standardized floor keyword “floor”, and combine the standardized prefix “−” and the standardized floor keyword “floor” with corresponding first numbers to obtain the first floor information: “floor−1”, “floor−2”, “floor−1”, “floor−1”, etc. The standardized prefix and/or the standardized supplementary word and/or the standardized floor keyword may be preset in advance.

In some embodiments, when a first number in the floor spatial description information does not have an adjacent connecting word, the processor 120 may determine that the first floor information of the floor spatial description information is empty.

In some embodiments, the processor 120 may store the first floor information in a temporary floor database.

The second floor information refers to floor information determined based on the first numbers and a continuity word between the first numbers. More descriptions regarding the continuity word may be found in 1410.

In some embodiments, when there is no continuity word between the first numbers, the processor 120 may directly determine the first numbers and the floor keyword as the second floor information.

In some embodiments, when a continuity word exists between the first numbers, the processor 120 may fill in the remaining numbers between floor counts on both sides of the continuity word, and take the filled result and the standardized floor keyword as the second floor information. For example, taking “floors 1 to 4” as an example, there is a continuity word “to” representing a continuous condition of floors between first numbers “1” and “4”, the processor 120 may fill in numbers “2” and “3” between the first numbers “1” and “4”, and combine the filled result with a standardized floor keyword “floor” as the second floor information: “floor 1”, “floor 2”, “floor 3”, “floor 4”.

In some embodiments, the processor 120 may store the second floor information in the temporary floor database.

In some embodiments, the processor 120 may merge the first floor information and the second floor information in the temporary floor database as the target floor information.

The supplementary floor information refers to descriptions that provide additional details to the target floor information. In some embodiments, the processor 120 may directly use custom floor information as the supplementary floor information, and store the supplementary floor information in the temporary floor database.

In some embodiments, the processor 120 may further merge the supplementary floor information, the first floor information, and the second floor information as the target floor information.

In some embodiments, for each of the plurality of spatial information combinations, the processor 120 may further perform deduplication processing (i.e., removing repeated floor information) on target floor information of the spatial information combination in the temporary floor database, to improve the accuracy of target spatial information obtained subsequently.

In some embodiments, the processor 120 may extract second numbers and a custom building in the building spatial description information, determine first building information based on adjacent connecting words of the second numbers, determine second building information based on a continuity word between the second numbers, and determine the target building information based on the first building information and the second building information, and take the custom building as supplementary building information.

A second number refers to a number describing a specific building number. The second number may be represented in a plurality of forms, such as natural number (e.g., 1, 2, 3, etc.), Chinese character numeral (e.g., one, two, three, etc.), Roman numeral, etc.

In some embodiments, the adjacent connecting word of a second number includes the building keyword. Taking building spatial description information “building 3”, “blocks 1~4” as an example, the adjacent connecting word includes “building”, “block”, etc. More descriptions regarding the building keyword may be found in 220.

The first building information refers to building information determined based on the second numbers and the adjacent connecting words of the second numbers.

In some embodiments, the processor 120 may process the adjacent connecting words of the second numbers, and substitute the second numbers to obtain the first building information. An exemplary processing method includes converting each adjacent connecting word into a standardized building keyword, and combining the standardized building keyword with the second numbers to obtain the first building information. For example, taking “building 3”, “blocks 1−4”, “Building No. 7”, etc., as examples, the processor 120 may convert adjacent connecting words of different building keywords such as “building”, “block”, “Building No.”, etc., into a standardized building keyword “building” (or converting into building keywords in other forms according to needs), and combine the standardized building keyword “building” with corresponding second numbers to obtain the first building information: “building 3”, “buildings 14”, “building 7”, etc. The standardized building keyword may be preset in advance.

In some embodiments, the processor 120 may store the first building information in a temporary building database.

The second building information refers to building information determined based on the second numbers and a continuity word between the second numbers. More descriptions regarding the continuity word may be found in step 1410.

In some embodiments, when there is no continuity word between the second numbers, the processor 120 may directly determine the second numbers and the building keyword as the second building information.

In some embodiments, when a continuity word exists between the second numbers, the processor 120 may fill in remaining numbers between building numbers on both sides of the continuity word, and take the filled result and the standardized building keyword as the second building information. For example, taking “buildings 1 to 4” as an example, there is a continuity word “to” representing a continuous condition of buildings between second numbers “1” and “4”, the processor 120 may fill in numbers “2” and “3” between the second numbers “1” and “4”, and combine the filled result with a standardized building keyword “building” as the second building information: “building 1”, “building 2”, “building 3”, “building 4”.

In some embodiments, the processor 120 may store the second building information in the temporary building database.

In some embodiments, the processor 120 may merge the first building information and the second building information in the temporary building database as the target building information.

The supplementary building information refers to descriptions that provide additional details to the target building information. In some embodiments, the processor 120 may directly use the custom building information as the supplementary building information, and store the supplementary building information in the temporary building database.

In some embodiments, the processor 120 may further merge the supplementary building information, the first building information, and the second building information as the target building information.

In some embodiments, for each of the plurality of spatial information combinations, the processor 120 may further perform deduplication processing (i.e., removing repeated building information) on the target building information of the spatial information combination in the temporary building database, to improve the accuracy of target spatial information obtained subsequently.

In some embodiments, for each of the plurality of spatial information combinations, the processor 120 may combine the target floor information and the target building information in the spatial information combination to obtain the target spatial information of the spatial information combination. For example, target floor information of a certain spatial information combination includes “floor 1”, “floor 2”, and “equipment floor”, and target building information includes “building 1”, “building 2”, and “building 3”, the processor 120 may combine each of the target floor information with each of the target building information, and merge combined results of the same building to obtain target spatial information of the spatial information combination: “building 1: floor 1, floor 2, equipment floor”, “building 2: floor 1, floor 2, equipment floor”, “building 3: floor 1, floor 2, equipment floor”.

In some embodiments, for each of the plurality of spatial information combinations of the target construction drawing, the processor 120 may respectively perform the manner described in step 1440 (e.g., executing simultaneously or executing separately) to obtain target spatial information of each spatial information combination, and merge target spatial information of the the plurality of spatial information combination as the target spatial information of the target construction drawing.

In some embodiments of the present disclosure, the method for extracting spatial information from a construction drawing can intelligently and automatically recognize spatial information in the construction drawing with high accuracy and broad applicability, and can accurately recognize custom floor/building information. At the same time, under a condition that text expressions in the construction drawing are non-standardized (e.g., there are a plurality of building/floor keywords, etc.), accurate recognition can also be achieved and converted into standardized expression forms, facilitating querying and management of the spatial information of the construction drawing. In addition, spatial information implied in drawing texts without direct expression (e.g., for continuous floor information floors 1 to 4, where floors 2 and 3 are implied spatial information) can also be accurately supplemented and recognized, thereby further improving the management effects of the spatial information of the construction drawing.

FIG. 15 is a flowchart of an exemplary process for determining target spatial information according to some embodiments of the present disclosure. In some embodiments, when the comparison result satisfies a fifth preset condition, the processor 120 may perform the process 1500 to determine target spatial information of a target construction drawing. That is, the processor 120 may determine whether the comparison result satisfies the fifth preset condition after executing step 1420, and perform the process 1500 when the comparison result satisfies the fifth preset condition. The fifth preset condition includes that the comparison result satisfies a second comparison result. More descriptions regarding the second comparison result may be found elsewhere in the present disclosure (e.g., 1420 and related descriptions thereof).

In some embodiments, the process 1500 may be performed by a processor (e.g., the processor 120). As shown in FIG. 15, the process 1500 includes the following steps.

In 1510, the initial spatial information is splatted to obtain floor spatial description information.

In some embodiments, the processor 120 may split the initial spatial information through a same manner as in step 1430 to obtain the floor spatial description information. Detailed descriptions regarding related contents may be found in step 1430.

In 1520, keyword extraction is performed on the floor spatial description information to obtain target floor information.

In some embodiments, the processor 120 may perform keyword extraction on the floor spatial description information through a same manner as in step 1440 to obtain the target floor information. Detailed descriptions regarding related contents may be found in step 1440.

In 1530, sub-item information of the drawing border is obtained, and sub-item spatial information is obtained based on the sub-item information.

The sub-item information refers to a sub-item name of the construction drawing. The sub-item refers to a lower-level sub-project or sub-item in the construction drawing.

The sub-item spatial information refers to information related to a building keyword, a building number, etc., in the sub-item name.

In some embodiments, the processor 120 may determine the sub-item spatial information through the same manner as extracting the initial spatial information. For example, the processor 120 may recognize the drawing border through a technique such as image recognition (e.g., an OCR technology) to obtain the sub-item name of the drawing border, and extract a building keyword, a building number, etc., in the sub-item name as the sub-item spatial information through a manner such as regular matching. As another example, the processor 120 may perform title block recognition on the drawing border through a manner such as a machine vision technique, an image recognition technique, etc., and extract the sub-item spatial information.

In some embodiments, the processor 120 may further compare the sub-item spatial information with the spatial information in a preset spatial information database.

In some embodiments, when the comparison result is that the sub-item spatial information successfully matches a building keyword (including a custom building) in the spatial information database, it indicates that building spatial information is included in the sub-item spatial information, and the processor 120 continues to performs step 1540 to 1560 to determine the target spatial information of the target construction drawing.

In some embodiments, when the comparison result is that the sub-item spatial information fails to match the building keyword (including a custom building) in the spatial information database, it indicates that building spatial information is not included in the sub-item spatial information, and the processor 120 ends the process.

In 1540, the sub-item spatial information is split to obtain building spatial description information.

In some embodiments, the processor 120 may split the sub-item spatial information through a custom building and/or a building keyword and/or a separation word. For example, for sub-item spatial information “buildings 1-3, building 7, building 8”, the processor may split the sub-item spatial information based on a separation word “.” and a building keyword “building” to obtain building spatial information: “buildings 1-3”, “building 7”, “building 8”. More descriptions regarding the building spatial description information may be found in step 1430.

In 1550, keyword extraction is performed based on the building spatial description information to obtain the target building information.

In some embodiments, the processor 120 may perform keyword extraction on the building spatial description information based on the same manner as in step 1440 to obtain the target building information. Detailed descriptions regarding related contents may be found in step 1440.

In 1560, the target floor information and the target building information is combined to obtain target spatial information of the construction drawing.

In some embodiments, the processor 120 may combine the target floor information and the target building information based on the same manner as in 1440 to obtain target spatial information of the target construction drawing. Detailed descriptions regarding related contents may be found in 1440.

In some embodiments, to further improve the accuracy of extracted target spatial information, the processor 120 may further verify the extracted target spatial information. For example, the processor 120 may compare the extracted target spatial information with spatial information in the spatial information database. If a comparison result is consistent, it is considered that the extracted target spatial information is accurate and correct, and target spatial information corresponding to the target construction drawing (i.e., building and floor information associated with the construction drawing) is obtained; if the comparison result is inconsistent, it is considered that the target spatial information is incorrect and needs to be modified or further verified (e.g., manually verified or modified).

In some embodiments, the processor 120 may also verify target spatial information based on the target construction drawing.

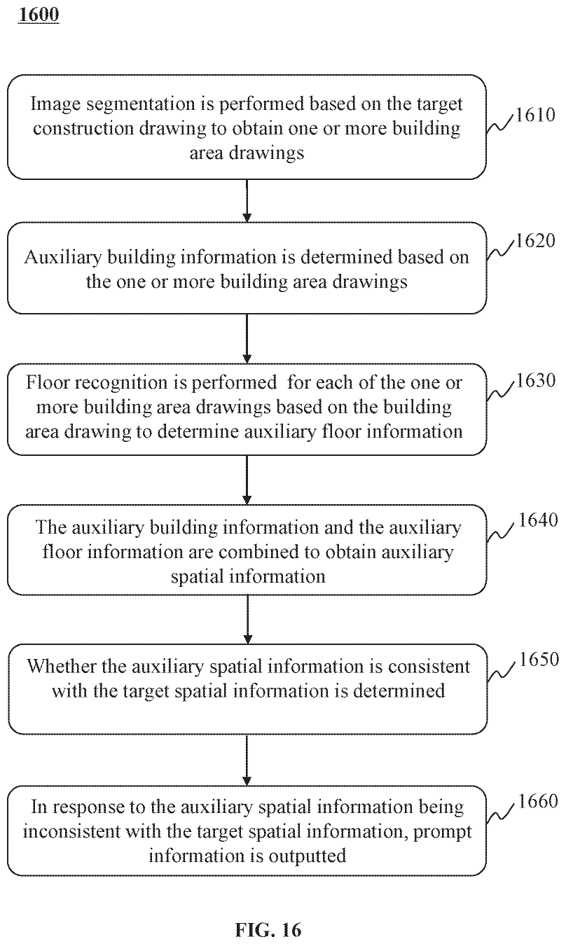

FIG. 16 is a flowchart of an exemplary process for verifying target spatial information based on a target construction drawing according to some embodiments of the present disclosure. In some embodiments, the process 1600 may be performed by a processor (e.g., the processor 120). As shown in FIG. 16, the process 1600 includes the following steps.

In 1610, image segmentation is performed based on the target construction drawing to obtain one or more building area drawings.

A building area drawing refers to a drawing obtained after segmenting different buildings in the target construction drawing into one or more individual buildings.

In some embodiments, the processor 120 may perform image segmentation on the target construction drawing based on at least one of a plurality of image segmentation techniques. Exemplary image segmentation techniques include gray threshold segmentation, region segmentation, edge segmentation, etc.

In 1620, auxiliary building information is determined based on the one or more building area drawings.

The auxiliary building information refers to building information extracted from the one or more building area drawings.

In some embodiments, the processor 120 may determine the auxiliary building information based on building information annotated in the one or more building area drawings.

In 1630, floor recognition is performed for each of the one or more building area drawings based on the building area drawing to determine auxiliary floor information.

The auxiliary floor information refers to floor information extracted from each building in the one or more building area drawings.

In some embodiments, the processor 120 may extract floor information annotated in each building area drawing through an image recognition technique (e.g., machine vision, an OCR technology, etc.), and take the extracted floor information as the auxiliary floor information.

In some embodiments, the processor 120 may further determine the auxiliary floor information through a machine learning model.

In some embodiments, the processor 120 may input the building area drawing into a convolutional neural network to obtain a convolutional feature vector, perform enhancement processing on the convolutional feature vector to obtain an enhanced feature vector, and input the enhanced feature vector into a floor recognition model to determine the auxiliary floor information.

In some embodiments, the convolutional neural network may be obtained through training by using first samples and first labels of the first samples. The first samples include a plurality of historical building area drawings, and the first labels includes manually annotated floor information of the historical building area drawings. When the training of the convolutional neural network is completed, the processor 120 may select a feature vector output by a layer preceding an output layer of the convolutional neural network as the convolutional feature vector.

In some embodiments, the processor 120 may further perform annotation information extraction based on the building area drawing to obtain drawing annotation information, perform feature extraction on the drawing annotation information to obtain an annotation feature vector, and perform fusion on the annotation feature vector and the convolutional feature vector to obtain the enhanced feature vector.

The drawing annotation information refers to floor information annotated in the building area drawing.

In some embodiments, the processor 120 may extract floor information annotated in each building area drawing using image recognition technology (e.g., machine vision, OCR, etc.), and use the extracted floor information as the drawing annotation information.

In some embodiments, the processor 120 may further obtain a preset annotation region of the target construction drawing, and extract the drawing annotation information from the preset annotation region. The preset annotation region is determined according to an annotation habit of a drafting user corresponding to the target construction drawing.

The preset annotation region refers to a preset region configured to annotate floor information in the building area drawing.

The annotation habit refers to a habit of the user annotating spatial information, such as buildings, floors, etc., when drafting a drawing. For example, the annotation habit may include annotating customary numbers (e.g., Arabic numerals, Roman numerals), an individual-floor annotation habit, a unified multi-floor annotation habit, etc. In some embodiments, the annotation habit of the user may be stored in advance in a storage device (e.g., the storage device 150) in the form of a vector, etc., and the processor 120 may obtain the annotation habit from the storage device based on a drafting user name in the title block information.

In some embodiments of the present disclosure, determining the preset annotation region of the target construction drawing according to the annotation habit of the drafting user corresponding to the target construction drawing, and extracting the drawing annotation information from the preset annotation region, may better fit drawing habits of different users when extracting the annotation information, improve accuracy of subsequently determined auxiliary floor information, and at the same time improve an intelligence degree of a target spatial information verification process.

In some embodiments, the processor 120 may further perform feature extraction on the drawing annotation information through a technique such as text structural features, grammatical features, word embedding, etc., to obtain the annotation feature vector.

In some embodiments, the processor 120 may perform fusion on the annotation feature vector and the convolutional feature vector in a plurality of ways. For example, the processor 120 may concatenate the annotation feature vector and the convolutional feature vector to obtain the enhanced feature vector. As another example, the processor 120 may compute a weighted sum of the annotation feature vector and the convolutional feature vector to obtain the enhanced feature vector, wherein the weights may be preset.

In some embodiments, by performing fusion on the annotation feature vector corresponding to the annotation information of the building area drawing and the convolutional feature vector to obtain the enhanced feature vector, the annotation information of the drawing may be integrated to improve the accuracy of the auxiliary floor information subsequently determined through the model.

The floor recognition model is a machine learning model configured to determine the auxiliary floor information in the building area drawing. In some embodiments, the floor recognition model may be a neural network model, a deep neural network model, etc.

In some embodiments, the input of the floor recognition model includes the enhanced feature vector, and the output includes the auxiliary floor information.

In some embodiments, the input of the floor recognition model further includes the annotation habit of the drafting user of the target construction drawing and an annotation parsing explanation. The annotation parsing explanation refer to an interpretation of the annotation habit of the drafting user of the target construction drawing. For example, for an annotation “floor 2”, the annotation parsing explanations include clarifying whether an annotation of the drafting user indicates “a second floor” or “a first floor and a second floor”.

In some embodiments of the present disclosure, the input of the floor recognition model further include the annotation habit of the drafting user of the target construction drawing and the annotation parsing explanation, which may improve the accuracy of the output auxiliary floor information, and at the same time make output results closer to annotation habits of different drafting users, making it more intelligent.

In some embodiments, the floor recognition model may be obtained through training by using second samples and second labels. The second samples include historical enhanced feature vectors corresponding to a plurality of historical building area drawings, and the second labels include manually annotated floor information of the historical building area drawings. When the plurality of historical building area drawings in the second samples are consistent with the plurality of historical building area drawings in the first samples, the first labels and the second labels may be the same.

In some embodiments, the convolutional neural network may be a part of the floor recognition model.

In some embodiments of the present disclosure, determining the auxiliary floor information through the machine learning model is more accurate and intelligent, which can improve the verification accuracy and verification efficiency of the target spatial information.

In 1640, the auxiliary building information and the auxiliary floor information are combined to obtain auxiliary spatial information.

The auxiliary spatial information refers to spatial information determined based on the building area drawing.

In some embodiments, the processor 120 may determine the auxiliary spatial information based on a manner similar to determining the target spatial information. For example, for each of the one or more building area drawings, the processor 120 may combine the auxiliary building information and the auxiliary floor information in the building area drawing to obtain the auxiliary spatial information of the building area drawing. For example, auxiliary floor information of a certain building area drawing includes “floor 1”, “floor 2”, and “equipment floor”, and auxiliary building information includes “building 1” and “building 2”, the processor 120 may combine each of the auxiliary floor information with each of the auxiliary building information, and merge combined results of the same building to obtain auxiliary spatial information of the building area drawing: “building 1: floor 1, floor 2, equipment floor”, “building 2: floor 1, floor 2, equipment floor”.

In some embodiments, for each of the one or more building area drawings, the processor 120 may respectively perform the manner described in steps 1620 to 1640 (e.g., performing simultaneously or separately) to obtain the auxiliary spatial information of each building area drawing, and merge the auxiliary spatial information of each building area drawing as the auxiliary spatial information of the target construction drawing.

In 1650, whether the auxiliary spatial information is consistent with the target spatial information is determined.

In some embodiments, the processor 120 may determine whether the auxiliary spatial information is consistent with the target spatial information through a plurality of ways. For example, the processor 120 may directly compare whether the auxiliary spatial information is consistent with the target spatial information. As another example, the processor 120 may determine a vector distance between the auxiliary spatial information and the target spatial information. When the vector distance is below a threshold, the auxiliary spatial information is consistent with the target spatial information; otherwise, the auxiliary spatial information is inconsistent with the target spatial information. An exemplary vector distance includes one or more of a Euclidean distance, a cosine distance, a Manhattan distance, a Chebyshev distance, etc.

In some embodiments, when the auxiliary spatial information is consistent with the target spatial information, it indicates that the target spatial information is extracted correctly, and the processor 120 ends the process.

In some embodiments, when the auxiliary spatial information is inconsistent with the target spatial information, it indicates that there may be an error in the extraction of the target spatial information, and the processor 120 performs step 1660.

In 1660, in response to the auxiliary spatial information being inconsistent with the target spatial information, prompt information is outputted.

The prompt information is configured to prompt a user to verify the target spatial information. For example, the prompt information may include a pop-up reminder, a highlight reminder, etc.

In some embodiments, the prompt information further includes a specific verification content, for example, specific buildings, floors, etc., of the target spatial information that is inconsistent with the auxiliary spatial information.

In some embodiments, the user may manually verify the target spatial information that is inconsistent with the auxiliary spatial information. In some embodiments, the processor 120 may also repeatedly perform one or more of processes 1400, 1500, and 1600 again to automatically verify the target spatial information. For example, comparing whether the target spatial information obtained after a repeated execution is consistent with the auxiliary spatial information or the target spatial information obtained before the repeated execution.

In some embodiments of the present disclosure, verifying the target spatial information based on the target construction drawing may improve recognition accuracy of the target spatial information; at the same time, when the extraction of the target spatial information is inconsistent with the auxiliary spatial information, a prompt can be timely sent to the user for further verification, further improving the recognition accuracy of the target spatial information; in addition, compared with a manner of directly comparing with spatial information in the spatial information database, the auxiliary spatial information of the target construction drawing targets a same drawing, so a comparison object is more accurate, and a comparison result can be quickly obtained.

FIG. 18 is a flowchart of an exemplary process for performing construction task assignment according to some embodiments of the present disclosure. In some embodiments, a recognition result includes wall surfaces, and the processor 120 may perform the construction task assignment based on a process shown as a process 1800. In some embodiments, the process 1800 may be performed by the processor 120.

In 1810, a construction task sheet corresponding to the wall surfaces is obtained.

In some embodiments, the recognition result includes the wall surfaces, and the processor 120 may recognize the wall surfaces in a target construction area from a construction floor plan of the target construction area.

The target construction area refers to a region requiring wall-surface task assignment. For example, the target construction area may include a plurality of floors. As another example, the target construction area may merely include one floor. As a further example, the target construction area may include a certain region in one floor.

In some embodiments, since an outdoor-facing exterior wall surface and an indoor-facing interior wall surface need to be distinguished subsequently, but a periphery of an underground region is buried in soil, and there is no distinction between the outdoor-facing exterior wall surface and the indoor-facing interior wall surface, the target construction area merely includes an above-ground region.

The construction floor plan refers to a drawing configured to guide the execution of a construction task in the target construction area. For example, the construction floor plan may be a two-dimensional drawing configured to represent the spatial layout and functional division of a building corresponding to the target construction area on a specific horizontal section plane. For example, the construction floor plan may display information such as a spatial layout, a room region, a wall structure, door and window arrangement, or the like, of the target construction area on a certain floor. The construction floor plan is a kind of construction drawing. For example, a construction drawing 110 may include the construction floor plan.

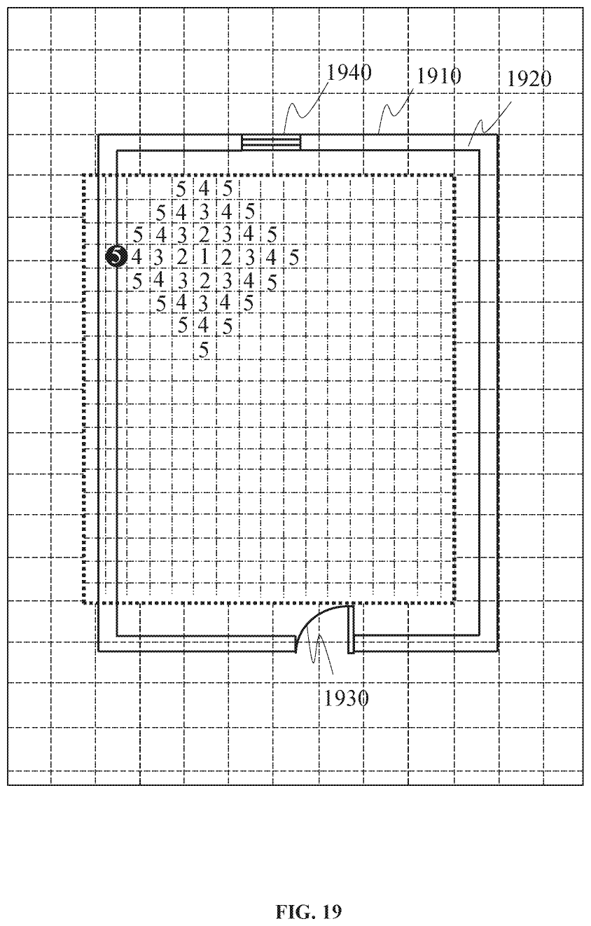

In some embodiments, the construction floor plan may include graphic primitives (e.g., a wall primitive, a door primitive, a window primitive, etc.), text primitives, or the like. A primitive refers to a basic drawing element in the construction floor plan. For example, the primitive may include, but is not limited to, a straight-line primitive, an arc primitive, a polyline primitive, a block primitive, a text primitive, or the like. Merely by way of example, as shown in FIG. 19, a room region 1910 may include a wall primitive 1920, a door primitive 1930, and a window primitive 1940.

In some embodiments, since the outdoor-facing exterior wall surface and the indoor-facing interior wall surface need to be distinguished subsequently, but a non-floor plan usually does not have a distinction between an interior wall and an exterior wall (for example, a detail drawing is merely a partial drawing, and there is no distinction between the interior wall and the exterior wall), the construction floor plan needs to be selected. In addition, since the target construction area merely includes the above-ground region, an above-ground construction floor plan needs to be selected.

A wall is a component that serves structural roles such as space separation, load-bearing, enclosure, thermal insulation, sound insulation, or the like in the target construction area. A wall surface refers to the outer surface of the wall. It should be noted that each wall has two surfaces, that is, each wall includes two wall surfaces, and the two wall surfaces need to be considered separately.

In some embodiments, the wall surfaces may include an inner wall surface facing interior and an outer wall surface facing exterior.

The inner wall surface refers to a wall surface facing an indoor region.

The outer wall surface refers to a wall surface facing an outdoor region. The outdoor region may include other spaces such as an open platform, a corridor, a terrace, an overhead space, a roof, or the like.

It should be noted that when a wall is an exterior wall, the exterior wall has a side facing outdoors (that is, the outdoor-facing exterior wall surface), and a side facing indoors (that is, the indoor-facing interior wall surface). Craftsmanship practices of the inner wall surface and the outer wall surface are different, and the indoor-facing interior wall surface and the outdoor-facing exterior wall surface need to be considered differently during task assignment. Therefore, by recognizing the indoor-facing interior wall surface and the outdoor-facing exterior wall surface, the indoor-facing interior wall surface and the outdoor-facing exterior wall surface may be designated as different basic units for task assignment.

In some embodiments, the processor may recognize the wall primitive, the door primitive, and the window primitive in the construction floor plan. For example, the processor may first recognize and parse title block fields in a plurality of construction drawings to determine types of each of the construction drawings; if a specialty to which a construction drawing belongs is “architecture”, and a drawing name of the construction drawing includes a keyword such as “floor plan”, the construction drawing is determined as the construction floor plan. Then the processor may filter a layer whose name includes a keyword such as “WALL” or “wall” from layers of the construction floor plan, and extract primitives such as line segments, arcs, or the like, in the layer as the wall primitive. filter a layer whose name includes a keyword such as “door” or “DOOR”, and extract primitives such as line segments, arcs, or the like, in the layer as the door primitive. and filter a layer whose name includes a keyword such as “window” or “WINDOW”, and extract primitives such as line segments, arcs, or the like, in the layer as the window primitive.

The processor may further recognize the room region in the construction floor plan based on the wall primitive, the door primitive, and the window primitive. For example, the processor may obtain endpoint coordinates of each primitive, and determine whether primitives have a connection relationship based on the spatial distance between the primitives. If the distance between an endpoint coordinate of a primitive and an endpoint coordinate of another primitive is less than or equal to a spacing threshold, it is considered that the primitive and the another primitivess are connected to each other. When endpoints among a plurality of primitives are connected to each other and form a closed region, the closed region may be determined as the room region. The spacing threshold may be set by a user (e.g., a project manager) based on actual engineering experience. For example, the spacing threshold may be 200 mm. As another example, the processor may recursively traverse the endpoint coordinates of adjacent primitives, starting from any primitive based on connection relationships among the primitives, and determine whether a traversal path can return to the starting primitive. If the traversal path constitutes a closed path without breakpoints, the traversal path may constitute a closed region, thereby recognizing the room region. It should be noted that if the distance between the endpoints of adjacent primitives in the traversal path is less than or equal to the spacing threshold, it is considered that the adjacent primitives have a continuous connection at corresponding endpoints, and the traversal path without breakpoints is constituted.

The processor may further determine the wall based on the boundary of the room region, and designate a wall surface facing an internal space of the room region as the inner wall surface, and designate a wall surface facing an external space of the room region as the outer wall surface.

In some embodiments of the present disclosure, based on connection relationships among the wall primitive, the door primitive, and the window primitive, the room region in the construction floor plan may be automatically deduced, and further, the indoor-facing interior wall surface and the outdoor-facing exterior wall surface may be recognized. Reliance on explicitly annotated region boundaries in construction drawings is not required, and drawings with different design styles may be adapted, thereby enhancing universality and adaptability and supporting subsequent execution of the construction task assignment in wall-surface dimensions.

In some embodiments, the processor may determine a plurality of outdoor grids and a plurality of indoor grids in the construction floor plan, traverse from at least one indoor grid of the plurality of indoor grids as a starting point to adjacent indoor grids of the at least one indoor grid until a target indoor grid corresponding to a space barrier element is determined, traverse from at least one outdoor grid of the plurality of outdoor grids as a starting point to adjacent outdoor grids of the at least one outdoor grid until a target outdoor grid corresponding to the space barrier element is determined, and recognize the indoor-facing interior wall surface and the outdoor-facing exterior wall surface in the target construction area from the construction floor plan based on the target indoor grid and the target outdoor grid. In some embodiments, the processor may recognize the indoor-facing interior wall surface and the outdoor-facing exterior wall surface in the target construction area from the construction floor plan based on steps S1 to S4.

In S1, a plurality of outdoor grids and a plurality of indoor grids are determined in the construction floor plan.

An outdoor grid refers to a grid corresponding to the outdoor region. An indoor grid refers to a grid corresponding to the indoor region.

In some embodiments, the processor may first perform a rough regional division in the construction floor plan to determine a rough indoor region and a rough outdoor region. For example, the processor may recognize straight-lines in the construction floor plan, find a region enclosed by the straight-lines, determine the region as the indoor region, and determine other regions as the outdoor region. As another example, the processor may recognize keywords of the outdoor region, determine a region corresponding to the keywords of the outdoor region as the outdoor region, and determine other regions as the indoor region. The keywords of the outdoor region include an open platform, a corridor, a terrace, an overhead space, a roof, etc. It should be noted that a rough division is performed here, and the accuracy is relatively low.

The processor may divide each of the indoor region and the outdoor region into grids. Dividing each of the indoor region and the outdoor region into grids refers to a process of dividing each of the indoor region and the outdoor region into simple and regular tiny units (e.g., triangles, quadrilaterals, squares, hexagons, etc.). A set of these tiny units is referred to as “grids”. Side lengths of the tiny units may be the same or different. For convenience of description, the following description takes a tiny unit, being a square, as an example.

In some embodiments, the dimension of the outdoor grid is greater than the dimension of the indoor grid. For example, the outdoor grid may be a square with a side length of 200 mm, and the indoor grid may be a square with a side length of 50 mm. Understandably, when the dimension of the grid is set too large, the accuracy is too low, and when the dimension of the grid is set too small, calculation efficiency is too low. Since the width of a door is usually above 600 mm, selecting a square with a side length of 200 mm for the outdoor grid may ensure that an indoor-outdoor connection manner similar to a door opening width is not missed. Since the indoor area is usually smaller compared with the outdoor area, and there are more wall surfaces set indoors, the dimension of the indoor grid needs to be set smaller to ensure accuracy.

In some embodiments, the dimension of the indoor grid is determined based on an area of the indoor region. For example, the processor may first determine the size of the indoor region. When the indoor region is relatively small, a relatively small dimension of the indoor grid may be set to ensure that a sufficient number of grids are segmented.

In some embodiments, the dimension of the outdoor grid may be preset.

In S2, a target indoor grid corresponding to a space barrier element is determined by traversing from at least one indoor grid of the plurality of indoor grids as a starting point to adjacent indoor grids of the at least one indoor grid.

The space barrier element refers to an element that serves as a barrier in a space. For example, the space barrier element may include an element such as a wall, a door, a window, etc.

The target indoor grid refers to a grid corresponding to the space barrier element among the indoor grids. For example, as shown in FIG. 19, a black-background grid 5 is a target indoor grid corresponding to a wall.

In some embodiments, the processor may select a starting point to start spreading, and merely process unspread grids during each spreading. The starting point refers to any one indoor grid among the plurality of indoor grids. When the starting point cannot spread (for example, there are two mutually unconnected buildings A and B in a target construction area, and it is impossible to spread from building A to building B), another unspread starting point among the plurality of indoor grids is selected to start spreading until all indoor grids among the plurality of indoor grids have been spread, and target indoor grids corresponding to all space barrier elements are determined. This manner is relatively cost-saving in computation. For example, as shown in FIG. 19, taking grid 1 as a starting point, spreading to 4 grids 2 above, below, left, and right of grid 1. No space barrier element is recognized in these 4 grids; continuing to take the four grids 2 as starting points, first excluding previously traversed grids, spreading to 8 grids 3. No space barrier element is recognized in these 8 grids . . . . When spreading to 15 grids 5, the black-background grid 5 is recognized as a target indoor grid corresponding to a space barrier element . . . until all target indoor grids corresponding to the space barrier elements are determined.

In some embodiments, the processor may respectively spread taking each grid among the plurality of indoor grids as a starting point. More descriptions regarding the spreading manner may be found elsewhere in the present disclosure (e.g., related descriptions above).

In S3, a target outdoor grid corresponding to the space barrier element is determined by traversing from at least one outdoor grid of the plurality of outdoor grids as a starting point to adjacent outdoor grids of the at least one outdoor grid.

The target outdoor grid refers to a grid corresponding to the space barrier element among the outdoor grids.

A process of determining the target outdoor grid corresponding to the space barrier element (i.e., step S3) is similar to a process of determining the target indoor grid corresponding to the space barrier element (i.e., step S2), which may be found in step S2 and related descriptions thereof.

It should be noted that in the process of determining the target outdoor grid corresponding to the space barrier element, four corner points of the construction floor plan and a grid where a keyword corresponding to the outdoor region recognized in the construction floor plan is located may be selected as the starting point.

In S4, the indoor-facing interior wall surface and the outdoor-facing exterior wall surface in the target construction area from the construction floor plan are recognized based on the target indoor grid and the target outdoor grid.

In some embodiments, the processor may determine a wall in the construction drawing based on the target indoor grid and the target outdoor grid. A region where the target indoor grid and the target outdoor grid overlap is a region where a wall separating the indoor region and the outdoor region is located. A non-overlapping region where the target indoor grid is located is a region where a wall separating different indoor rooms is located. For example, the processor may take a straight-line primitive or a rectangular primitive located in the overlapping region of the target indoor grid and the target outdoor grid as a wall primitive in combination with straight-line primitives or rectangular primitives in the construction floor plan. As another example, the processor may take a straight-line primitive or a rectangular primitive in the non-overlapping region where the target indoor grid is located as a wall primitive in combination with straight-line primitives or rectangular primitives in the construction floor plan. When the wall primitive is determined, the processor may designate a side of the wall primitive facing the outdoor region as the outdoor-facing exterior wall surface, and designate a side of the wall primitive facing the indoor region as the indoor-facing interior wall surface.

In some embodiments of the present disclosure, the indoor-facing interior wall surface and the outdoor-facing exterior wall surface may be accurately determined through a grid spreading method. In addition, the dimension of the outdoor grid is greater than the dimension of the indoor grid, and the dimension of the indoor grid is determined based on the area of the indoor region, taking both accuracy and calculation efficiency into consideration.

It should be noted that, since distances among wall surfaces need to be determined during subsequent task assignment, if length differences among walls are too large, distances measurement will be inaccurate. Therefore, it is necessary to split an excessively long wall into walls with a length not exceeding a preset length, and corresponding wall surfaces are also split. The preset length may be a preset length threshold. For example, the processor may regard a wall with a length less than a preset length of 3m as one wall, and split a wall with a length greater than the preset length of 3m. Merely by way of example, a 9 m wall may be split into 3 segments of 3m+3m+3m; a 10m wall may be split into 4 segments of 3m+3m+3m+1m. By splitting the wall whose length exceeds the preset length, distance distortion may be prevented. For example, for a 100m wall and a 1 m wall, directly determining the distance between them will have an inaccurate problem. By splitting the 100m wall into 200 wall surfaces, determining the distance between each wall surface and the 1m wall is more accurate.

The construction task sheet refers to a document in which a project department issues work instructions to construction workers during a construction process.

In some embodiments, the construction task sheet may include construction task information and construction worker information corresponding to a target construction period.

The target construction period refers to a time period during which a construction task needs to be completed. For example, the target construction period may be any time period such as one day, one week, one month, etc.

The construction worker information refers to information associated with personnel related to wall surface task assignment within the target construction period. For example, the construction worker information may include a construction worker count, an user identification of each construction worker, a construction task item assigned to each construction worker, and a constructable area per unit time. The construction worker user identification refers to a unique code of a construction worker. The user identification may be an Identification (ID) of the construction worker, which may be composed of letters, numbers, symbols, etc. The constructable area per unit time may include that N square meters of waterproofing can be done per day, M square meters of latex paint can be done per day, etc.

In some embodiments, the construction task sheet may include preset information about construction workers (also referred to as construction worker information).

In some embodiments, the processor may dynamically assign the construction worker information based on an overall construction task of the target construction area in a current construction stage and a completed task amount. For example, if a construction task is to paint a 1000 square meter wall on one floor, it is estimated to take 10 days to complete. Each construction worker can paint 10 square meters per day. When the task begins, it is planned to paint 100 square meters per day, requiring 10 construction workers. However, an actual situation may be fast or slow. After 5 days of painting, theoretically 500 square meters should have been painted, and 500 square meters are left to be painted. But the actual situation is that 800 square meters remain to be painted. Therefore, a subsequent plan is modified to paint 160 square meters per day, requiring 16 construction workers. It should be noted that the above method uses a linear algorithm to determine the construction worker information, and other algorithms may also be used to determine the construction worker information. For example, painting may be faster in the first few days and slower in the last few days, and an equal distribution is not adopted.

In some embodiments, since the wall surfaces may be divided into outdoor-facing exterior wall surfaces and indoor-facing interior wall surfaces, and task types and construction workers corresponding to the outdoor-facing exterior wall surfaces and the indoor-facing interior wall surfaces are different, there will be corresponding construction task sheets for each. Therefore, the construction task sheet may include a first construction task sheet for the indoor-facing interior wall surface and a second construction task sheet for the outdoor-facing exterior wall surface. Task assignment for the indoor-facing interior wall surface is performed based on the first construction task sheet, and task assignment for the outdoor-facing exterior wall surface is performed based on the second construction task sheet.

In 1820, target wall surfaces to be constructed in the target construction period and a construction task item corresponding to each target wall surface from the wall surfaces in the target construction area are determined based on the construction task information and historical construction data of the wall surfaces.

The historical construction data refers to wall surface construction data before a current time point.

A target wall surface refers to a wall surface needing to be constructed within the target construction period.

The construction task item corresponding to each target wall surface refers to a construction task item determined by taking each target wall surface as a unit. More descriptions regarding the construction task item may be found elsewhere in the present disclosure (e.g., related descriptions above).

In some embodiments, based on the construction task information and the historical construction data of the wall surfaces, and referring to a task assignment rule, which walls need to be constructed within the target construction period are determined and designated as the target wall surfaces, and a construction task item corresponding to each target wall surface is determined. The construction task information may prescribe, in general terms, what work needs to be done on wall surfaces in the next target construction area. The historical construction information of the wall surface may be configured to determine the current construction progress of the wall surfaces in the target construction area.

The task assignment rule stipulates construction task items needing to be performed for different types of rooms and different types of wall surfaces, and sequential orders among the wall surface task items. For example, for a construction task item of waterproofing, a suitable wall surface type is an innerwall surface of a bathroom. As another example, for a construction task item of installing an exterior glass curtain wall, a suitable wall surface type is an exterior wall. As a further example, for a construction task item of tiling, an essential preceding construction task item of tiling is waterproofing. Understandably, some construction task items are not related to a spatial position where a wall is located, such as cleaning the floor of a room where the wall is located. Some construction task items are related to a spatial position where a wall is located. For example, if another side of a wall surface A is a wall surface B, and the wall surface B is an inner wall surface of a bathroom, then latex paint needs to be applied to the wall surface A after waterproofing of the wall surface B is finished.

For example, for each wall surface in the target construction area, the processor may predict a construction task item needing to be performed on the wall surface within the target construction period according to the task assignment rule, the current construction progress, the type of the wall surface, and the room where the wall surface is located. If the above construction task item is included in the construction task sheet, then the wall surface is the target wall surface, and the above construction task item is the construction task item corresponding to the target wall surface.

In 1830, target construction workers, and the target wall surfaces and the construction task item assigned to each of the target construction workers in the target construction period are determined based on the construction worker information and the construction task item corresponding to each of the target wall surfaces.

The target construction workers refer to construction workers actually assigned to a construction task item corresponding to a target wall surface. The target construction workers may include all construction workers or a portion of construction workers.

The target wall surface assigned to a target construction worker refers to a target wall surface needing to be handled by the target construction worker, and the construction task item of the target construction worker refers to a construction task item corresponding to the target wall surface.

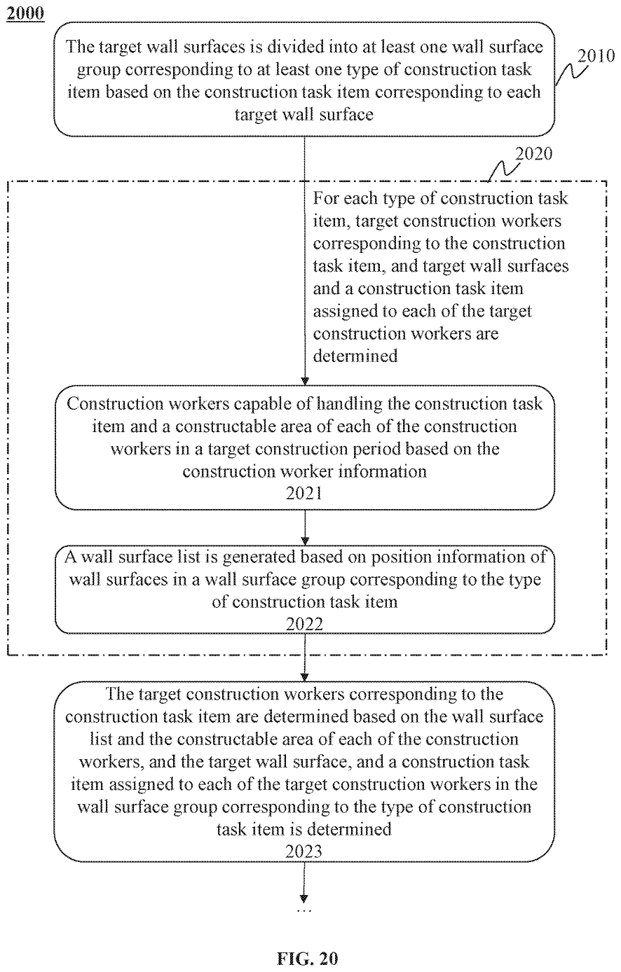

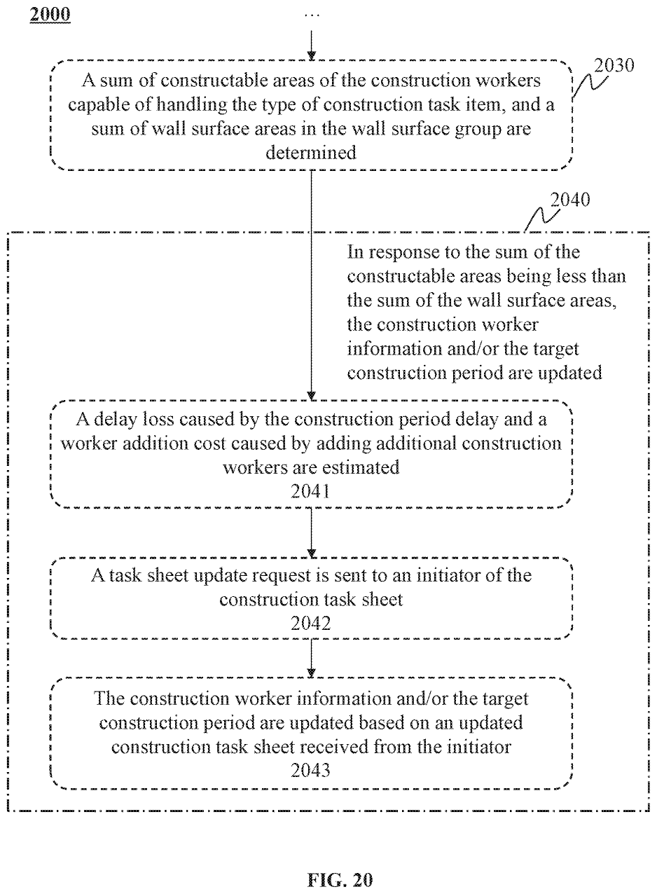

In some embodiments, the processor may determine the target construction workers, and the target wall surface and the construction task item of each target construction worker through a process shown in FIG. 20. More descriptions regarding determining the target construction workers, and the target wall surface and the construction task item of each target construction worker may be found elsewhere in the present disclosure (e.g., FIG. 20 and related descriptions thereof).

In some embodiments of the present disclosure, by determining the target construction workers, and the target wall surface and the construction task item assigned to each of the target construction workers in the target construction period, an automatic assignment of the construction task item corresponding to the target wall surface is achieved, thereby improving assignment efficiency. In addition, an assignment unit is detailed to a specific wall surface, and an indoor-facing interior wall surface and an outdoor-facing exterior wall surface are distinguished, making the assignment more accurate.

It should be noted that the above descriptions of the wall surface task assignment process are merely examples and illustrations and do not limit the scope of the present disclosure. For those skilled in the art, a plurality of variations and modifications may be made to the wall surface task assignment process under the guidance of the present disclosure. However, these variations and modifications do not depart from the scope of the present disclosure. For example, a sequence of Step S2 and Step S3 may be interchanged.

FIG. 20 is a flowchart of an exemplary process for determining target construction workers, and a target wall surface and a construction task item assigned to each of the target construction workers in a target construction period according to some embodiments of the present disclosure. In some embodiments, as shown in FIG. 20, the process 2000 may include steps 2010 to 2020. In some embodiments, as shown in FIG. 20, the process 2000 may further include steps 2030 to 2040.

In some embodiments, the processor may divide the target wall surfaces into at least one wall surface group corresponding to at least one type of construction task item based on the construction task item corresponding to each target wall surface. For each type of construction task item, the processor may determine construction workers capable of handling the type of construction task item and a constructable area of the construction workers in the target construction period based on the construction worker information. The processor may generate a wall surface list based on position information of wall surfaces in a wall surface group corresponding to the type of construction task item, and determine the target construction workers corresponding to the type of construction task item based on the wall surface list and the constructable area of the construction workers. The processor may determine the target wall surface and the construction task item assigned to each of the target construction workers in the wall surface group corresponding to the type of construction task item.

In some embodiments, the processor may further determine a sum of constructable areas of the construction workers capable of handling the construction task item, and a sum of wall surface areas in the wall surface group. In response to the sum of the constructable areas being less than the sum of the wall surface areas, the processor may estimate a delay loss caused by construction period delay and a worker addition cost caused by adding additional construction workers, and send a task sheet update request to an initiator of the construction task sheet. The task sheet update request includes the delay loss and the worker addition cost. The processor may update the construction worker information and/or the target construction period based on an updated construction task sheet received from the initiator.

In 2010, the target wall surfaces is divided into at least one wall surface group corresponding to at least one type of construction task item based on the construction task item corresponding to each target wall surface.

The construction task item type refers to a specific type of a construction task item. The construction task item type may include a waterproofing task, a painting task, a plastering task, a tiling task, etc. Each type of construction task item may correspond to at least one wall surface. Therefore, at least one type of construction task item corresponds to at least one wall surface group, and each wall surface group may include at least one target wall surface.

In some embodiments, the target wall surfaces and the construction task item corresponding to each target wall surface have been determined in step 1820. The processor may divide the target wall surfaces into the at least one wall surface group based on the construction task item type corresponding to each target wall surface. For example, the processor may divide the target wall surfaces into wall surface groups A₁-Aᵢ corresponding to a construction task item type A, and wall surface groups B₁-Bⱼ corresponding to a construction task item type B.

For convenience of description, the following description takes the wall surface groups A₁-Aᵢ as an example.

In 2020, for each type of construction task item, target construction workers corresponding to the construction task item, and target wall surfaces and a construction task item assigned to each of the target construction workers are determined.

In some embodiments, step 2020 may be implemented according to step 2021 to step 2023.

In 2021, construction workers capable of handling the construction task item and a constructable area of each of the construction workers in a target construction period based on the construction worker information.

The construction worker information may include a construction worker count, user identification of each construction worker, a construction task item that each construction worker is responsible for, and a constructable area of each construction worker per unit time. More descriptions regarding the construction worker information may be found elsewhere in the present disclosure (e.g., FIG. 18 and related descriptions thereof).

In some embodiments, for each type of construction task item, the processor may determine N construction workers capable of executing the type of construction task item based on the construction worker information, and a constructable area that each of the N construction workers can complete within the target construction period. For example, if the target construction period is one week, a constructable area of a certain construction worker within the target construction period may be N square meters of waterproofing per week, M square meters of latex paint per week, etc.

In 2022, a wall surface list is generated based on position information of wall surfaces in a wall surface group corresponding to the type of construction task item.

Position information of a wall surface refers to data configured to reflect a spatial position of the wall surface. For example, the position information of a wall surface may include a coordinate value (Xᵢ, Yⱼ) of a center point of the wall surface. The coordinate value may be position data in a preset coordinate system, and the preset coordinate system may be a coordinate system taking a certain point in the target construction area as an origin, an east-west direction as an X-axis, and a north-south direction as a Y-axis.

It should be noted that if an excessively long wall surface is split, the position information of the wall surface is data of a spatial position of each split wall surface. For example, the position information of the wall surface may include a coordinate value of the center point of each split wall surface. More descriptions regarding splitting a wall surface may be found elsewhere in the present disclosure (e.g., FIG. 18 and related descriptions thereof).

The wall surface list refers to a list generated after arranging adjacent wall surfaces. For example, the wall surface list may be wall surface A₁, wall surface A₂ . . . wall surface Aⱼ. In some embodiments, the wall surface list includes related information of each wall surface, such as a number, a position, a corresponding construction task item, an area, etc.

Understandably, when assigning the target wall surfaces and the construction task items thereof, it is desired that construction workers can minimize walking distances during work to improve working efficiency. Therefore, wall surfaces in the wall surface groups A1-Ai may be sorted according to spatial positions, so that wall surfaces with close positions are adjacent in the wall surface list.

The wall surface list may include a wall surface list of indoor-facing interior wall surfaces and a wall surface list of outdoor-facing exterior wall surfaces.

Since the indoor-facing interior wall surfaces have relatively good accessibility, construction workers can reach indoor-facing interior wall surfaces at different positions through doors, corridors, etc. In some embodiments, for the indoor-facing interior wall surface, the processor may take a center point of any wall surface a in the wall surface group as a reference point, connect the reference point with center points of other wall surfaces in the wall surface group to obtain a plurality of connection lines, take the wall surface a as a first wall surface in the wall surface list, randomly select a wall surface b among the other wall surfaces as a second wall surface in the wall surface list, take a connection line between the wall surface a and the wall surface b as a starting connection line, and sort remaining wall surfaces according to a sequence of remaining connection lines (e.g., sorting clockwise) to generate the wall surface list. In some embodiments, for the indoor-facing interior wall surface, the processor may map two-dimensional coordinates to a one-dimensional sequence by using a space-filling curve and then perform sorting. In some embodiments, if wall surfaces are roughly linearly arranged, the processor may directly sort the wall surfaces according to x-coordinates or y-coordinates.

In some embodiments, for the indoor-facing interior wall surface, the processor may select any wall surface A₁ in the wall surface groups A₁-Aᵢ (e.g., the processor may select a wall surface close to an exit of a construction elevator) as a starting point, find a wall surface A₂ closest to the wall surface A₁, and then find a wall surface A₃ closest to the wall surface A₂, until all wall surfaces are processed, forming the wall surface list including the wall surface A₁, the wall surface A₂, the wall surface A₃ . . . the wall surface Aᵢ.

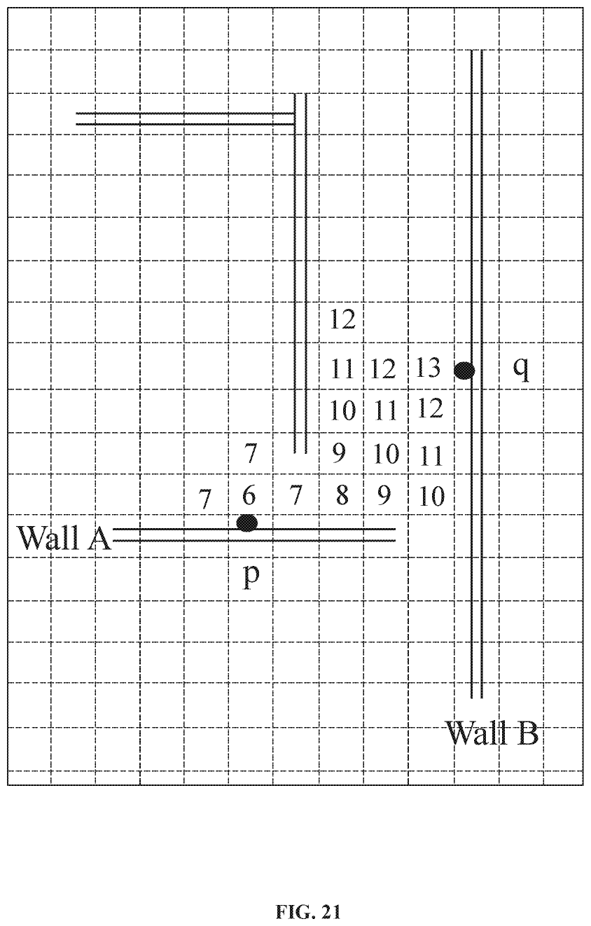

A distance between wall surfaces refers to the distance between the center points of the wall surfaces. For example, as shown in FIG. 21, the distance between a wall A and a wall B refers to the distance between a center point p of the wall A and a center point q of the wall B.

Since doors and unfinished walls are passable, windows and finished walls may be designated as space barrier elements, excluding doors and unfinished walls. Whether a wall is finished can be determined by whether a key task sheet regarding wall construction, etc., is completed. The processor may recognize impassable windows and finished walls through a manner of recognizing the indoor-facing interior wall surface and the outdoor-facing exterior wall surface in FIG. 18. Since windows are set on walls, the positions of windows are not marked in FIG. 21, and illustrations are made directly using walls. More descriptions regarding recognizing the indoor-facing interior wall surface and the outdoor-facing exterior wall surface may be found elsewhere in the present disclosure (e.g., FIG. 18 and related descriptions thereof).

As shown in FIG. 21, when a distance between the wall A and the wall B needs to be determined, the processor may take a grid 6 closest to the center point p of the wall A as a starting point, and spread to 3 grids 7 on an upper side, a left side, and a right side of the grid 6; continue to take the grids 7 as starting points (since grids 7 on the upper side and the left side are far from the wall B, spreading of these two grids is not shown in the figure), first exclude previously traversed grids and impassable grids, and spread to a grid 8 . . . . When spreading to a grid 13, the center point q of the wall B is reached. Therefore, from the center point p of the wall A to the center point q of the wall B, spreading is performed for 7 times in total. If each grid is 1 m, the distance between the wall A and the wall B is 7 m.

However, for the outdoor-facing exterior wall surface, construction can merely be performed according to a specific sequence, for example, starting from the roof to the bottom of a building. A wall surface list thereof may be generated based on a 3D model corresponding to a plurality of floors.

In some embodiments, the target construction area may include at least two floors, the construction floor plan includes a construction floor plan corresponding to each floor, the wall surface includes an outdoor-facing exterior wall surface, and a wall surface list corresponding to the exterior wall surface is generated according to the following steps. For each floor among the at least two floors, a first 3D model corresponding to the floor is generated based on a floor height of the floor and a wall surface in the construction floor plan corresponding to the floor. A reference area corresponding to a common vertical space of the at least two floors in the first 3D model. The first 3D models of the at least two floors are aligned and stacked based on the reference areas in the first 3D models of the at least two floors to generate a second 3D model of the target construction area. The wall surface list corresponding to the exterior wall surface is generated based on the second 3D model.

The wall surface list corresponding to the outdoor-facing exterior wall surface may be generated based on steps P1 to P3.

In P1, for each floor among a plurality of floors, a first 3D model corresponding to the floor is generated based on a floor height of the floor and a wall surface in a construction floor plan corresponding to the floor; and a reference area corresponding to a common vertical space of a plurality of floors is determined in the first 3D models.

The first 3D model refers to a 3D model of each floor.

In some embodiments, for each floor, the processor may determine a room outline of the floor based on walls recognized in the construction floor plan of the floor. Further, the processor may generate the first 3D model of the floor based on the floor height of the floor.

The common vertical space refers to a vertical space shared across different floors. For example, the common vertical space may include an elevator and stairs. Understandably, no matter how rooms in the plurality of floors change, a position of the common vertical space is fixed.

The reference area corresponding to the common vertical space refers to an area corresponding to the common vertical space in the first 3D model of each floor.

In some embodiments, for each floor, the processor may recognize corresponding text primitives in the construction floor plan to determine the position of the common vertical space, and determine corresponding areas in the first 3D models.

In P2, first 3D models of the plurality of floors are aligned and stacked based on reference areas in the first 3D models of the plurality of floors to generate a second 3D model of a target construction area.

Aligning refers to a process of matching the plurality of floors to keep parts with same orientations consistent. Stacking refers to a process of overlapping the plurality of floors according to a floor sequence.

The second 3D model refers to a 3D model of the plurality of floors.

In some embodiments, for adjacent floors, the processor may align reference areas corresponding to common vertical spaces of the adjacent floors, and based on alignment, stack first 3D models corresponding to the adjacent floors to generate the second 3D model of the target construction area. For example, for adjacent floors of a 2nd floor and a 3rd floor, there are 4 elevator spaces on both the 2nd floor and the 3rd floor, and the dimension 4 of each of the 4 elevator spaces is 2500 m×2500 m. Since elevators are usually aligned vertically, the processor may align reference areas corresponding to the 4 elevator spaces on the 2nd floor and the 3rd floor, and based on the alignment, stack first 3D models corresponding to the 2nd floor and the 3rd floor to generate the second 3D model of the target construction area.

In P3, a wall surface list corresponding to an outdoor-facing exterior wall surface is generated based on the second 3D model.

In some embodiments, the processor may determine a plurality of columns of outdoor-facing exterior wall surfaces of different floors located on the same vertical plane according to the second 3D model (e.g., outdoor-facing exterior wall surfaces corresponding to elevators). The processor may arbitrarily select a column of outdoor-facing exterior wall surfaces r from the plurality of columns of outdoor-facing exterior wall surfaces. The processor may sort the outdoor-facing exterior wall surfaces of different floors of the column of outdoor-facing exterior wall surfaces r from top to bottom as a first part of the wall surface list. The processor may sort outdoor-facing exterior wall surfaces of different floors of a column of wall surfaces r+1 adjacent to the column of wall surfaces r from top to bottom as a second part adjacent to the first part of the wall surface list . . . until all columns of wall surfaces are covered, generating the wall surface list corresponding to the outdoor-facing exterior wall surface.

In some embodiments of the present disclosure, determining the wall surface list corresponding to the outdoor-facing exterior wall surface from 3D models aligns task assignment with general practices in exterior wall construction, thereby improving construction efficiency.

In 2023, the target construction workers corresponding to the construction task item are determined based on the wall surface list and the constructable area of each of the construction workers, and the target wall surface, and a construction task item assigned to each of the target construction workers in the wall surface group corresponding to the type of construction task item is determined.

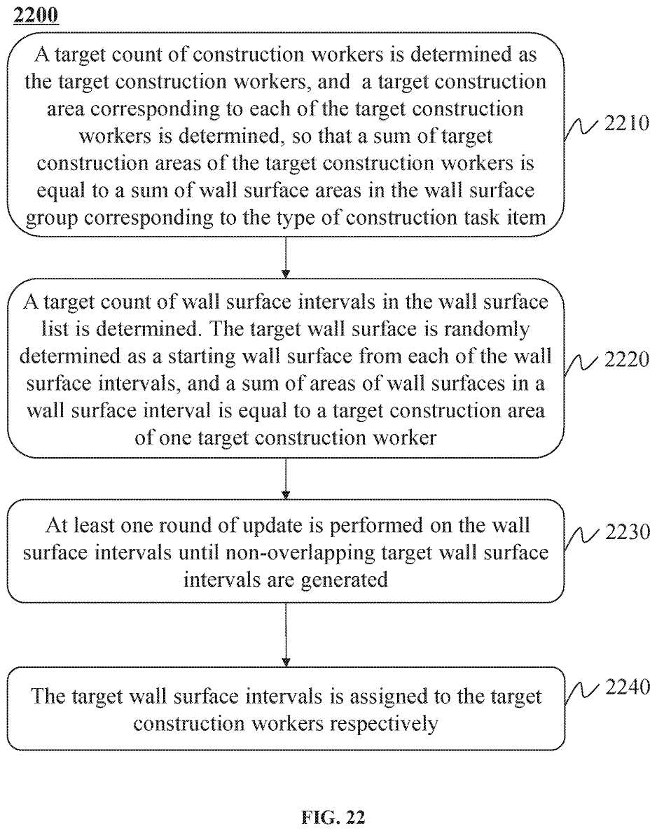

In some embodiments, the processor may determine the target construction workers corresponding to a construction task item, and a target wall surface and a construction task item assigned to each of the target construction workers through a process shown in FIG. 22. More descriptions regarding determining the target construction workers corresponding to the construction task item, and the target wall surface and the construction task item assigned to each of the target construction workers may be found elsewhere in the present disclosure (e.g., FIG. 22 and related descriptions thereof).

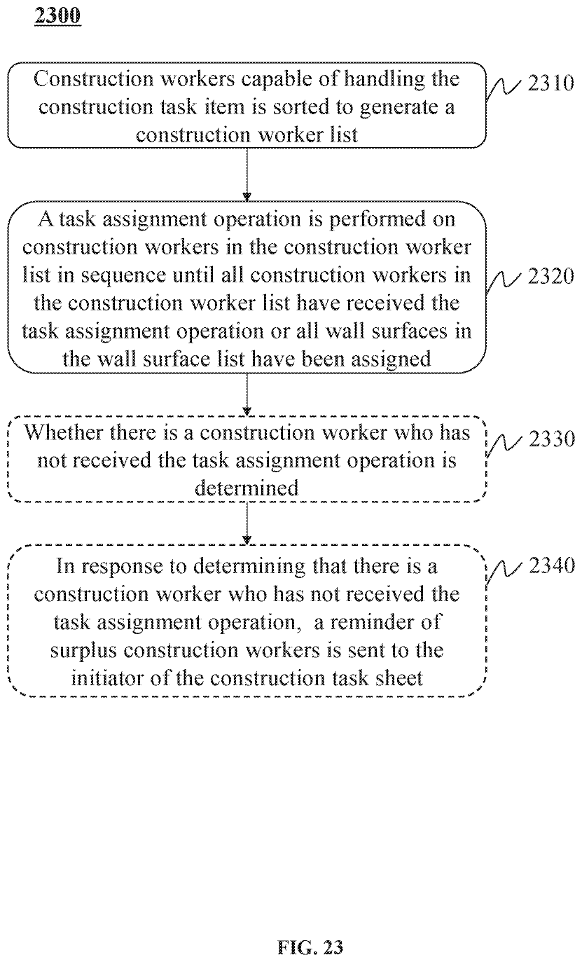

In some embodiments, the processor may determine the target construction workers corresponding to a construction task item, and a target wall surface and a construction task item assigned to each of the target construction workers through a process shown in FIG. 23. More descriptions regarding determining the target construction workers corresponding to the construction task item, and the target wall surface and the construction task item assigned to each of the target construction workers may be found elsewhere in the present disclosure (e.g., FIG. 23 and related descriptions thereof).

In some embodiments, under some conditions, there are relatively many construction tasks, but there are relatively few construction workers in a construction task sheet, and a situation where a portion of the construction tasks cannot be assigned to the construction workers exists. At this time, whether to extend the construction period or add additional construction workers may be comprehensively considered. In some embodiments, the processor may further perform steps 2030 to 2040.

In 2030, a sum of constructable areas of the construction workers capable of handling the type of construction task item, and a sum of wall surface areas in the wall surface group are determined.

In some embodiments, for each type of construction task item, the processor may add constructable areas of construction workers capable of handling the type of construction task item in a target construction period to obtain the sum of the constructable areas of the construction workers capable of handling the type of construction task item, and the processor may add wall surface areas in a wall surface group corresponding to the construction task item to obtain the sum of the wall surface areas in the wall surface group.

In 2040, in response to the sum of the constructable areas being less than the sum of the wall surface areas, the construction worker information and/or the target construction period are updated.

When the sum of the constructable areas is less than the sum of the wall surface areas, it indicates that the construction workers are insufficient, and the following manners may be adopted: 1. delaying the construction period and spending more time to complete a construction task. For example, if the target construction period is 3 days, the target construction period needs to be increased to 7 days to complete the construction task; 2. arranging more construction workers and still completing the construction task according to the target construction period.

In 2041, a delay loss caused by the construction period delay and a worker addition cost caused by adding additional construction workers are estimated.

The delay loss refers to an economic loss caused by the construction period delay.

The worker addition cost refers to a cost increase caused by adding additional construction workers.

In some embodiments, the processor may determine whether an extension compensation exists based on a construction contract. If the extension compensation exists, the extension compensation constitutes a first delay loss. The processor may determine whether the construction period delay will affect the progress of a subsequent construction task. If the construction period delay will affect the progress of the subsequent construction task, the processor may determine whether the construction period delay will cause a monetary loss, and if the construction period delay will cause the monetary loss, the monetary loss constitutes a second delay loss. The processor may determine the first delay loss and/or the second delay loss as the delay loss.

In some embodiments, the processor may estimate how many additional construction workers need to be added to complete the construction task on time based on a difference between the sum of the constructable areas and the sum of the wall surface areas, and add costs of added the additional construction workers as the worker addition cost.

In 2042, a task sheet update request is sent to an initiator of the construction task sheet.

The initiator of the construction task sheet refers to a party initiating the construction task sheet.

The task sheet update request refers to a decision request needing to be selected by the initiator of the construction task sheet. For example, the task sheet update request may include the delay loss and the worker addition cost.

In some embodiments, the processor may send the delay loss and the worker addition cost as information in the task sheet update request to the initiator of the construction task sheet as a decision reference.

In 2043, the construction worker information and/or the target construction period are updated based on an updated construction task sheet received from the initiator.

The initiator selects delaying the construction period and/or adding additional construction workers according to the information in the task sheet update request. If the initiator selects a manner of adding additional construction workers, the processor may update the construction worker information; if the initiator selects a manner of delaying the construction period, the processor may update the target construction period; and if the initiator selects a manner of adding construction workers and delaying the construction period (e.g., adding a small count of construction workers while delaying some construction periods), the processor may simultaneously update the construction worker information and the target construction period.

In some embodiments of the present disclosure, by determining target construction workers corresponding to each type of construction task item, and determining target wall surfaces and a construction task item assigned to the target construction workers in a corresponding wall surface group, minimizing walking distances of the construction workers can be achieved, and the sum of the wall surface areas not exceeding the sum of the constructable areas can be achieved. Moreover, by updating the construction worker information and/or the target construction period, a normal progress of the construction task can be ensured, and costs can be saved at the same time. Providing the initiator with more decision-relevant information can improve decision-making accuracy.

It should be noted that the above descriptions regarding a process for determining the target construction workers, and the target wall surface and the construction task item assigned to each of the target construction workers in the target construction period are merely for examples and illustrations, and do not limit the scope of the present disclosure. For those skilled in the art, a plurality of variations and modifications may be made to the process for determining the target construction workers, and the target wall surface and the construction task item assigned to each of the target construction workers in the target construction period under the guidance of the present disclosure. However, these variations and modifications do not depart from the scope of the present disclosure. In some embodiments, steps 2330 to 2340 may be performed after step 2020.

FIG. 22 is a flowchart of an exemplary process for determining target construction workers, and a target wall surface and a construction task item assigned to each of the target construction workers in a target construction period according to some other embodiments of the present disclosure. In some embodiments, as shown in FIG. 22, a process 2200 may include steps 2210 to 2240.

In some embodiments, the processor may determine a target count of construction workers as the target construction workers, so that a sum of constructable areas of the target construction workers is equal to a sum of wall surface areas in a wall surface group corresponding to the type of construction task item. The processor may determine a target count of wall surface intervals in the wall surface list. A target wall surface is determined as a starting wall surface, and a sum of areas of wall surfaces in a wall surface interval is equal to an average constructable area of the target construction workers. The processor may perform at least one round of update on the wall surface intervals until non-overlapping target wall surface intervals are generated. Each round of update includes a first update and a second update. The first update is performed based on a sum of distances from each target wall surface to other target wall surfaces in the wall surface interval, and the second update is performed based on overlapping target wall surfaces between the wall surface intervals. The processor may assign the target wall surface intervals to the target construction workers respectively.

In 2210, a target count of construction workers is determined as the target construction workers, and a target construction area corresponding to each of the target construction workers is determined, so that a sum of target construction areas of the target construction workers is equal to a sum of wall surface areas in the wall surface group corresponding to the type of construction task item.

In some embodiments, assuming that when recognizing the wall surfaces in the target construction area, the wall surfaces are divided by area to obtain wall surfaces with the same area. The processor may determine a target count of target construction workers and a target construction area corresponding to each target construction worker based on a sum of wall surface areas and a constructable area of each construction worker, so that a sum of target construction areas of the target construction workers is equal to the sum of the wall surface areas in the wall surface group corresponding to the type of construction task item. For example, assuming that there are 200 walls of 1 square meter to be assigned, and constructable areas of construction workers are all 20 square meters, the processor may determine that the target count of target construction workers is 10, and a target construction area of each target construction worker is 20 square meters. As another example, assuming that there are 200 walls of 1 square meter to be assigned, and constructable areas of construction workers are all 19 square meters, the processor may determine that a target count of target construction workers is 11, a target construction area of 10 target construction workers is 19 square meters, and an area of 1 target construction worker is 10 square meters.

In 2220, a target count of wall surface intervals in the wall surface list is determined. The target wall surface is randomly determined as a starting wall surface from each of the wall surface intervals, and a sum of areas of wall surfaces in a wall surface interval is equal to a target construction area of one target construction worker.

In some embodiments, the processor may randomly select any target count of target wall surfaces in the wall surface list as starting wall surfaces, and determine wall surface intervals taking the starting wall surfaces as starting points, and a sum of areas of wall surfaces in a wall surface interval is equal to a target construction area of one target construction worker.

For example, assuming that there are 200 walls of 1 square meter to be assigned to 10 target construction workers, and a target construction area of each target construction worker is 20 square meters, the processor may randomly select any 10 wall surfaces (e.g., wall surface A1, wall surface B1, wall surface C1 . . . ) as starting wall surfaces, and determine wall surface intervals each of which includes 20 wall surfaces and takes each starting wall surface as a starting point. Thereby, 10 wall surface intervals may be determined, and a total area of wall surfaces in each wall surface interval is 20 square meters, which may be assigned to 1 target construction worker. As another example, assuming that there are 200 walls of 1 square meter to be assigned to 11 target construction workers, a target construction area of each of 10 target construction workers is 19 square meters, and an area of 1 target construction worker is 10 square meters. The processor may randomly select any 11 wall surfaces as starting wall surfaces, and determine 11 wall surface intervals each of which takes a starting wall surface as a starting point, wherein a total area of wall surfaces in 10 wall surface intervals is 190 square meters, which may be respectively assigned to 10 target construction workers; a total area of wall surfaces in 1 wall surface interval is 10 square meters, which may be assigned to 1 target construction worker.

In 2230, at least one round of update is performed on the wall surface intervals until non-overlapping target wall surface intervals are generated.

Each round of update includes a first update and a second update.

The first update may be performed based on a sum of distances from each target wall surface to other target wall surfaces in the wall surface interval. For example, in a group of 20 wall surfaces, for each wall surface, a sum of distances between the wall surface and remaining 19 wall surfaces is determined, and a wall surface with a smallest sum value is determined as a new starting point. According to the new starting point, 19 wall surfaces closest to the new starting point may be determined to form a new group of wall surfaces.

The second update may be performed based on overlapping target wall surfaces between the wall surface intervals. For example, after the first update, there are usually overlapping portions among the 10 wall surface intervals. If an overlapping portion includes a wall surface A falling into a wall surface interval 1 and a wall surface interval 2, a sum of first distances each of which is between the wall surface A and one of remaining 19 wall surfaces in the wall surface interval 1, and a sum of second distances each of which is between the wall surface A and one of remaining 19 wall surfaces in the wall surface interval 2 are determined. In response to the sum of the first distance being less than the sum of the second distance, attribute the wall surface A to the wall surface interval 1; in response to the first distance being greater than the second distance, attribute the wall surface A to the wall surface interval 2; in response to the first distance being equal to the second distance, attribute the wall surface A to the wall surface interval 1 or the wall surface interval 2; for a wall surface interval not assigned with the wall surface A, the processor may add a wall surface with a smallest sum of distances to 19 wall surfaces in the wall surface interval from wall surfaces not divided into any wall surface intervals, to compose 20 wall surfaces.

The processor may repeat the first update and the second update until non-overlapping target wall surface intervals are generated, and finally 200 wall surfaces may be divided into 10 groups, with 20 wall surfaces in each group.

In 2240, the target wall surface intervals is assigned to the target construction workers respectively.

In some embodiments, each target wall surface interval is assigned to a target construction worker, that is, target wall surfaces and corresponding target task items in the target wall surface interval may be assigned to a target construction worker. In addition, the total sum of areas of target wall surfaces included in the target wall surface interval does not exceed the constructable area of a corresponding target construction worker.

In some embodiments of the present disclosure, through at least one round of update method, minimizing walking distances of construction workers can be achieved, and wall surface areas assigned to each target construction worker not exceeding a constructable area thereof can be achieved.

FIG. 23 is a flowchart of an exemplary process for determining target construction workers, and a target wall surface and a construction task item assigned to each of the target construction workers in a target construction period according to some other embodiments of the present disclosure. In some embodiments, as shown in FIG. 23, the process 2300 may include steps 2310 to 2320. In some embodiments, as shown in FIG. 23, the process 2300 may further include steps 2330 to 2340.

In some embodiments, the processor may sort construction workers capable of handling the construction task item to generate a construction worker list. The processor may perform a task assignment operation on the construction workers in the construction worker list in sequence until all construction workers in the construction worker list have performed the task assignment operation or all wall surfaces in the wall surface list have been assigned. For a current construction worker, the task assignment operation includes: the processor may determine a first unassigned wall surface in the wall surface list as a starting wall surface; the processor may determine an ending wall surface in the wall surface list, so that a cumulative sum of wall surface areas from the starting wall surface to the ending wall surface is less than or equal to a constructable area of the current construction worker, and a cumulative sum of wall surface areas from the starting wall surface to a next wall surface of the ending wall surface is greater than the constructable area of the current construction worker; the processor may take the current construction worker as one of the target construction workers, and the processor may take the starting wall surface, the ending wall surface, and intermediate wall surfaces between the starting wall surface and the ending wall surface, and construction task items thereof as the target wall surfaces and construction task items assigned to the target construction workers.

In some embodiments, the processor may further determine whether there is a construction worker that has not received the task assignment operation; and in response to determining that there is a construction worker that has not received the task assignment operation, send a reminder of surplus construction workers to an initiator of the construction task sheet.

In 2310, construction workers capable of handling the construction task item is sorted to generate a construction worker list.

The construction worker list refers to a list in which the construction workers are arranged in a certain sequence. For example, a construction worker list of N construction workers is P₁-Pₙ.

In some embodiments, the processor may sort the construction workers according to a preset rule. The preset rule refers to a rule set in advance. For example, the preset rule may include random sorting, sorting according to constructable areas corresponding to construction workers in a descending order, sorting according to rating scores of the construction workers in a descending order, etc.

In 2320, a task assignment operation is performed on construction workers in the construction worker list in sequence until all construction workers in the construction worker list have received the task assignment operation or all wall surfaces in the wall surface list have been assigned.

In some embodiments, for the current construction worker, the processor may determine the first unassigned wall surface in the wall surface list as a starting wall surface and determine an ending wall surface in the wall surface list, so that the cumulative sum of wall surface areas from the starting wall surface to the ending wall surface is less than or equal to the constructable area of the current construction worker, and the cumulative sum of wall surface areas from the starting wall surface to the next wall surface of the ending wall surface is greater than the constructable area of the current construction worker. The processor mat take the current construction worker as one of the target construction workers, and take the starting wall surface, the ending wall surface, and the intermediate wall surfaces between the starting wall surface and the ending wall surface, and the construction task items of the starting wall surface, the ending wall surface, and the intermediate wall surfaces as the target wall surfaces and the construction task items assigned to the target construction workers.

For example, when the construction worker list is P₁-Pₙ, for a current construction worker P₁, a constructable area of the current construction worker P₁ is S₁. The processor may start from the first unassigned wall surface in the wall surface list, sequentially determine a cumulative sum of wall surface areas from each wall surface to the first wall surface, until finding an ending wall surface of the construction worker P₁ satisfying a termination condition. The termination condition refers to that the cumulative sum of wall surface areas from the first wall surface to the ending wall surface is less than or equal to S₁, and the cumulative sum of wall surface areas from the first wall surface to a next wall surface of the ending wall surface is greater than S₁. For a current construction worker P₂, an assignment starts from a first wall surface among remaining wall surfaces in the wall surface list, and an assignment method similar to that for the construction worker P₁ is adopted to assign the construction worker P₂, until an ending wall surface of the construction worker P₂ is determined. By analogy, until all construction workers in the construction worker list have performed the task assignment operation or all wall surfaces in the wall surface list have been assigned.

The processor may designate the construction workers who have performed the task assignment operation as the target construction workers. For each of the target construction workers, the processor may take a starting wall surface, an ending wall surface, and wall surfaces between the starting wall surface and the ending wall surface corresponding to the target construction worker as target wall surfaces, and assign the target wall surfaces to the target construction worker.

In some embodiments, under some conditions, construction tasks are relatively few, but construction workers in the construction task sheet are relatively many, and a situation where a portion of the construction workers are not assigned tasks may exist. At this time, the initiator of the construction task sheet may be reminded of the surplus construction workers, which may be performed through steps 2330 to 2340.

In 2330, whether there is a construction worker who has not received the task assignment operation is determined.

After assigning the tasks, the processor may compare the target construction workers with the construction workers in the construction task sheet, so as to determine whether there is a construction worker who has not received the task assignment operation.

In 2340, in response to determining that there is a construction worker who has not received the task assignment operation, a reminder of surplus construction workers is sent to the initiator of the construction task sheet.

In response to determining that there is a construction worker who has not received the task assignment operation, it indicates that there is a surplus of construction workers in the construction task sheet.

The reminder of surplus construction workers may be in a text form, a voice form, a light form, etc.

In some embodiments, the processor may send the reminder of surplus construction workers to a user terminal of the initiator through a network, so as to be presented to the initiator through the user terminal.

In some embodiments of the present disclosure, through the task assignment operation, minimizing walking distances of the construction workers can be achieved, and a sum of wall surface areas assigned to each target construction worker not exceeding a sum of constructable areas thereof can be achieved. By sending a reminder about surplus construction workers to the initiator of the construction task sheet, new tasks can be assigned to the remaining construction workers, thereby preventing personnel waste and improving personnel utilization.

It should be noted that the above descriptions regarding the processes 200 to 2300 are merely for examples and illustrations, and do not limit the scope of the present disclosure. For those skilled in the art, a plurality of variations and modifications may be made to the processes 200 to 2300 under the guidance of the present disclosure. However, these variations and modifications do not depart from the scope of the present disclosure.

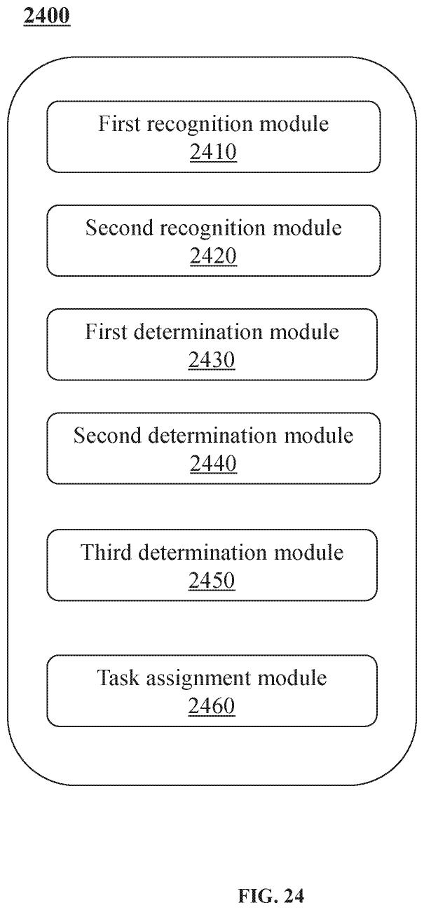

FIG. 24 is an exemplary module diagram illustrating a system for construction task assignment based on recognition of construction drawing information according to some embodiments of the present disclosure. In some embodiments, a system 2400 for construction task assignment based on recognition of construction drawing information may be disposed in the processor 120. As shown in FIG. 24, the system 2400 for construction task assignment based on recognition of construction drawing information includes a first recognition module 2410, a second recognition module 2420, a first determination module 2430, a second determination module 2440, a third determination module 2450, and a task assignment module 2460.

The first recognition module 2410 is configured to obtain a construction drawing.

The second recognition module 2420 is configured to recognize a plurality of closed paths in the construction drawing.

The first determination module 2430 is configured to determine a drawing border of the construction drawing based on a positional relationship between the plurality of closed paths.

The second determination module 2440 is configured to determine title block information based on the drawing border of the construction drawing and a title block scope of the construction drawing.

The third determination module 2450 is configured to determine a recognition result of a target object in the construction drawing based on the title block information.

The task assignment module 2460 is configured to perform a construction task assignment based on the recognition result of the target object.

It should be noted that the above descriptions of the system 2400 for construction task assignment based on recognition of construction drawing information and modules thereof are merely for convenience of description, and cannot limit the present disclosure to a scope of cited embodiments. In some embodiments, the first recognition module 2410, the second recognition module 2420, the first determination module 2430, the second determination module 2440, the third determination module 2450, and the task assignment module 2460 in FIG. 24 may be different modules in one system, or one module may implement functions of two or more of the above modules. For example, each module may share one storage module, and each module may also have its own storage module respectively. Variations such as these are all within a protection scope of the present disclosure.

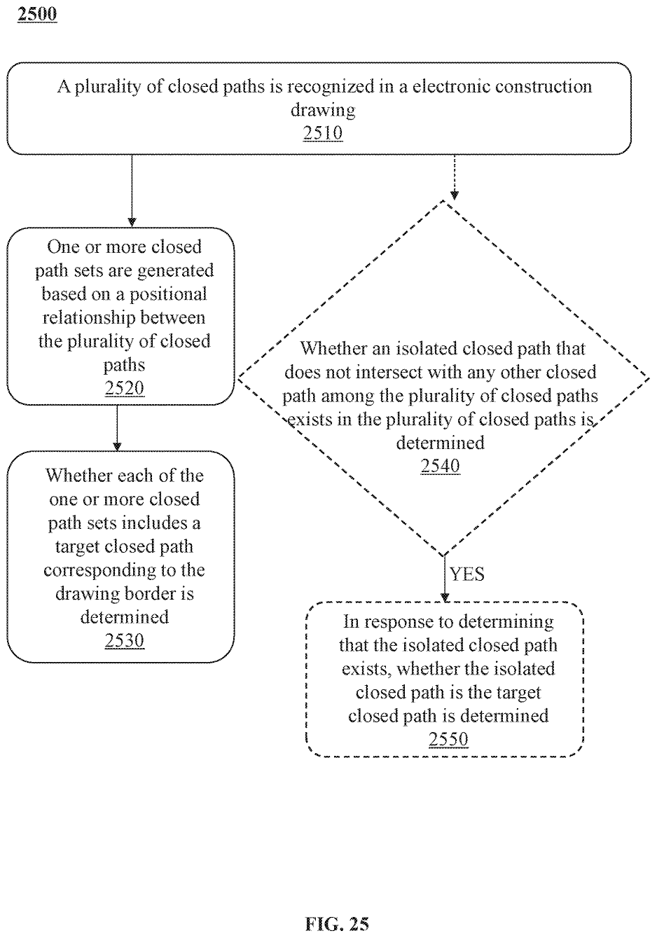

In some embodiments, the present disclosure further provides a method for drawing border recognition. FIG. 25 is a flowchart of an exemplary process for drawing border recognition according to some embodiments of the present disclosure. In some embodiments, a process 2500 may be performed by the processor 120. As shown in FIG. 25, the process 2500 includes the following steps.

In 2510, a plurality of closed paths is recognized in a electronic construction drawing.

In some embodiments, the processor 120 may parse the construction drawing to extract a plurality of straight-lines in the construction drawing. As another example, the processor 120 may extract a plurality of straight lines in the electronic construction drawing through an image recognition algorithm (such as a Hough transform algorithm, an edge detection algorithm, etc.). Further, the processor 120 may obtain intersection information of the plurality of straight lines, and determine whether the plurality of straight lines can form a closed path according to the intersection information of the plurality of straight lines. For example, the processor 120 may recognize whether endpoints of the plurality of straight lines intersect through positions of the plurality of straight lines, and determine whether the plurality of straight lines can form a closed path according to whether a plurality of continuous straight lines with intersecting endpoints return to a starting endpoint.

In some embodiments, the processor 120 may construct an undirected graph based on the electronic construction drawing, and determine a plurality of closed paths according to the undirected graph.

In 2520, one or more closed path sets are generated based on a positional relationship between the plurality of closed paths.

In some embodiments, each of the one or more closed path sets includes one or more closed paths at one or more levels, a first area enclosed by each of closed paths at a lower level being included within a second area enclosed by closed paths at an upper level of the lower level, or intersecting with the second area. More descriptions regarding generating one or more closed path sets may be found elsewhere in the present disclosure (e.g., FIG. 6 and related descriptions thereof).

In 2530, whether each of the one or more closed path sets includes a target closed path corresponding to the drawing border is determined.

In 2540, whether an isolated closed path that does not intersect with any other closed path among the plurality of closed paths exists in the plurality of closed paths is determined.

In 2550, in response to determining that the isolated closed path exists, whether the isolated closed path is the target closed path is determined.

More descriptions regarding the process 2500 may be found in related sections above, such as FIGS. 2 to 9B.

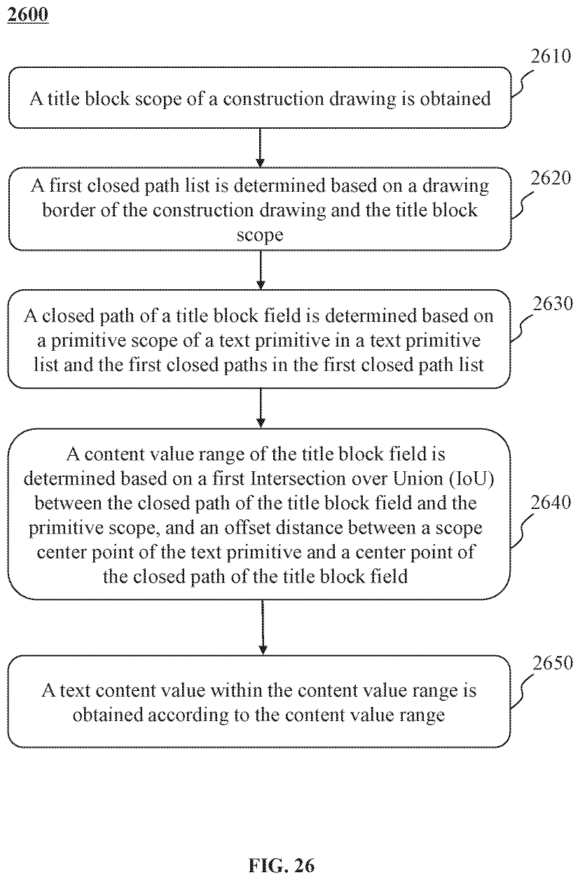

In some embodiments, the present disclosure further provides a method for title block information recognition. FIG. 26 is a flowchart of an exemplary process for title block information recognition according to some embodiments of the present disclosure. In some embodiments, a process 2600 may be performed by the processor 120. As shown in FIG. 26, the process 2600 includes following steps.

In 2610, a title block scope of a construction drawing is obtained.

In 2620, a first closed path list is determined based on a drawing border of the construction drawing and the title block scope.

In 2630, a closed path of a title block field is determined based on a primitive scope of a text primitive in a text primitive list and the first closed paths in the first closed path list.

In 2640, a content value range of the title block field is determined based on a first Intersection over Union (IoU) between the closed path of the title block field and the primitive scope, and an offset distance between a scope center point of the text primitive and a center point of the closed path of the title block field.

In 2650, a text content value within the content value range is obtained according to the content value range.

More descriptions regarding the process 2600 may be found in related sections above, such as FIG. 2, FIGS. 10 to 13, etc.

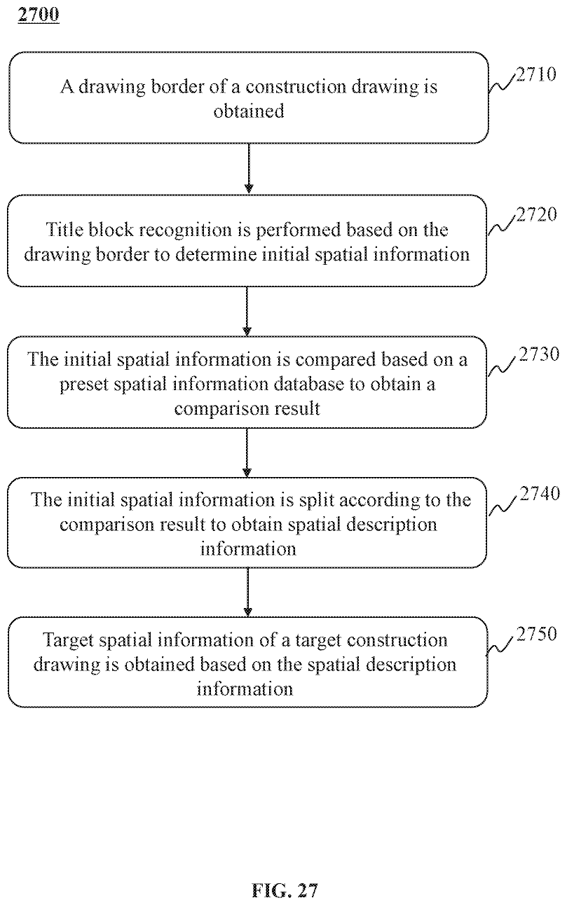

In some embodiments, the present disclosure further provides a method for extracting spatial information of a construction drawing. FIG. 27 is a flowchart of an exemplary process for extracting spatial information of a construction drawing according to some embodiments of the present disclosure. In some embodiments, a process 2700 may be performed by the processor 120. As shown in FIG. 27, the process 2700 includes following steps.

In 2710, a drawing border of a construction drawing is obtained.

In 2720, title block recognition is performed based on the drawing border to determine initial spatial information.

In 2730, the initial spatial information is compared based on a preset spatial information database to obtain a comparison result.

In 2740, the initial spatial information is split according to the comparison result to obtain spatial description information.

In 2750, target spatial information of a target construction drawing is obtained based on the spatial description information.

More descriptions regarding the process 2700 may be found in related sections above, such as FIG. 2, FIGS. 14 to 17, etc.

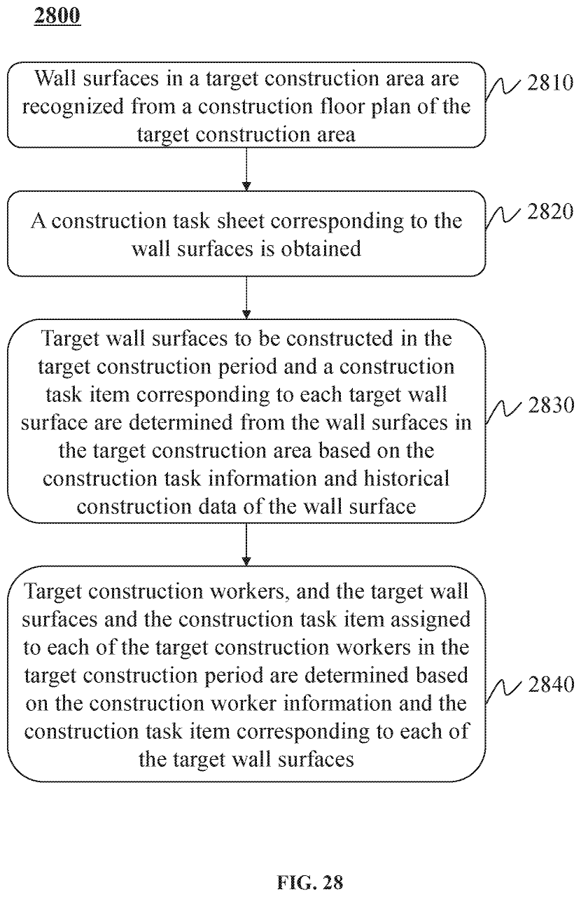

In some embodiments, the present disclosure further provides a method for wall surface task assignment. FIG. 28 is a flowchart of an exemplary process for wall surface task assignment according to some embodiments of the present disclosure. In some embodiments, a process 2800 may be performed by the processor 120. As shown in FIG. 28, the process 2800 includes following steps.

In 2810, wall surfaces in a target construction area are recognized from a construction floor plan of the target construction area.

In 2820, a construction task sheet corresponding to the wall surfaces is obtained.

In 2830, target wall surfaces to be constructed in the target construction period and a construction task item corresponding to each target wall surface are determined from the wall surfaces in the target construction area based on the construction task information and historical construction data of the wall surface.

In 2840, target construction workers, and the target wall surfaces and the construction task item assigned to each of the target construction workers in the target construction period are determined based on the construction worker information and the construction task item corresponding to each of the target wall surfaces.

More descriptions regarding the process 2800 may be found in related sections above, such as FIG. 2, FIGS. 18 to 23, etc.

The basic concepts have been described above. Obviously, for those skilled in the art, the above detailed disclosure is merely an example and does not constitute a limitation on the present disclosure. Meanwhile, the present disclosure uses specific words to describe embodiments of the present disclosure. For example, “one embodiment”, “an embodiment”, and/or “some embodiments” means a certain feature, structure, or characteristic related to at least one embodiment of the present disclosure. Therefore, it should be emphasized and noted that “an embodiment” or “one embodiment” or “an alternative embodiment” mentioned twice or more times in different positions in the present disclosure does not necessarily refer to a same embodiment.

It should be noted that, in order to simplify expressions disclosed in the present disclosure and thereby help understand one or more embodiments, in the foregoing descriptions of the embodiments of the present disclosure, a plurality of features are sometimes grouped into one embodiment, drawing, or description thereof. However, this disclosure method does not mean that an object of the present disclosure requires more features than those mentioned in claims. In fact, features of the embodiments are less than all features of a single embodiment disclosed above.

What is claimed is:

1. A method for construction task assignment based on recognition of construction drawing information, comprising:
obtaining a construction drawing;
recognizing a plurality of closed paths in the construction drawing;
determining a drawing border of the construction drawing based on a positional relationship between the plurality of closed paths;
determining title block information based on the drawing border of the construction drawing and a title block scope of the construction drawing;
determining a recognition result of a target object in the construction drawing based on the title block information; and
performing a construction task assignment based on the recognition result of the target object.

2. The method of claim 1, wherein the determining a drawing border of the construction drawing based on a positional relationship between the plurality of closed paths includes:
generating one or more closed path sets based on the positional relationship between the plurality of closed paths, each of the one or more closed path sets including one or more closed paths at one or more levels, a first area enclosed by each of closed paths at a lower level being included within a second area enclosed by closed paths at an upper level of the lower level, or intersecting with the second area; and
determining whether each of the one or more closed path sets includes a target closed path corresponding to the drawing border.

3. The method of claim 2, wherein the generating one or more closed path sets based on the positional relationship between the plurality of closed paths includes:
determining one or more groups of intersecting closed paths based on the positional relationship between the plurality of closed paths;
determining each group of intersecting closed paths as closed paths in one of the one or more closed path sets; and
determining, for each of the one or more closed path sets, a level of each closed path in the closed path set based on an area of a region enclosed by the each closed path in the closed path set includes:
determining an initial upper level closed path among two intersecting closed paths in the closed path set by comparing areas of regions enclosed by the two intersecting closed paths;
for each of the closed paths in the closed path set, in response to determining that a count of initial upper level closed paths corresponding to each of the closed paths is zero, determining that the closed path is a highest-level closed path;
in response to determining that the count of the initial upper-level closed paths is one, determining that the initial upper-level closed path is an upper-level closed path of the each of the closed paths; and
in response to determining that the count of the initial upper-level closed paths is two or more, determining the upper-level closed path of the each of the closed pathsbased on an Intersection over Union (IoU) between the each of the closed paths and each of the initial upper-level closed paths.

4. The method of claim 2, wherein determining whether each of the one or more closed path sets includes a target closed path corresponding to the drawing border includes:
processing closed paths in the one of the one or more closed path sets starting from a close path at the highest level, until the target closed path is found or all closed paths in the one of the one or more closed path sets are processed, wherein processing one or more closed path at a current level includes:
determining a rectangular closed path among the one or more closed paths at the current level;
determining whether the rectangular closed path satisfies a first preset condition and a second preset condition, the first preset condition being related to a positional relationship between the one or more closed paths at the current level and one or more lower-level closed paths of the one or more closed paths at the current level, and the second preset condition being related to one or more characteristics of the drawing border;
in response to determining that the rectangular closed path satisfies the first preset condition and the second preset condition, determining the rectangular closed path as the target closed path; and
in response to determining that the rectangular closed path does not satisfy the first preset condition or the second preset condition, processing one or more closed paths at a next level; wherein the first preset condition includes that the rectangular closed path has a lower-level closed path with an IoU greater than a preset threshold, or the rectangular closed path includes a lower-level closed path passing through one or more vertices of the rectangular closed path.

5. The method of claim 1, further comprising:
determining whether an isolated closed path that does not intersect with any other closed path among the plurality of closed paths exists in the plurality of closed paths;
in response to determining that the isolated closed path exists in the plurality of closed paths,
determining whether the isolated closed path is a rectangular closed path that satisfies a second preset condition, the second preset condition being related to one or more characteristics of the drawing border; and
in response to determining that the isolated closed path is the rectangular closed path that satisfies the second preset condition, designating the isolated closed path as the target closed path.

6. The method of claim 1, wherein the determining title block information based on the drawing border of the construction drawing and a title block scope of the construction drawing includes:
determining a first closed path list based on the drawing border of the construction drawing and the title block scope of the construction drawing, the first closed path list including all first closed paths that do not contain any other closed paths;
determining a closed path of a title block field based on a primitive scope of a text primitive in a text primitive list and the first closed paths in the first closed path list;
determining a content value range of the title block field based on a first IoU between the closed path of the title block field and the primitive scope, and an offset distance between a scope center point of the text primitive and a center point of the closed path of the title block field; and
designating a text content value within the content value range as the title block information according to the content value range; wherein the determining the content value range of the title block field based on the first IoU between the closed path of the title block field and the primitive scope, and the offset distance between the scope center point of the text primitive and the center point of the closed path of the title block field includes:
determining whether the first IoU and the offset distance satisfy a third preset condition; and
in response to determining that the first IoU and the offset distance satisfy the third preset condition, designating a scope of the closed path of the title block field as the content value range;
in response to the first IoU and/or the offset distance not satisfying the third preset condition, determining adjacent closed paths each of which shares a same vertice with the closed path of the title block field;
determining adjacent closed paths that satisfy a filtering condition as second closed paths defining a second closed path list; and
determining the content value range based on the second closed path list.

7. The method of claim 6, wherein the third preset condition includes that the first IoU is less than or equal to a first threshold, and a ratio of the offset distance to a length of the closed path of the title block field in a target direction is greater than a second threshold.

8. The method of claim 6, wherein the determining the content value range based on the second closed path list includes:
determining a path count in the second closed path list;
in response to the path count in the second closed path list being 0, determining the closed path of the title block field as the content value range;
in response to the path count in the second closed path list being greater than 0, determining a second IoU between each of the second closed paths and the title block scope;
in response to a count of the second closed paths whose second IoUs with the title block scope satisfy a fourth preset condition, in the second closed path list being less than a preset count, designating the second closed paths whose second IoUs with the title block scope satisfy the fourth preset condition as the content value range; and
in response to the count of the second closed paths whose second IoUs with the title block scope satisfy the fourth preset condition, in the second closed path list being not less than the preset count, determining a target distance between a center point of each of the second closed paths and the center point of the closed path of the title block field in a preset direction, and designating the second closed path whose center point has the target distance in the preset direction from the center point of the closed path of the title block field satisfy a fifth preset condition as the content value range.

9. The method of claim 6, wherein the title block scope of the construction drawing is obtained according to operations including:
generating a primitive information list based on the text primitive in the construction drawing;
determining an aggregation scope list based on an aggregation condition between the text primitive in the primitive information list, the aggregation scope list including the primitive scope of at least one of the text primitive; and
determining the title block scope based on the aggregation scope list includes:
for each of the text primitive in the primitive information list, determining a first IoU between the primitive scope of the text primitive and a drawing border scope of the drawing border;
in response to the first IoU being greater than a third threshold, deleting the text primitive from the primitive information list;
in response to the first IoU being less than or equal to the third threshold, determining whether the aggregation scope list is empty;
in response to the aggregation scope list being empty, filling the primitive scope of the text primitive into the aggregation scope list;
in response to the aggregation scope list being non-empty, determining a union of each aggregation scope in the aggregation scope list and the primitive scope of the text primitive, and determining a second IoU between the union and the drawing border;
in response to the second IoU being greater than a fourth threshold, filling the primitive scope of the text primitive into the aggregation scope list;
in response to the second IoU being less than or equal to the fourth threshold, replacing the aggregation scope with the union; and
determining the title block scope based on an occurrence count of the title block field in at least one aggregation scope in the aggregation scope list.

10. The method of claim 1, wherein the recognition result includes target spatial information, and the determining a recognition result of a target object in the construction drawing based on the title block information includes:
determining initial spatial information based on the title block information;
comparing the initial spatial information based on a preset spatial information database to obtain a comparison result;
splitting the initial spatial information according to the comparison result to obtain spatial description information; and
obtaining the target spatial information of the target construction drawing based on the spatial description information.

11. The method of claim 10, wherein the splitting the initial spatial information to obtain spatial description information according to the comparison result includes:
splitting the initial spatial information to obtain a plurality of spatial information combinations in response to the comparison result satisfying a fifth preset condition; and
obtaining floor spatial description information and building spatial description information for each of the spatial information combinations based on a preset manner; wherein the obtaining the target spatial information of the target construction drawing based on the spatial description information includes:
performing keyword extraction based on the floor spatial description information and the building spatial description information to obtain target floor information and target building information; and
combining the target floor information and the target building information to obtain the target spatial information of the target construction drawing; wherein the performing keyword extraction based on the floor spatial description information and the building spatial description information to obtain target floor information and target building information includes:
extracting first numbers and a custom floor in the floor spatial description information;
determining first floor information based on an adjacent connecting word of the first numbers;
determining second floor information based on a continuity word between the first numbers;
determining the target floor information based on the first floor information and the second floor information, and taking the custom floor as supplementary floor information;
extracting second numbers and a custom building in the building spatial description information;
determining first building information based on an adjacent connecting word of the second number;
determining second building information based on a continuity word between the second numbers; and
determining the target building information based on the first building information and the second building information, and taking the custom building as supplementary building information.

12. The method of claim 10, further comprising:
splitting the initial spatial information to obtain floor spatial description information in response to the comparison result satisfying a sixth preset condition;
performing keyword extraction based on the floor spatial description information to obtain target floor information;
obtaining sub-item information of the drawing border, and obtaining sub-item spatial information based on the sub-item information;
splitting the sub-item spatial information to obtain building spatial description information;
performing keyword extraction based on the building spatial description information to obtain target building information; and
combining the target floor information and the target building information to obtain the target spatial information of the target construction drawing.

13. The method of claim 10, further comprising:
performing image segmentation based on the target construction drawing to obtain one or more building area drawings;
determining auxiliary building information based on the one or more building area drawings;
performing floor recognition for each of the one or more building area drawings based on the building area drawing to determine auxiliary floor information;
combining the auxiliary building information and the auxiliary floor information to obtain auxiliary spatial information;
determining whether the auxiliary spatial information is consistent with the target spatial information; and
in response to the auxiliary spatial information being inconsistent with the target spatial information, outputting prompt information, the prompt information being used to prompt a user to verify the target spatial information.

14. The method of claim 13, wherein the performing floor recognition based on the building area drawing to determine auxiliary floor information includes:
inputting the building area drawing into a convolutional neural network to obtain a convolutional feature vector;
performing enhancement processing on the convolutional feature vector to obtain an enhanced feature vector; and
inputting the enhanced feature vector into a floor recognition model to determine the auxiliary floor information.

15. The method of claim 1, wherein the recognition result includes wall surfaces, and the performing construction task assignment based on the recognition result of the target object includes:
obtaining a construction task sheet corresponding to the wall surfaces, the construction task sheet including construction task information and construction worker information corresponding to a target construction period;
determining target wall surfaces to be constructed in the target construction period and a construction task item corresponding to each target wall surface from the wall surfaces in the target construction area based on the construction task information and historical construction data of the wall surface; and
determining target construction workers, and the target wall surfaces and the construction task item assigned to each of the target construction workers in the target construction period, based on the construction worker information and the construction task item corresponding to each of the target wall surfaces; wherein the wall surface includes an indoor-facing interior wall surface and an outdoor-facing exterior wall surface, the construction task sheet includes a first construction task sheet corresponding to the interior wall surface and a second construction task sheet corresponding to the exterior wall surface, task assignment for the interior wall surface is performed based on the first construction task sheet, and task assignment for the exterior wall surface is performed based on the second construction task sheet.

16. The method of claim 15, wherein the determining a recognition result of a target object in the construction drawing based on the title block information includes:
determining the construction drawing as a construction floor plan based on the title block information;
determining a plurality of outdoor grids and a plurality of indoor grids in the construction floor plan;
traversing from at least one indoor grid of the plurality of indoor grids as a starting point to adjacent indoor grids of the at least one indoor grid until a target indoor grid corresponding to a space barrier element is determined;
traversing from at least one outdoor grid of the plurality of outdoor grids as a starting point to adjacent outdoor grids of the at least one outdoor grid until a target outdoor grid corresponding to the space barrier element is determined; and
recognizing the interior wall surface and the exterior wall surface in the target construction area from the construction floor plan based on the target indoor grid and the target outdoor grid.

17. The method of claim 15, wherein the determining target construction workers, and the target wall surfaces and the construction task item assigned to each of the target construction workers in the target construction period, based on the construction worker information and the construction task item corresponding to each of the target wall surfaces includes:
dividing the target wall surfaces into at least one wall surface group corresponding to at least one type of construction task item based on the construction task item corresponding to each target wall surface;
for each type of construction task item,
determining construction workers capable of handling the construction task item and a constructable area of the construction workers in the target construction period based on the construction worker information;
generating a wall surface list based on position information of wall surfaces in a wall surface group corresponding to the construction task item;
determining the target construction workers corresponding to the construction task item based on the wall surface list and the constructable area of the target construction workers; and
determining the target wall surfaces, and a construction task item of the target wall surfaces assigned to each of the target construction workers in the wall surface group corresponding to the construction task item; wherein the method further includes:
determining a sum of constructable areas of the construction workers capable of handling the construction task item, and a sum of wall surface areas in the wall surface group;
in response to the sum of the constructable areas being less than the sum of the wall surface areas:
estimating a delay loss caused by construction period delay and a worker addition cost caused by adding additional construction workers;
sending a task sheet update request to an initiator of the construction task sheet, the task sheet update request including the delay loss and the worker addition cost; and
updating the construction worker information and/or the target construction period based on an updated construction task sheet received from the initiator.

18. The method of claim 17, wherein the determining the target construction workers corresponding to the construction task item based on the wall surface list and the constructable area of the target construction workers; and determining the target wall surfaces, and a construction task item of the target wall surfaces assigned to each of the target construction workers in the wall surface group corresponding to the construction task item includes:
sorting construction workers capable of handling the construction task item to generate a construction worker list;
performing a task assignment operation on the construction workers in the construction worker list in sequence until all construction workers in the construction workers list have performed the task assignment operation or all wall surfaces in the wall surface list have been assigned, wherein
for a current construction worker, the task assignment operation includes:
determining a first unassigned wall surface in the wall surface list as a starting wall surface;
determining an ending wall surface in the wall surface list, so that a cumulative sum of wall surface areas from the starting wall surface to the ending wall surface is less than or equal to a constructable area of the current construction worker, and a cumulative sum of wall surface areas from the starting wall surface to a next wall surface of the ending wall surface is greater than the constructable area of the current construction worker; and
taking the current construction worker as one of the target construction workers,
taking the starting wall surface, the ending wall surface, and intermediate wall surfaces between the starting wall surface and the ending wall surface, as the target wall surfaces; and
taking construction task items of the current construction worker as construction task items assigned to the target construction workers.

19. The method of claim 17, wherein the target construction area includes at least two floors, the construction floor plan includes a construction floor plan corresponding to each of the at least two floors, the wall surface includes an outdoor-facing exterior wall surface, and a wall surface list corresponding to the exterior wall surface is generated according to operations including:
for each floor of the at least two floors,
generating a first 3D model corresponding to the floor based on a floor height of the floor and a wall surface in the construction floor plan corresponding to the floor;
determining a reference area corresponding to a common vertical space of a plurality of floors in the first 3D model;
aligning and stacking the first 3D models of the at least two floors based on the reference areas in the first 3D models of the at least two floors to generate a second 3D model of the target construction area; and
generating the wall surface list corresponding to the exterior wall surface based on the second 3D model.

20. A system for construction task assignment based on recognition of construction drawing information, comprising:
a first recognition module configured to obtain a construction drawing;
a second recognition module configured to recognize a plurality of closed paths in the construction drawing;
a first determination module configured to determine a drawing border of the construction drawing based on a positional relationship between the plurality of closed paths;
a second determination module configured to determine title block information based on the drawing border of the construction drawing and a title block scope of the construction drawing;
a third determination module configured to determine a recognition result of a target object in the construction drawing based on the title block information; and
a task assignment module configured to perform a construction task assignment based on the recognition result of the target object.
